(19) United States
(12) Patent Application Publication
(10) Pub. No.: US 2013/0203187 A1
(43) Pub. Date: Aug. 8, 2013

(54) SEMICONDUCTOR DEVICE AND METHOD FOR MANUFACTURING A SEMICONDUCTOR DEVICE

(71) Applicants: Masamichi MATSUOKA, Kanagawa (JP); Tatsuya FUKUMURA, Kanagawa (JP)

(72) Inventors: Masamichi MATSUOKA, Kanagawa (JP); Tatsuya FUKUMURA, Kanagawa (JP)

(73) Assignee: RENESAS ELECTRONICS CORPORATION, Kanagawa (JP)

(21) Appl. No.: 13/827,068

(22) Filed: Mar. 14, 2013

Related U.S. Application Data
(62) Division of application No. 13/023,188, filed on Feb. 8, 2011.

(30) Foreign Application Priority Data
Feb. 12, 2010 (JP) 2010-028998

(51) Int. Cl. H01L 43/02

(52) U.S. Cl. CPC H01L 43/02
USPC 438/3

(57) ABSTRACT

The semiconductor device of this invention includes a semiconductor substrate having a main surface, and a magnetoresistive element located over the main surface of the semiconductor substrate. Further, it includes a protective layer, a wiring, a first upper electrode, and a second upper electrode. The protective layer is disposed so as to cover the side surface of the magnetoresistive element. The wiring is located over the top of the magnetoresistive element. The first upper electrode substantially the same in dimensions in plan view as the magnetoresistive element is disposed over the magnetoresistive element. The second upper electrode is electrically coupled with the first upper electrode over the first upper electrode, and larger in dimensions in plan view than the first upper electrode.

### CROSS-REFERENCE TO RELATED APPLICATIONS

The disclosure of Japanese Patent Application No. 2010-28998 filed on Feb. 12, 2010 including the specification, drawings and abstract is incorporated herein by reference in its entirety.

### BACKGROUND OF THE INVENTION

The present invention relates to a semiconductor device and a method for manufacturing a semiconductor device. More particularly, it relates to a semiconductor device including a magnetoresistive element, and a manufacturing method thereof.

As semiconductor devices such as semiconductor integrated circuits for storage, conventionally, DRAMs (Dynamic Random Access Memories) and SRAMs (Static Random Access Memories) have been widely used. On the other hand, MRAMs (Magnetic Random Access Memories) are devices which store information by magnetism, and have more excellent features than those of other memory technologies in terms of high-speed operation, rewrite resistance, nonvolatility, and the like.

A MRAM includes a magnetoresistive element referred to as a MTJ (Magnetic Tunnel Junction) element using a TMR (Tunneling Magnetoresistive) effect, and stores information by the magnetization state of the magnetoresistive element. As one example of the semiconductor device using a MRAM, for example, mention may be made of a semiconductor device in which at portions of intersection between digit lines extending in one direction and bit lines extending in the direction generally orthogonal thereto, magnetoresistive elements are disposed, and formed in an array. In this case, each magnetoresistive element includes a layer changing in direction of magnetization due to the magnetic field formed by currents flowing through the digit line and the bit line. The magnetoresistive element stores the direction of magnetization as information. Then, the electrical resistance of the magnetoresistive element changes according to the direction of magnetization of the layer. By the change in electrical resistance, the change in current flowing through the magnetoresistive element is detected. Thus, the information stored in the magnetoresistive element is detected.

There have been conventionally proposed semiconductor devices variously changed in configuration of the region sandwiched between a magnetoresistive element and a bit line in order to intensively supply the magnetic field formed by a current to the magnetoresistive element.

For example, Japanese Unexamined Patent Publication No. 2006-165556 (Patent Document 1) discloses a magnetic memory element including conductive electrode pad layers between a MTJ cell and a bit line, and between the MTJ cell and a conductive plug. For the magnetic memory element, the write operation to the MTJ cell is carried out by the magnetic field generated around the conductive electrode pad layer closer to the MTJ cell than the bit line. The magnetic field necessary for performing write to the MTJ cell can be reduced. Accordingly, the driving electrical power of the magnetic memory element can be reduced.

Further, for example, Japanese Unexamined Patent Publication No. 2004-47966 (Patent Document 2) discloses a semiconductor storage device in which a part other than magnetic substance elements in a region including the magnetic substance elements stacked therein has been insulated in order to increase the amount of the magnetic field, which has been generated upon passing a current through a wiring for write over the tops of the magnetic substance elements, to be exerted to the neighboring magnetic substance elements. Further, in the semiconductor storage device, a mask to be used for forming an insulation film in the region to be insulated is disposed as an upper electrode of the magnetic substance element in such a manner as to be close to the magnetic substance element. Therefore, it is possible to reduce the magnetic field necessary for performing write to the magnetic substance element by the current flowing though the overlying wiring. Accordingly, it is possible to reduce the driving electrical power of the magnetic substance element.

On the other hand, for example, Japanese Unexamined Patent Publication No. 2006-54458 (Patent Document 3) discloses a magnetic RAM element in which in a region sandwiched between a magnetic tunneling junction structure and a semiconductor substrate, a contact plug for electrically coupling the magnetic tunneling junction structure and the semiconductor substrate is disposed. Accordingly, for example, as compared with a magnetic RAM element in which a contact plug is disposed in a region away from immediately under the magnetic tunneling junction structure, the occupancy area in plan view is reduced. Therefore, it is possible to improve the integration degree of a semiconductor device using a magnetic RAM element.

### PATENT DOCUMENT

[Patent Document 1]
Japanese Unexamined Patent Publication No. 2006-165556

[Patent Document 2]
Japanese Unexamined Patent Publication No. 2004-47966

[Patent Document 3]
Japanese Unexamined Patent Publication No. 2006-54458

In both of the magnetic memory element and the semiconductor storage device disclosed in Japanese Unexamined Patent Publication No. 2006-165556 and Japanese Unexamined Patent Publication No. 2004-47966, in order to electrically couple a MTJ cell or a magnetic substance element corresponding to a magnetoresistive element and a bit line (upper wiring), the upper electrode formed over the top of the magnetoresistive element includes only one layer. This may cause penetration of impurities such as moisture from the top side (bit line side) of the magnetoresistive element into the inside of the magnetoresistive element, for example, from the interlayer insulation film. Such penetration of impurities may impair the function of the magnetoresistive element.

Further, the upper electrode formed over the top of the magnetoresistive element includes only one layer. This results in an increase in stress of the bit line (upper wiring) exerted on the upper electrode or the underlying magnetoresistive element. An increase in stress applied to the magnetoresistive element may cause damage or characteristic deterioration of the magnetoresistive element.

In the magnetic RAM element disclosed in Japanese Unexamined Patent Publication No. 2006-54458, two layers of the upper electrode and the capping layer are disposed between the magnetic tunneling junction structure and the bit line. However, the dimensions in plan view of the upper electrode and the capping layer are roughly the same as the dimensions in plan view of the magnetic tunneling junction structure. The magnetic RAM element in accordance with the present invention has a structure for improving the degree of integration of the magnetic tunneling junction structure. For this reason, the dimensions thereof in plan view are relatively small, which may cause an increase in contact resistance between the bit line and the magnetic tunneling junction structure. In other words, the conductivity between the bit line and the magnetic tunneling junction structure may be deteriorated.

### SUMMARY OF THE INVENTION

The present invention was made in view of the foregoing problems. It is an object thereof to provide a semiconductor device which inhibits penetration of impurities into the magnetoresistive element, and the load of a stress thereon, and operates at a low driving electrical power with high precision, and a manufacturing method thereof.

A semiconductor device in one example of the present invention includes the following respective constituent elements. First, the semiconductor device has a semiconductor substrate having a main surface, and a magnetoresistive element located over the main surface of the semiconductor substrate. In addition, the semiconductor device includes a protective layer, a wiring, a first upper electrode, and a second upper electrode. The protective layer is disposed in such a manner as to cover the side surface of the magnetoresistive element. The wiring is located over the top of the magnetoresistive element. The first upper electrode substantially the same in dimensions in plan view as the magnetoresistive element is disposed over the magnetoresistive element. The second upper electrode is, over the first electrode, electrically coupled with the first upper electrode, and is larger in dimensions in plan view than the first upper electrode.

A method for manufacturing a semiconductor device in one embodiment of the present invention includes the following steps. First, a semiconductor substrate having a main surface is prepared. A magnetoresistive element located over the main surface of the semiconductor substrate is formed. The magnetoresistive element is formed so as to have, over the magnetoresistive element, a first upper electrode substantially the same in dimensions in plan view as the magnetoresistive element. A protective layer is formed in such a manner as to cover the side surface of the magnetoresistive element. Over the first upper electrode, a second upper electrode larger in dimensions in plan view than the first upper electrode is formed. A wiring located over the second upper electrode is formed.

In accordance with the present example, between the wiring and the magnetoresistive element, there are disposed two layers of the first upper electrode and the second upper electrode. For this reason, it is possible to implement a semiconductor device which can more inhibit the penetration of impurities such as moisture from the top of the magnetoresistive element, and can relieve the stress applied to the magnetoresistive element, as compared with, for example, the case where the upper electrode includes only one layer.

Further, the dimensions in plan view of the second upper electrode are larger than the dimensions in plan view of the first upper electrode. For this reason, the contact resistance between the wiring and the magnetoresistive element becomes smaller, resulting in an improvement of the conductivity between both thereof. Therefore, it is possible to implement a semiconductor device in which a magnetoresistive element can operate at a smaller driving electrical power with high precision.

### BRIEF DESCRIPTION OF THE DRAWINGS

FIG. 1 is a plan view schematically showing a semiconductor device including a digit line in accordance with the present embodiment;

FIG. 2 is a plan view showing a magnetoresistive element and the periphery thereof of FIG. 1 in the semiconductor device of Embodiment 1;

FIG. 3 is a schematic cross-sectional view of a portion along line III-III of FIG. 2;

FIG. 4 is a schematic cross-sectional view of a portion along line IV-IV of FIG. 2;

FIG. 5 is a cross-sectional view showing a form of a circuit in a peripheral part in a memory cell region including a plurality of magnetoresistive elements disposed therein of the semiconductor device of FIG. 3 in accordance with Embodiment 1;

FIG. 6 is a cross-sectional view showing a form in which a first upper electrode and a second upper electrode are coupled in such a manner as to be in contact with each other as a modified example of FIG. 3 in accordance with Embodiment 1;

FIG. 7 is a cross-sectional view showing one example of a lamination structure forming a magnetization pinned layer;

FIG. 8 is a cross-sectional view showing a first manufacturing step of a method for manufacturing a semiconductor device;

FIG. 9 is a cross-sectional view showing a manufacturing step after the manufacturing step shown in FIG. 8;

FIG. 10 is a cross-sectional view showing a manufacturing step after the manufacturing step shown in FIG. 9;

FIG. 11 is a cross-sectional view showing a manufacturing step after the manufacturing step shown in FIG. 10;

FIG. 12 is a cross-sectional view showing a manufacturing step after the manufacturing step shown in FIG. 11;

FIG. 13 is a cross-sectional view showing a manufacturing step after the manufacturing step shown in FIG. 12;

FIG. 14 is a cross-sectional view showing a manufacturing step after the manufacturing step shown in FIG. 13;

FIG. 15 is a cross-sectional view showing a manufacturing step after the manufacturing step shown in FIG. 14;

FIG. 16 is a schematic view of a sputtering device;

FIG. 17 is a cross-sectional view showing a manufacturing step after the manufacturing step shown in FIG. 15;

FIG. 18 is a cross-sectional view showing a manufacturing step after the manufacturing step shown in FIG. 17;

FIG. 19 is a cross-sectional view showing a manufacturing step after the manufacturing step shown in FIG. 18;

FIG. 20 is a cross-sectional view showing a manufacturing step after the manufacturing step shown in FIG. 19;

FIG. 21 is a cross-sectional view showing a manufacturing step after the manufacturing step shown in FIG. 20;

FIG. 22 is a cross-sectional view showing a manufacturing step after the manufacturing step shown in FIG. 21;

FIG. 23 is a cross-sectional view showing a manufacturing step after the manufacturing step shown in FIG. 22;

FIG. 24 is a cross-sectional view showing a manufacturing step after the manufacturing step shown in FIG. 23;

FIG. 25 is a cross-sectional view showing a manufacturing step after the manufacturing step shown in FIG. 24;

FIG. 26 is a cross-sectional view showing a manufacturing step after the manufacturing step shown in FIG. 25;

FIG. 27 is a cross-sectional view showing a manufacturing step after the manufacturing step shown in FIG. 26;

FIG. 28 is a cross-sectional view showing a manufacturing step after the manufacturing step shown in FIG. 27 in Embodiment 1;

FIG. 29 is a cross-sectional view showing a manufacturing step after the manufacturing step shown in FIG. 28;

FIG. 30 is a cross-sectional view showing a manufacturing step after the manufacturing step shown in FIG. 29;

FIG. 31 is a cross-sectional view showing a manufacturing step shown in FIG. 30, as seen from the direction crossing FIG. 30;

FIG. 32 is a cross-sectional view showing the manufacturing step shown in FIG. 30 in a peripheral circuit region;

FIG. 33 is a cross-sectional view showing a manufacturing step after the manufacturing step shown in FIG. 30;

FIG. 34 is a cross-sectional view showing the manufacturing step shown in FIG. 33, as seen from the direction crossing FIG. 33;

FIG. 35 is a cross-sectional view showing the manufacturing step shown in FIG. 33 in the peripheral circuit region;

FIG. 36 is a cross-sectional view showing a manufacturing step after the manufacturing step shown in FIG. 33;

FIG. 37 is a cross-sectional view showing the manufacturing step shown in FIG. 36, as seen from the direction crossing FIG. 36;

FIG. 38 is a cross-sectional view showing the manufacturing step shown in FIG. 36 in the peripheral circuit region;

FIG. 39 is a plan view showing the magnetoresistive element and the periphery thereof of FIG. 1 in a semiconductor device of Embodiment 2;

FIG. 40 is a schematic cross-sectional view of a portion along line XL-XL of FIG. 39;

FIG. 41 is a schematic cross-sectional view of a portion along line XLI-XLI of FIG. 39;

FIG. 42 is a schematic cross-sectional view of a modified example of Embodiment 2, as seen from the same direction as for FIG. 40;

FIG. 43 is a schematic cross-sectional view of the modified example of Embodiment 2, as seen from the same direction as for FIG. 41;

FIG. 44 is a cross-sectional view showing a manufacturing step after the manufacturing step shown in FIG. 27 in Embodiment 2;

FIG. 45 is a cross-sectional view showing a manufacturing step after the manufacturing step shown in FIG. 44;

FIG. 46 is a cross-sectional view showing the manufacturing step shown in FIG. 45, as seen from the direction crossing FIG. 45;

FIG. 47 is a cross-sectional view showing a manufacturing step after the manufacturing step shown in FIG. 45;

FIG. 48 is a cross-sectional view showing a manufacturing step shown in FIG. 47, as seen from the direction crossing FIG. 47;

FIG. 49 is a cross-sectional view showing a manufacturing step after the manufacturing step shown in FIG. 47;

FIG. 50 is a schematic cross-sectional view of a semiconductor device of Embodiment 3 as seen from the same direction as for FIG. 3;

FIG. 51 is a schematic cross-sectional view of a portion along line LI-LI of FIG. 50;

FIG. 52 is a cross-sectional view showing a form of a circuit in a peripheral part in a memory cell region including a plurality of magnetoresistive elements disposed therein of the semiconductor device of FIG. 50 in accordance with Embodiment 3;

FIG. 53 is a cross-sectional view showing a manufacturing step after the manufacturing step shown in FIG. 29 in Embodiment 3;

FIG. 54 is a cross-sectional view showing the manufacturing step shown in FIG. 53, as seen from the direction crossing FIG. 53;

FIG. 55 is a cross-sectional view showing a manufacturing step shown in FIG. 53 in the peripheral circuit region;

FIG. 56 is a cross-sectional view showing a manufacturing step after the manufacturing step shown in FIG. 53;

FIG. 57 is a cross-sectional view showing the manufacturing step shown in FIG. 56, as seen from the direction crossing FIG. 56;

FIG. 58 is a cross-sectional view showing a manufacturing step shown in FIG. 56 in the peripheral circuit region;

FIG. 59 is a cross-sectional view showing a manufacturing step after the manufacturing step shown in FIG. 56;

FIG. 60 is a cross-sectional view showing the manufacturing step shown in FIG. 59, as seen from the direction crossing FIG. 59;

FIG. 61 is a cross-sectional view showing the manufacturing step shown in FIG. 59 in the peripheral circuit region;

FIG. 62 is a cross-sectional view showing a manufacturing step after the manufacturing step shown in FIG. 59;

FIG. 63 is a cross-sectional view showing the manufacturing step shown in FIG. 62, as seen from the direction crossing FIG. 62;

FIG. 64 is a cross-sectional view showing the manufacturing step shown in FIG. 62 in the peripheral circuit region;

FIG. 65 is a cross-sectional view showing a manufacturing step after the manufacturing step shown in FIG. 62;

FIG. 66 is a cross-sectional view showing the manufacturing step shown in FIG. 65, as seen from the direction crossing FIG. 65;

FIG. 67 is a cross-sectional view showing a manufacturing step shown in FIG. 65 in the peripheral circuit region;

FIG. 68 is a cross-sectional view showing a manufacturing step after the manufacturing step shown in FIG. 65;

FIG. 69 is a cross-sectional view showing the manufacturing step shown in FIG. 68, as seen from the direction crossing FIG. 68;

FIG. 70 is a cross-sectional view showing the manufacturing step shown in FIG. 68 in the peripheral circuit region;

FIG. 71 is a schematic cross-sectional view of a semiconductor device of Embodiment 4, as seen from the same direction as for FIG. 3;

FIG. 72 is a schematic cross-sectional view of a portion along line LXXII-LXXII of FIG. 71;

FIG. 73 is a cross-sectional view showing a manufacturing step after the manufacturing step shown in FIG. 44 in Embodiment 4;

FIG. 74 is a cross-sectional view showing the manufacturing step shown in FIG. 73, as seen from the direction crossing FIG. 73;

FIG. 75 is a cross-sectional view showing a manufacturing step after the manufacturing step shown in FIG. 73;

FIG. 76 is a cross-sectional view showing the manufacturing step shown in FIG. 75, as seen from the direction crossing FIG. 75;

FIG. 77 is a schematic cross-sectional view of a semiconductor device of Embodiment 5, as seen from the same direction as for FIG. 3;

FIG. 78 is a plan view showing the magnetoresistive element and the periphery thereof of FIG. 1 in a semiconductor device of Embodiment 6;

FIG. 79 is a schematic cross-sectional view of a portion along line LXXIX-LXXIX of FIG. 78;

FIG. 80 is a schematic cross-sectional view of a portion along line LXXX-LXXX of FIG. 78;

FIG. 81 is a cross-sectional view showing a manufacturing step after the manufacturing step shown in FIG. 26 in Embodiment 6;

FIG. 82 is a cross-sectional view showing a manufacturing step after the manufacturing step shown in FIG. 81;

FIG. 83 is a plan view showing the same magnetoresistive element and the periphery thereof as in FIG. 2, in a semiconductor device of Embodiment 7;

FIG. 84 is a schematic cross-sectional view of a portion along line LXXXIV-LXXXIV of FIG. 83;

FIG. 85 is a schematic cross-sectional view of a portion along line LXXXV-LXXXV of FIG. 83;

FIG. 86 is a schematic cross-sectional view of a modified example of Embodiment 7, as seen from the same direction as for FIG. 84;

FIG. 87 is a schematic cross-sectional view of the modified example of Embodiment 7, as seen from the same direction as for FIG. 85;

FIG. 88 is a plan view showing the same magnetoresistive element and the periphery thereof as in FIG. 2, in a semiconductor device obtained by combining the semiconductor device of Embodiment 7 with a sidewall of Embodiment 6;

FIG. 89 is a schematic cross-sectional view of a portion along line LXXXIX-LXXXIX of FIG. 88;

FIG. 90 is a schematic cross-sectional view of a portion along line XC-XC of FIG. 88;

FIG. 91 is a cross-sectional view showing a manufacturing step after the manufacturing step shown in FIG. 27 in Embodiment 7;

FIG. 92 is a cross-sectional view showing a manufacturing step after the manufacturing step shown in FIG. 91;

FIG. 93 is a cross-sectional view showing a manufacturing step shown in FIG. 92, as seen from the direction crossing FIG. 91;

FIG. 94 is a cross-sectional view showing a manufacturing step after the manufacturing step shown in FIG. 92;

FIG. 95 is a cross-sectional view showing the manufacturing step shown in FIG. 94, as seen from the direction crossing FIG. 94;

FIG. 96 is a plan view showing the same magnetoresistive element and the periphery thereof as in FIG. 2, in a semiconductor device of Embodiment 8;

FIG. 97 is a schematic cross-sectional view of a portion along line XCVII-XCVII of FIG. 96;

FIG. 98 is a schematic cross-sectional view of a portion along line XCVIII-XCVIII of FIG. 96;

FIG. 99 is a plan view showing the same magnetoresistive element and the periphery thereof as in FIG. 2, in a semiconductor device of a modified example of Embodiment 8;

FIG. 100 is a schematic cross-sectional view of a portion along line C-C of FIG. 99;

FIG. 101 is a schematic cross-sectional view of a portion along line CI-CI of FIG. 99;

FIG. 102 is a schematic cross-sectional view of a semiconductor device obtained by combining the semiconductor device of Embodiment 8 with the sidewall of Embodiment 6, as seen from the same direction as for FIG. 3; and

FIG. 103 is a schematic cross-sectional view of a portion along line CIII-CIII of FIG. 102.

### DETAILED DESCRIPTION OF THE PREFERRED EMBODIMENTS

Below, embodiments of the present invention will be described by reference to the accompanying drawings.

### Embodiment 1

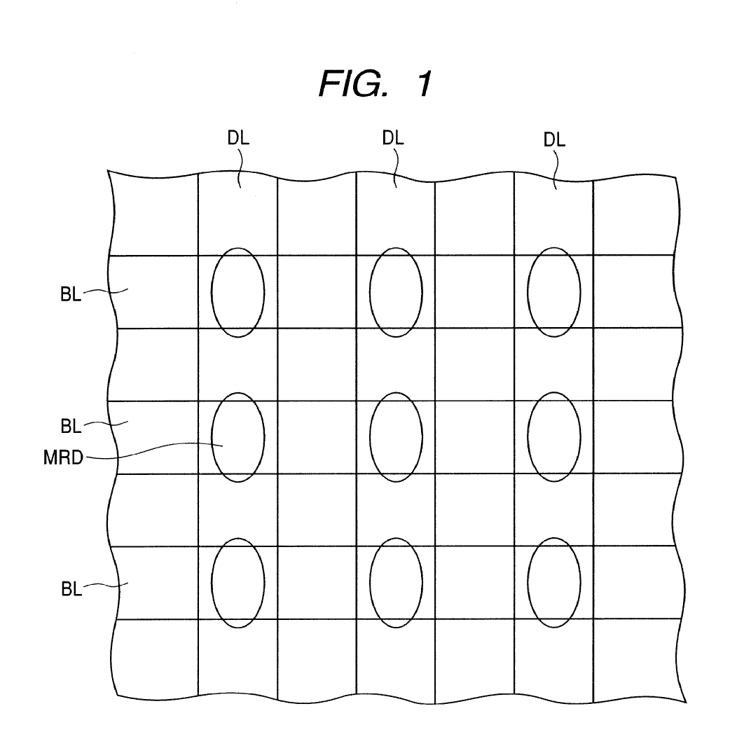

FIG. 1 is a plan view schematically showing a semiconductor device in accordance with Embodiment 1. As shown in FIG. 1, the semiconductor device includes bit lines BL extending in one direction, digit lines DL formed in such a manner as to be located under the bit lines BL, and to cross the bit lines BL, and magnetoresistive elements MRD each formed in a region which is located between the digit line DL and the bit line BL, and in which the digit line DL and the bit line BL cross each other.

The bit lines BL extend in one direction, and are formed in plural number to be spaced apart from each other. The digit lines DL extend in the direction of array of the bit lines BL, and are formed in plural number to be spaced apart from each other in the direction of extension of the bit lines BL. The magnetoresistive elements MRD are each provided at each portion of intersection between the digit line DL and the bit line BL.

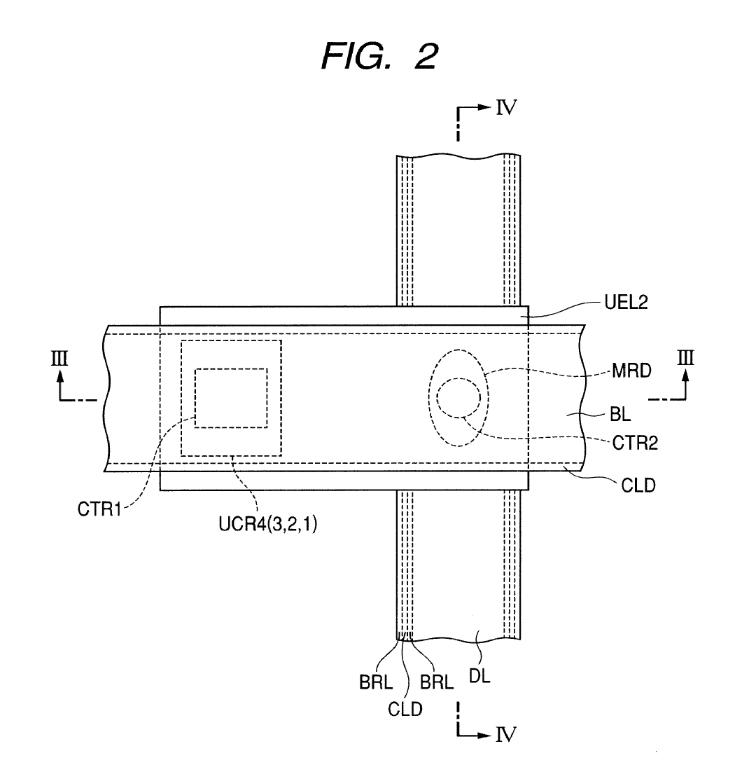

FIG. 2 is a plan view showing the magnetoresistive element MRD and the periphery thereof. As shown in FIG. 2, the magnetoresistive element MRD is formed inside the region in which the digit line DL and the bit line BL cross each other in plan view.

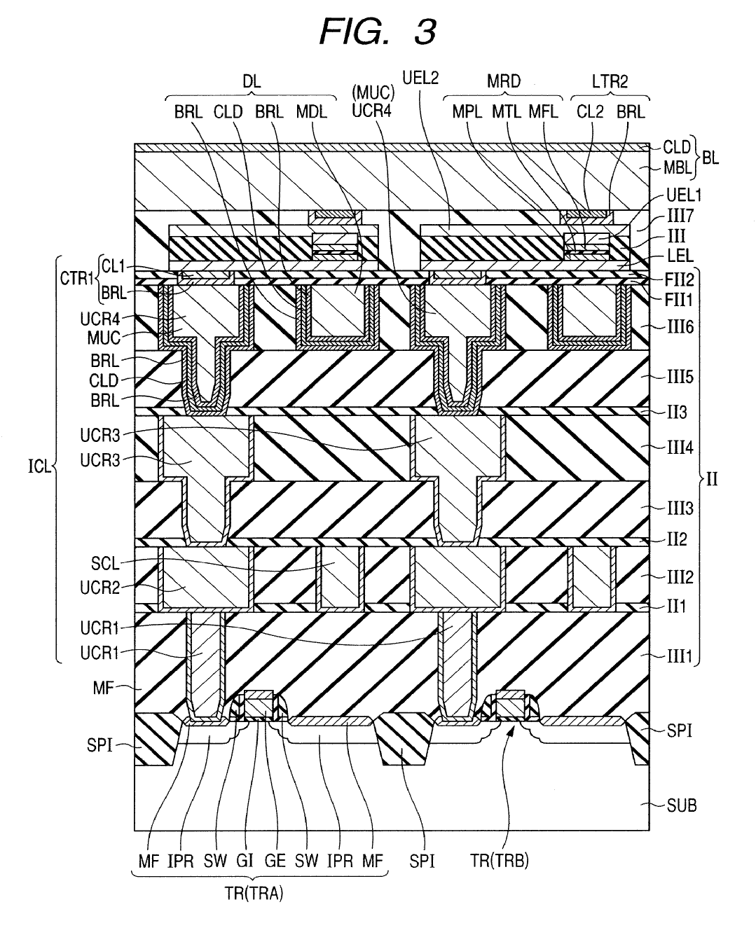

As shown in the cross-sectional view of FIG. 3, the semiconductor device includes a semiconductor substrate SUB, a plurality of MOS transistors (switching elements) TR (TRA and TRB) formed over the main surface of the semiconductor substrate SUB, an interlayer insulation film II including a plurality of insulation films formed in such a manner as to cover the MOS transistors TR, and a flat insulation film FII1 and a flat insulation film FII2 formed over the insulation films, and a lower electrode LEL formed over the top surface of the flat insulation film FII2, and serving as a lead-out wiring. Incidentally, herein, the main surface is a main surface with the largest area of the surfaces. Specifically, the main surface means a surface extending in the horizontal direction crossing the direction of lamination of a plurality of the layers (the vertical direction of FIG. 3).

The semiconductor device includes an interconnection line ICL for coupling the MOS transistors TR and the lower electrodes LEL, and the magnetoresistive elements MRD formed over the lower electrodes LEL. In other words, as shown in FIG. 3, in the semiconductor device, over the main surface of the semiconductor substrate SUB, the magnetoresistive elements MRD are located.

Incidentally, in FIG. 3, two lower electrodes LEL are spaced from each other. Over the top surfaces of the lower electrodes LEL, the magnetoresistive elements MRD are formed. Whereas, under the magnetoresistive elements MRD, the digit lines DL are formed. Over the magnetoresistive elements MRD, the bit lines BL (wirings) are formed.

The digit line DL includes barrier layers BRL and a cladding layer CLD covering the inner side surface, and a digit line main body part MDL including a conductor film filling the inside. Whereas, the bit line BL includes a bit line main body part MBL which is the main body part of the wiring, and a cladding layer CLD covering the side surface (the surface along the direction of extension of the bit line main body part MBL disposed in the vertical direction of FIG. 3) and the top surface (the surface along the direction of extension of the bit line main body part MBL disposed in the lateral direction of FIG. 3). Herein, the barrier layer BRL is, for example, a thin film disposed for inhibiting the mutual diffusion between the digit line main body part MDL and the cladding layer CLD, and the cladding layer CLD is a layer for shielding against the magnetic field.

The passage of currents through the digit line DL and the bit line BL results in the formation of the magnetic fields around the digit line DL and the bit line BL. The synthetic magnetic field of the magnetic field around the digit line DL and the magnetic field around the bit line BL is applied to the magnetoresistive element MRD.

Over the main surface of the semiconductor substrate SUB, a separation insulation film SPI defining an active region is formed. The MOS transistors TR are formed over the active region.

Incidentally, in the cross section shown in FIG. 3, the MOS transistor TRA and the MOS transistor TRB are formed apart from each other.

The MOS transistor TRA includes a channel region formed in the main surface of the semiconductor substrate SUB, impurity regions IPR formed on the opposite sides of the channel region, a gate insulation film GI, and a gate electrode GE formed over the gate insulation film GI. The MOS transistor TRA includes a sidewall SW formed over the side surface of the gate electrode GE, a metal film MF formed over the top surface of each impurity region IPR, and a metal film MF formed over the gate electrode GE.

The impurity region IPR functioning as a drain electrode is coupled with the interconnection line ICL. The other impurity region IPR functions as a source electrode.

The impurity region IPR functioning as a source electrode is coupled with a contact part not shown, which is coupled with a source line SCL formed in the interlayer insulation film II. Incidentally, the MOS transistor TRB is formed similarly to the MOS transistor TRA.

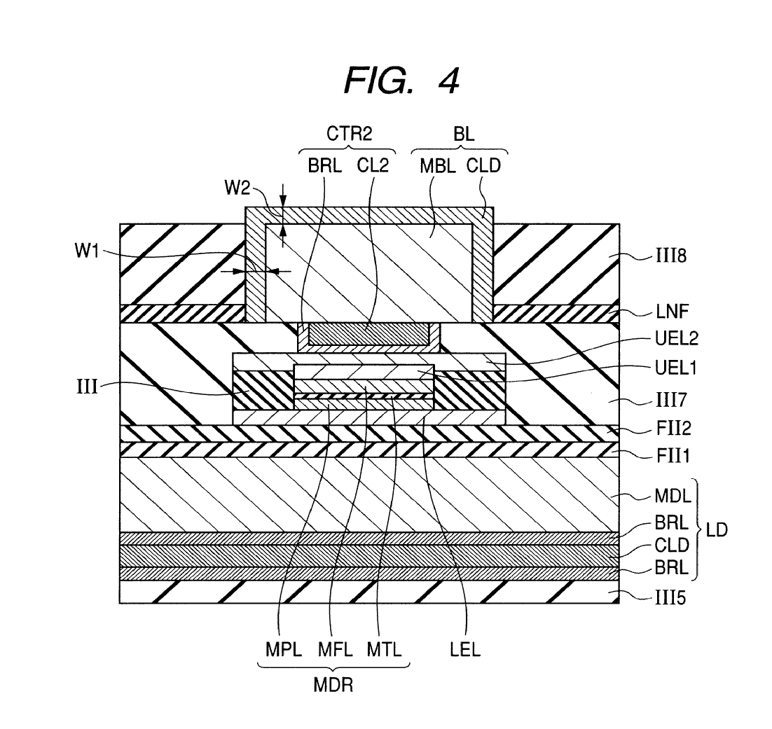

FIG. 4 is a cross-sectional view showing a state of one magnetoresistive element as seen from the direction crossing FIG. 3. With reference to FIGS. 3 and 4, the magnetoresistive element MRD is formed over the main surface of one (top side) of the lower electrode LEL. The magnetoresistive element MRD is formed over the lower electrode LEL, and includes a magnetization pinned layer MPL coupled to the lower electrode LEL, the tunnel insulation film MTL formed over the magnetization pinned layer MPL, and a magnetization free layer MFL formed over the tunnel insulation film MTL. In the left-right direction of FIG. 4, a plurality of the magnetoresistive elements MRD are arranged at given intervals. The cladding layers CLD covering the side surfaces and the top surfaces of the bit lines BL over the tops of respective magnetoresistive elements MRD are electrically separated from each other by, for example, a liner film LNF.

The magnetization free layer MFL is variable in direction of magnetization by action of the magnetic field. The magnetization pinned layer MPL is pinned in magnetization direction, and is formed so as to be kept constant in magnetization direction even when applied with a magnetic field from surroundings.

Over the top surface of the magnetoresistive element MRD, a first upper electrode UEL1 which is a metal film is disposed. Over the first upper electrode UEL1, a second upper electrode UEL2 is disposed. Then, a protective layer III is disposed in such a manner as to cover the side surfaces of the magnetoresistive element MRD and the first upper electrode UEL1, and a region of the bottom side (first upper electrode UEL1 side) of the second upper electrode UEL2. The protective layer III protects the magnetoresistive element MRD in order to inhibit mixing of impurities into the inside of the magnetoresistive element MRD, and etching of the magnetoresistive element MRD during manufacturing of the semiconductor device.

In other words, the first upper electrode UEL1 and the second upper electrode UEL2 are disposed in such a manner as to oppose each other. At both mutually opposing surfaces, both are mechanically coupled (in contact) with each other. Further, the dimensions in plan view of the protective layer III are substantially the same as the dimensions in plan view of the second upper electrode UEL2. Herein, the wording “the dimensions in plan view are substantially the same” includes generally the same plan configuration formed based on the same resist mask, and includes a configuration having an end with a continuous side surface. Incidentally, the meaning of the wording “substantially the same” is assumed to be the same in this specification below.

The first upper electrode UEL1 is substantially the same in dimensions in plan view as the magnetoresistive element MRD. However, the second upper electrode UEL2 is larger in dimensions in plan view than the magnetoresistive element MRD.

Referring to FIGS. 3 and 4, a partial region of the first upper electrode UEL1 is disposed in such a manner as to be embedded in the inside of the second upper electrode UEL2. In other words, the main surface of the first upper electrode UEL1 which is smaller in dimensions in plan view than the second upper electrode UEL2, opposite to the second upper electrode UEL2 is disposed in such a manner as to be inserted into the inside of the second upper electrode UEL2. In still other words, the lowermost surface of the second upper electrode UEL2 is located between the uppermost surface and the lowermost surface of the first upper electrode UEL1 in the vertical direction (thickness direction) of FIG. 3 or 4. Apart of the side surface of the first upper electrode UEL1 crossing the main surface thereof facing the second upper electrode UEL2 is disposed in such a manner as to be in contact with the second upper electrode UEL2.

The lower electrode LEL of the magnetoresistive element MRD and the MOS transistors TR are electrically coupled with each other through unit contact parts UCR1, UCR2, UCR3, and UCR4, and a contact part CTR1. Further, the second upper electrode UEL2 formed over the top surface of the magnetoresistive element MRD and the bit line BL are electrically coupled with each other by a contact part CTR2. In other words, the second upper electrode UEL2 and the wiring (bit line BL) are apart from each other. Both are coupled with each other by the contact part CTR2 disposed in a region sandwiched between the second upper electrode UEL2 and the bit line BL.

The unit contact parts UCR1, UCR2, UCR3, and UCR4 are formed in such a manner as to penetrate through the layers such as an insulation layer III1 forming the interlayer insulation film II in the vertical direction of FIG. 3. Out of these, in the unit contact parts UCR1, UCR2, and UCR3, one layer of a barrier layer is formed over the inner wall surface of the hole forming each unit contact part. The inside of the hole is filled with a conductive layer. In contrast, in the unit contact part UCR4, as with the digit line DL, three layers of a barrier layer BRL, a cladding layer CLD, and a barrier layer BRL are stacked over the inner wall surface sequentially from the outside. The inside of the hole is filled with a conductive layer.

The contact part CTR1 is formed in such a manner as to penetrate through the flat insulation film FII1 and the flat insulation film FII2 in the vertical direction of FIG. 3. Over the inner wall surface of the hole forming the contact part CTR1, a barrier layer BRL is formed. A conductive layer CL1 is formed in such a manner as to fill the inside of the contact part CTR1 including the barrier layer BRL formed therein. Similarly for the contact part CTR2, a conductive layer CL2 is formed in such a manner as to fill the inside of the contact part CTR2 with the inner wall surface covered with a barrier layer BRL.

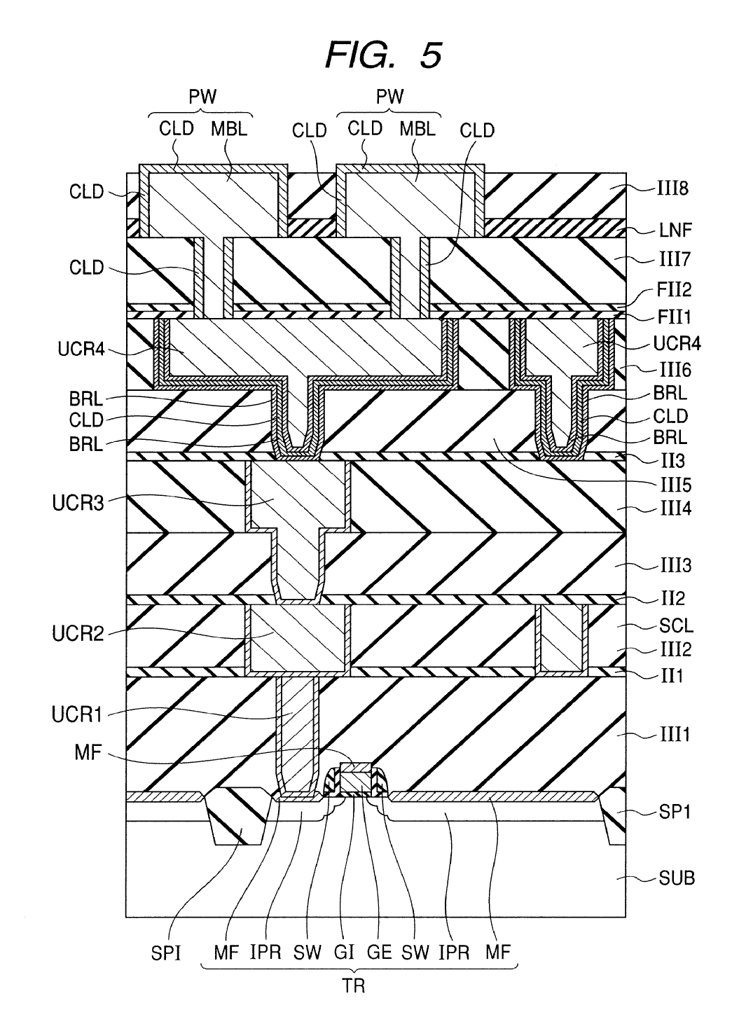

FIGS. 3 and 4 each show a region (memory cell region) in which a plurality of the magnetoresistive elements MRD forming the semiconductor device are arranged. Around the memory cell region in plan view, there exists, for example, a peripheral circuit part for selecting each memory unit and performing reading and writing of data, or supplying electrical information or a current to external devices via electrode pads. FIG. 5 is a cross-sectional view of a partial region of the peripheral circuit cut in the same direction as for FIG. 4.

Referring to FIGS. 5 and 3, in the semiconductor device of the present embodiment, together with the memory cell region and the peripheral circuit region, there are formed conductive layers such as the unit contact parts UCR1, UCR2, and UCR3 formed in such a manner as to penetrate through a plurality of insulation films II1, II2, and II3, and insulation layers III1 and III2, and the like. This is a member for establishing conduction between the semiconductor substrate SUB and the bit line BL (wiring PW). For example, each wiring PW formed in such a manner as to penetrate through the insulation layers III7 and III8 in the peripheral circuit region is similar in shape to the unit contact part, and is a wiring to be formed simultaneously with the bit line BL in the memory cell region of FIGS. 3 and 4. Supply of a current to each wiring PW in the peripheral circuit region is performed through the underlying unit contact parts UCR4 and UCR3, and the like. For the wiring PW in the peripheral circuit region, a cladding layer CLD is formed in such a manner as to cover the side surface (surface extending in the vertical direction of FIG. 5) of the surfaces of the inside thereof and the uppermost part of the wiring PW.

Further, although omitted in FIGS. 3, 4, and 5, another insulation layer is further formed over the top of the insulation layer III8. Particularly, in a partial region of the peripheral circuit region, over the top of the insulation layer, external loads such as electrode pads may be disposed. In this case, the external loads are electrically coupled with the peripheral circuits. Control by switching elements (MOS transistors TR) in the peripheral circuits establishes electrical coupling between the semiconductor device and external devices, which enables free control thereof.

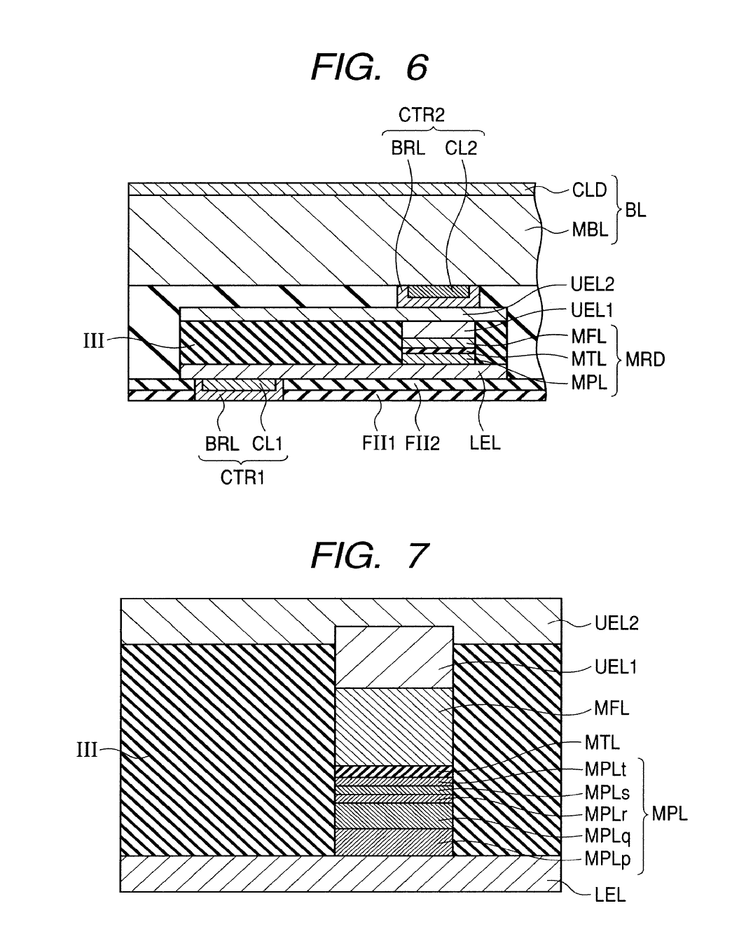

Incidentally, in the present embodiment, as described with reference to FIGS. 3 and 4, the first upper electrode UEL1 may be disposed in such a manner as to be inserted into the inside of the second upper electrode UEL2. However, as shown in FIG. 6, the first upper electrode UEL1 and the second upper electrode UEL2 may be mechanically and electrically coupled with each other such that the first upper electrode UEL1 is not inserted into the inside of the second upper electrode UEL2, and such that the mutual main surfaces are in contact with each other.

Herein, a description will be particularly given to the materials and dimensions of the magnetoresistive element MRD, and the upper electrode and the lower electrode described up to this point.

The lower electrode LEL preferably includes, for example, Ta (tantalum), TaN (tantalum nitride), Ru (ruthenium), or TiN (titanium nitride). Further, the lower electrode LEL may include one layer, or may include a plurality of thin films including the foregoing different materials stacked therein. The thickness of the lower electrode LEL (in the vertical direction of FIGS. 3 and 4) is preferably, for example, 10 nm or more and 70 nm or less, and in particular preferably 20 nm or more and 50 nm or less (as one example, 35 nm).

The upper electrode also similarly preferably includes Ta, TaN, Ru, or TiN as with the lower electrode LEL. The first upper electrode UEL1 and the second upper electrode UEL2 may include the same material, or may include different materials, respectively. However, more preferably, the first upper electrode UEL1 includes Ta, and the second upper electrode UEL2 includes any of Ta, TaN, W (tungsten), and TiN. The thickness of the first upper electrode UEL1 is preferably, for example, 30 nm or more and 70 nm or less, and especially preferably 35 nm or more and 65 nm or less (as an example, 60 nm). Whereas, the thickness of the second upper electrode UEL2 is preferably, for example, 5 nm or more and 100 nm or less.

The magnetization pinned layer MPL is shown as one layer in FIGS. 3 and 4. However, generally, for the magnetization pinned layer MPL, there is used a two-layer structure in which a ferromagnetic layer is stacked over an antiferromagnetic layer, a 4-layer structure in which over an antiferromagnetic layer, a ferromagnetic layer, a non-magnetic layer, and a ferromagnetic layer are sequentially stacked in this order, a 5-layer structure, or the like. However, the number of stacked layers, the order of stacked layers, and the like are not limited thereto.

For example, when the magnetization pinned layer MPL is in a 5-layer structure, as shown in FIG. 7, it is preferable that a seed layer MPLp, an antiferromagnetic layer MPLq, a ferromagnetic layer MPLr, a non-magnetic layer MPLs, and a ferromagnetic layer MPLt are stacked in this order from the bottom side.

The seed layer MPLp is preferably a metal film including an alloy of Ta, Ru, or Ni (nickel), and Fe (iron). Alternatively, the seed layer MPLp may be a metal film including an alloy of Ni, Fe, and Cr (chromium). Further alternatively, the seed layer MPLp may be formed of a lamination of a plurality of metal films including the various alloys. The total thickness of the seed layer MPLp is preferably 0.5 nm or more and 10 nm or less, and especially more preferably 1.0 nm or more and 8.5 nm or less.

The antiferromagnetic layer MPLq is preferably a metal film including any of an alloy of Pt (platinum) and Mn (manganese), an alloy of Ir (iridium) and Mn (manganese), and an alloy of Ru and Mn. The thickness thereof is preferably 10 nm or more and 30 nm or less, and especially more preferably 12 nm or more and 25 nm or less.

The ferromagnetic layer MPLr is preferably a film of a metal elemental substance or an alloy including one or more selected from a group consisting of Ni, Co (cobalt), Fe, and B (boron). Alternatively, the ferromagnetic layer PMLr may include a lamination of a plurality of alloy layers of an appropriate combination of these materials. The total thickness of the ferromagnetic layer MPLr is preferably 1.2 nm or more and 3.0 nm or less, and more preferably 1.5 nm or more and 2.5 nm or less.

The non-magnetic layer MPLs is preferably a metal film including Ru, and having a thickness of 0.4 nm or more and 1.0 nm or less. Incidentally, the thickness of the non-magnetic layer MPLs is more preferably 0.6 nm or more and 0.9 nm or less.

Further, the ferromagnetic layer MPLt preferably includes the same material as that for the ferromagnetic layer MPLr. Further, the thickness thereof is preferably set at a film thickness such that the magnetization amount is roughly the same as that for the ferromagnetic layer MPLr.

The tunnel insulation film MTL is preferably an insulation film including any of AlOₓ (aluminum oxide), MgO (magnesium oxide), and HfO (hafnium oxide). The thickness thereof is preferably 0.5 nm or more and 2.0 nm or less, and especially more preferably 0.6 nm or more and 1.5 nm or less.

The magnetization free layer MFL is preferably a thin film including a ferromagnetic layer. Specifically, the magnetization free layer MFL is preferably a film of a metal elemental substance or an alloy including one or more selected from a group consisting of Ni, Co, Fe, B, and Ru. Alternatively, the magnetization free layer MFL may include a lamination of a plurality of the films including alloys of the different materials. The total thickness thereof is preferably 2.0 nm or more and 10 nm or less, and is more preferably 3.0 nm or more and 9.0 nm or less.

Then, as the barrier layers BRL present extensively in the semiconductor device, there is preferably used a thin film of non-magnetic tantalum, or TaN (tantalum nitride) obtained by adding nitrogen thereto.

Further, as the cladding layer CLD, there is preferably used a soft magnetic material with a high magnetic permeability and a very low residual magnetization. Specifically, there is preferably used an alloy such as NiFe (iron-nickel), NiFeMo, CoNbZr (cobalt-niobium-zirconium), CoFeNb, CoFeSiB, CoNbRu, CoNbZrMoCr, or CoZrCrMo, or an amorphous alloy thereof. Incidentally, as described later, particularly, the thickness of the cladding layer CLD at the side surface of the bit line BL is preferably larger than the thickness of the cladding layer CLD at the top surface of the bit line BL.

The liner film LNF is disposed in such a manner as to couple the adjacent memory units in the left-right direction of FIG. 4. For this reason, the liner film LNF preferably includes a dielectric substance (insulator) material such as SiN, SiC, SiON, or SiOC as distinct from the barrier layer BRL and the like.

The barrier layer BRL is a conductor material, and hence the adjacent memory units are required to be separated from each other. Further, the liner film LNF is a dielectric substance material, and hence the adjacent memory units are preferably coupled with each other. When the foregoing conditions are satisfied, as the barrier layer, a conductor material may be used, or a dielectric substance material may be used. Alternatively, both may be combined.

Then, the protective layer III covering the side surface of the magnetoresistive element MRD is preferably formed of, for example, SiN (silicon nitride film). However, the protective layer III may be formed of SiO₂, AlOₓ, or SiON in place of SiN.

Then, a description will be given to the operation principle of the semiconductor device having the foregoing configuration. A desired MOS transistor TR is selected, and the switch is turned ON. Then, conduction is established throughout from the MOS transistor to the overlying unit contact parts, contact parts, lower electrode LEL, magnetoresistive element MRD, upper electrode, and bit line BL. Thus, a current is passed through the desired digit line DL (digit line main body part MDL) and bit line BL (bit line main body part MBL). This results in a change in directions of magnetization of the magnetization free layers MFL of all the magnetoresistive elements MRD continuous thereto.

At this step, when the current flowing through the digit line DL or the bit line BL (or the magnetic field formed by the current) is smaller than the current necessary for reversal of the direction of magnetization, after switching off the current, the directions of magnetization of the magnetization free layers MFL of all the magnetoresistive elements MRD continuous to the digit line DL or the bit line BL return to the state before passing the current. This means the case where the magnetic field formed by the current is smaller than the magnetic field necessary for reversal of the direction of magnetization of the magnetization free layer MFL.

However, when the current is larger than the current necessary for reversal of the direction of magnetization of the magnetization free layer MFL, after switching off the current, the directions of magnetization of the magnetization free layers MFL of all the magnetoresistive elements MRD continuous to the digit line DL and the bit line BL are rendered in the reversed state. This means the case where the magnetic field formed by the current is larger than the magnetic field necessary for reversal of the direction of magnetization of the magnetization free layer MFL.

Making use of the characteristics described up to this point, first, to any one of the digit line DL or the bit line BL, a smaller current (first current) than the current necessary for reversal of the direction of magnetization of the magnetization free layer MFL is passed. Then, in the sate, out of the digit line DL or the bit line BL, to the other different from the foregoing one, a proper current (second current) is passed.

Herein, the term “proper current” means a current value necessary for making the synthetic magnetic field formed by the first current and the second current larger than the magnetic field necessary for reversal of the direction of magnetization of the magnetization free layer MFL of the magnetoresistive element MRD in only a region of intersection of the wirings for passing the first current and the second current therethrough.

With this configuration, in only the magnetoresistive elements MRD in the region of intersection of the digit line DL and the bit line BL through which the currents have passed, the direction of magnetization of each magnetization free layer MFL is reversed. As a result, data is rewritten. In other words, for rewriting data, selection and rewriting of the magnetoresistive element MRD to be rewritten are simultaneously carried out.

Specifically, the direction of magnetization of the magnetization free layer MFL becomes the same direction as the direction of magnetization of the magnetization pinned layer MPL. Alternatively, the direction of magnetization of the magnetization free layer MFL becomes the opposite direction to the direction of magnetization of the magnetization pinned layer MPL. Between the time when the direction of magnetization of the magnetization free layer MFL and the direction of magnetization of the magnetization pinned layer MPL are in agreement and the time when the direction of magnetization of the magnetization free layer MFL and the direction of magnetization of the magnetization pinned layer MPL are opposite to each other, the electrical resistance of the magnetoresistive element MRD changes. The difference in resistance value is utilized as information corresponding to “0” or “1”

For reading the information of the selected magnetoresistive elements MRD, the MOS transistors TR coupled to the selected magnetoresistive elements MRD are turned ON.

Then, a voltage is applied so as to pass through the MOS transistors TR and the bit line BL. Thus, the resistance value of each selected magnetoresistive element MRD is detected. As a result, the electrical information stored in the magnetoresistive element MRD can be read.

Then, a description will be given to a method for manufacturing a semiconductor device of the present embodiment. First, a step of preparing an underlying wiring is carried out. Specifically, this is a step of preparing a semiconductor substrate having a main surface, or a step of forming an underlying circuit for forming a memory unit over the main surface of the semiconductor substrate.

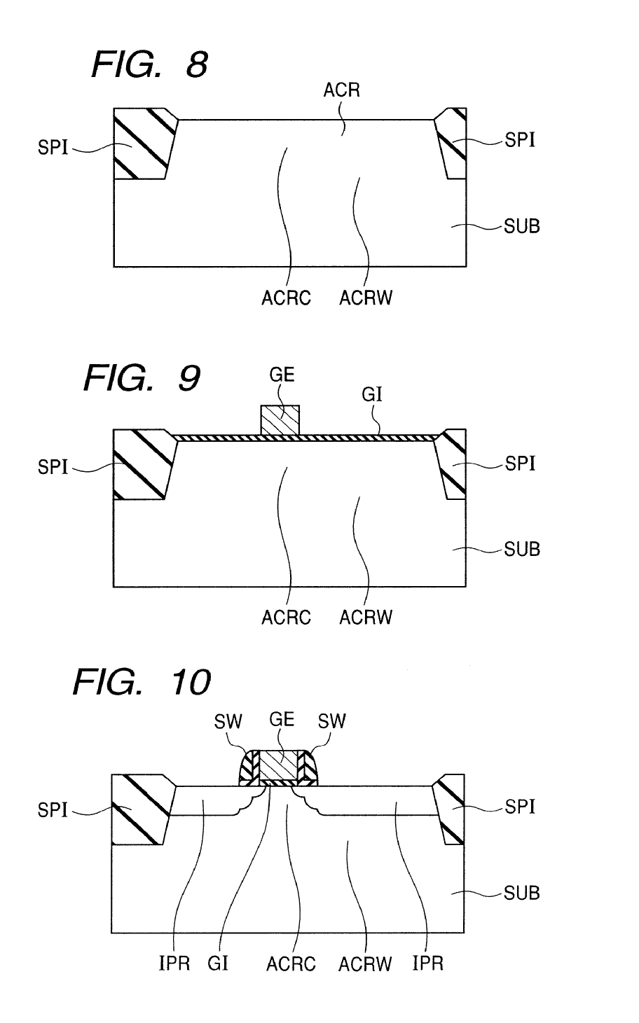

FIGS. 8 to 15 and FIGS. 17 to 23 are each a cross-sectional view showing the form in each process, as seen from the same direction as for FIG. 3. As shown in FIG. 8, a semiconductor substrate SUB having a main surface is prepared. Over the main surface of the semiconductor substrate SUB, a separation insulation film SPI is formed. The separation insulation film SPI forms an active region ACR over the main surface of the semiconductor substrate SUB.

Then, with an ion implantation method or the like on the active region, impurities are introduced into the active region, thereby to successively form a well region ACRW and a channel region ACRC.

As shown in FIG. 9, with a thermal oxidation treatment method, over the main surface of the channel region ACRC, a gate insulation film GI is formed. Then, a polycrystalline silicon film, and the like are deposited. The polycrystalline silicon film and the like are patterned, thereby to form the gate electrode GE over the gate insulation film GI.

Then, as shown in FIG. 10, using the gate electrode GE as a mask, impurities of a prescribed conductivity type are introduced into the active region ACR. Further, over the side surface of the gate electrode GE, an insulation film such as a silicon oxide film is formed. After formation of the insulation film, again, impurities are introduced into the active region ACR.

After second introduction of impurities, an insulation film such as a silicon oxide film or a silicon nitride film is deposited. The deposited insulation film is dry etched, thereby to form a sidewall SW. After formation of the sidewall SW, again, impurities are introduced into the channel region ACRC. As a result, an impurity region IPR functioning as source or drain is formed.

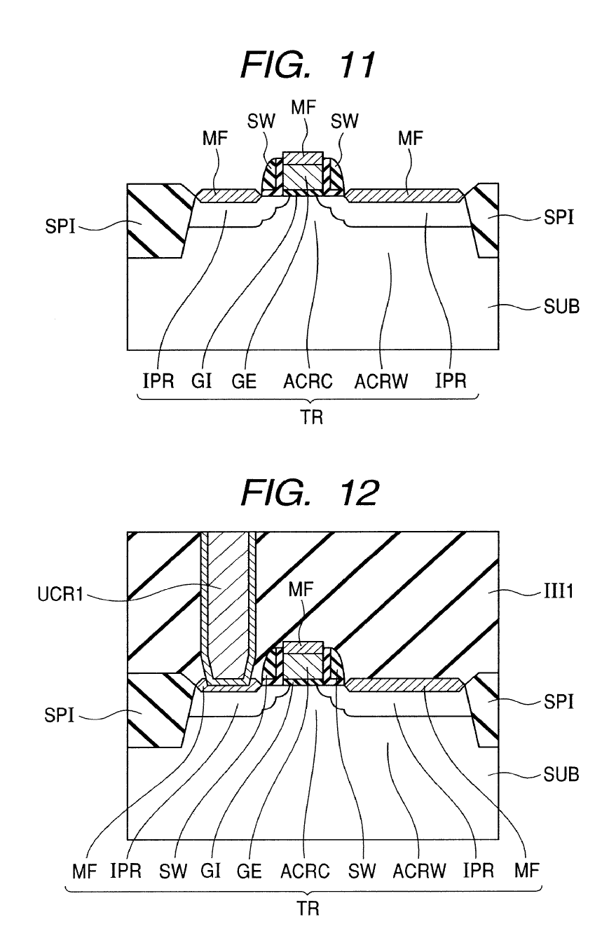

As shown in FIG. 11, a metal film is formed by sputtering, and then, is patterned. As a result, over the top surface of each impurity region IPR and the top surface of the gate electrode GE, a metal film MF is formed, resulting in formation of the MOS transistor TR.

As shown in FIG. 12, after formation of the MOS transistor TR, for example, an insulation layer III1 formed of a silicon oxide film or the like is formed in such a manner as to cover the MOS transistor TR.

The formed insulation layer III1 is subjected to photolithography and etching, thereby to form a contact hole. The contact hole is formed in such a manner as to reach the metal film MF formed over the impurity region IPR.

Then, by sputtering or the like, over the inner surface of the contact hole, a barrier layer is formed. After formation of the barrier layer, a conductive film such as copper is filled in the contact hole. The conductive film is subjected to a CMP (Chemical Mechanical Polishing) treatment. As a result, the unit contact part UCR1 is formed.

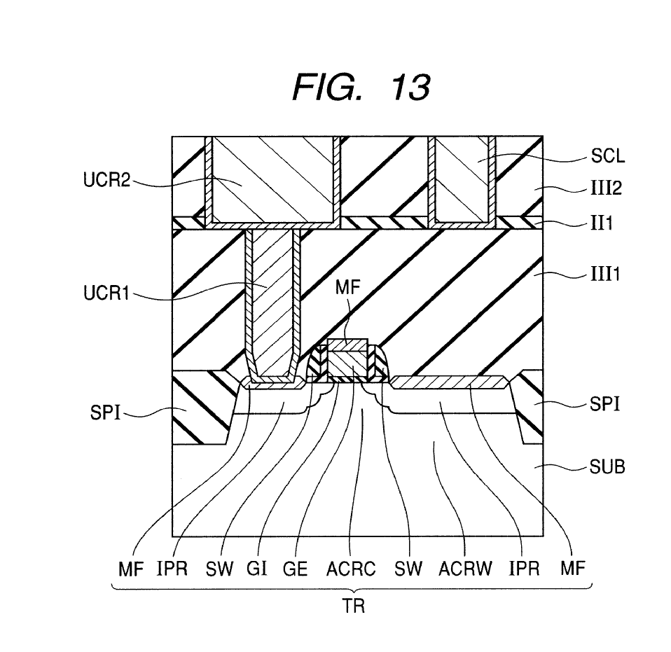

Then, as shown in FIG. 13, over the top surface of the insulation layer III1, the insulation film II1 and the insulation layer III2, are successively formed. Then, in the insulation layer III2, and the insulation film II1, groove parts are formed. In each formed groove part, a barrier layer is formed, and a conductive film is filled therein. The conductive film is planarized. As a result, in the insulation layer III2, and the insulation film III, the unit contact part UCR2 and the source line SCL are formed, respectively.

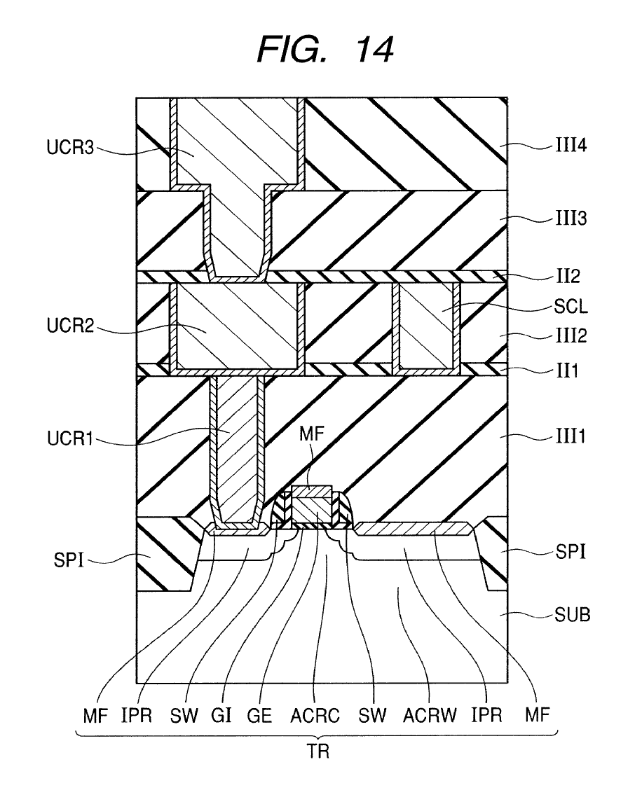

Then, as shown in FIG. 14, the insulation film II2, and the insulation layers III3 and III4 are successively formed. Then, in the insulation film II2, and the insulation layers III3 and III4, a hole part is formed. A barrier layer is formed over the inner surface of the hole part. Over the barrier layer, a conductive film is filled, and the conductive film is planarized. As a result, the unit contact part UCR3 is formed.

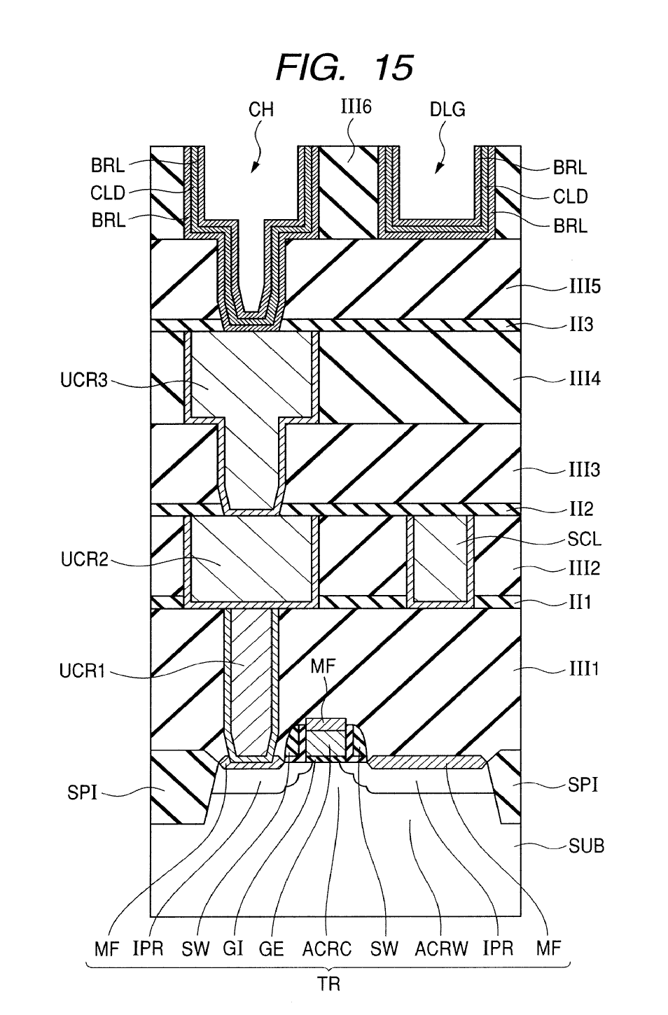

As shown in FIG. 15, over the top surface of the insulation layer III4, an insulation film II3, and insulation layers III5 and III6 are successively formed. Then, in the insulation film II3, and the insulation layers III5 and III6, a contact hole CH is formed. In addition, in the insulation layer III6, a digit-line groove part DLG is formed.

Then, in the contact hole CH, a barrier layer BRL is formed. In addition, over the inner surface of the digit-line groove part DLG, a barrier layer BRL is formed.

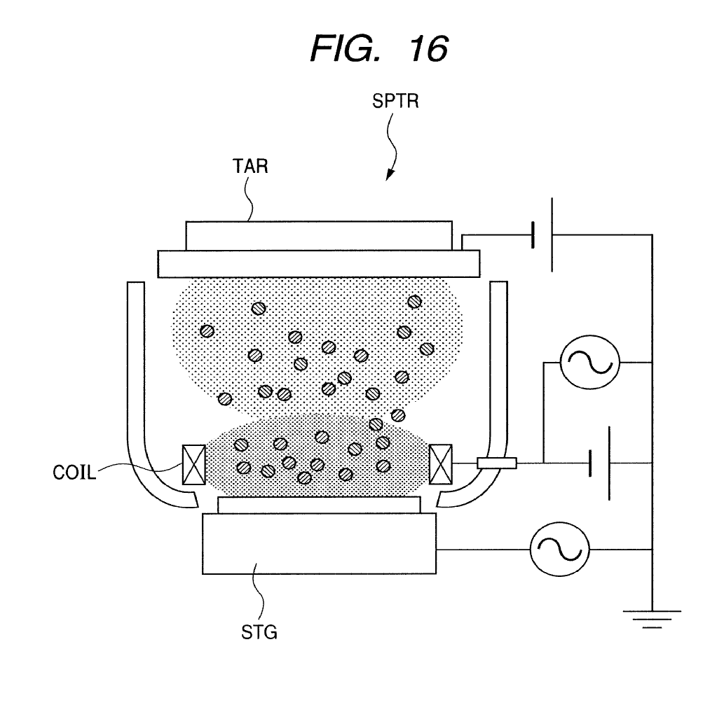

The barrier layer BRL is deposited using a sputtering device SPTR shown in FIG. 16. The sputtering device SPTR includes a stage STG which is disposed in a chamber, and over the top surface of which a semiconductor substrate during a manufacturing process is disposed, a target TAR on which a target is disposed, a direct-current coil COIL, and a high-frequency coil.

Then, by the magnetic force generated from the direct-current coil COIL and the high-frequency coil, the directivity of particles in the chamber can be adjusted.

When the barrier layer BRL is formed, the stage STG is applied with an AC power of, for example, about 200 W to 230 W. Then, the side coverage ratio of the barrier layer BRL can be increased.

Herein, with reference to the deposition rate for deposition over the top surface of the insulation layer III6 shown in FIG. 15, the term “side coverage ratio” is the ratio of the deposition rate for deposition over the inner side surfaces of the contact hole CH and the digit-line groove part DLG to the deposition rate.

After formation of the barrier layer BRL, the cladding layer CLD shown in FIG. 15 is formed. When the cladding layer CLD is formed, the high-frequency coil is applied with an electric power of, for example, about 2000 W. The direct-current coil COIL is applied with an electric power of, for example, about 0 W to 500 W. Further, the pressure in the chamber is set at about 0.2 Pa. Further, the target TAR and the stage STG are applied with a prescribed electric power.

Under the foregoing conditions, the cladding layer is formed. As a result, the deposition rate for deposition over the inner side surface of the barrier layer BRL is higher than the deposition rate for deposition over the bottom of the barrier layer BRL.

Namely, the side coverage ratio for forming the cladding layer is higher than the side coverage ratio for forming the barrier layer BRL.

Incidentally, the side coverage ratio for forming the cladding layer CLD is, with reference to the deposition rate of the cladding layer CLD formed over the top surface of the insulation layer III6, the ratio of the deposition rate of the cladding layer formed over the inner side surface of the barrier layer BRL to the deposition rate. As a result, the thickness of the sidewall part of the cladding layer CLD formed is larger than the thickness of the bottom wall part. Such formation can inhibit the reduction of the cross-sectional area of the digit line main body part MDL. This can inhibit the excessive increase in electrical resistance of the digit line main body part MDL.

Thus, after formation of the cladding layer CLD, the barrier layer BRL is formed over the top surface of the cladding layer CLD. Incidentally, the deposition conditions for the barrier layer BRL herein are assumed to be the same conditions as the deposition conditions for forming the barrier layer BRL (formed before formation of the cladding layer CLD).

After formation of the barrier layer BRL, a conductive film such as copper is filled over the barrier layer BRL. The filled conductive film is a contact main body part MUC for forming the unit contact part UCR4, and is a digit line main body part MDL for the digit line DL.

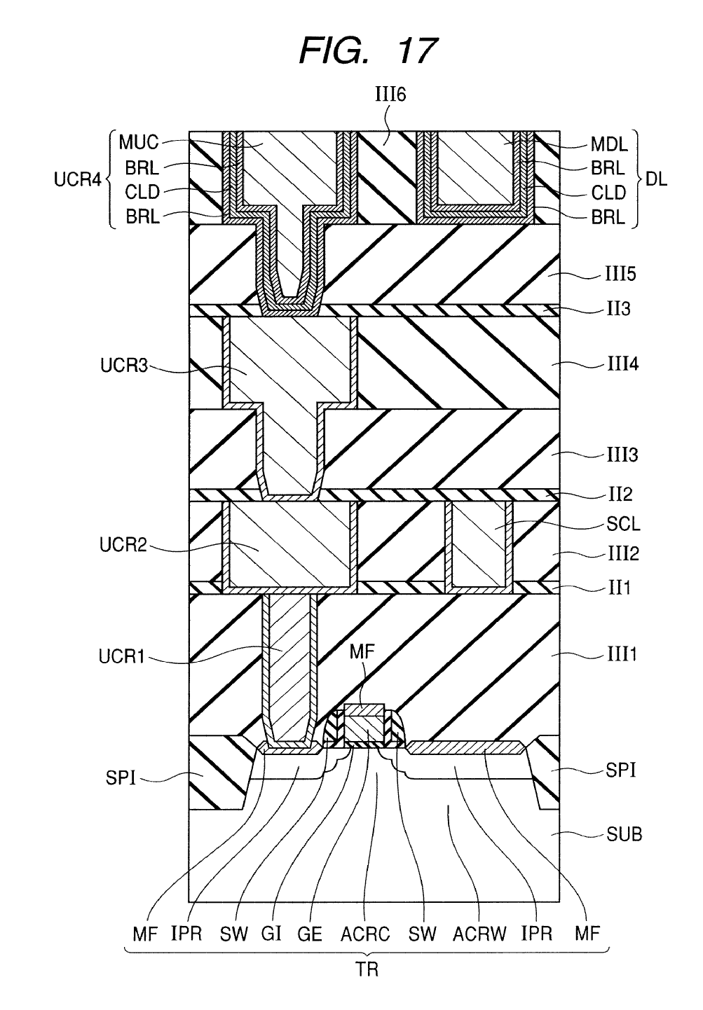

After filling of the conductive film, as shown in FIG. 17, by a CMP method, the top surface of the insulation layer III6 is planarized. As a result, the unit contact part UCR4 and the digit line DL are formed. Then, simultaneously with the formation of the digit line DL, the unit contact part UCR4 can be formed.

Thus, the insulation layer III1, the insulation film II1, the insulation layer III2, the insulation film II2, the insulation layer III3, the insulation layer III4, the insulation film II3, the insulation layer III5, and the insulation layer III6 are successively stacked, thereby to form the interlayer insulation film II.

Further, the unit contact parts UCR1, UCR2, UCR3, and UCR4 are successively formed, thereby to form the interconnection line ICL.

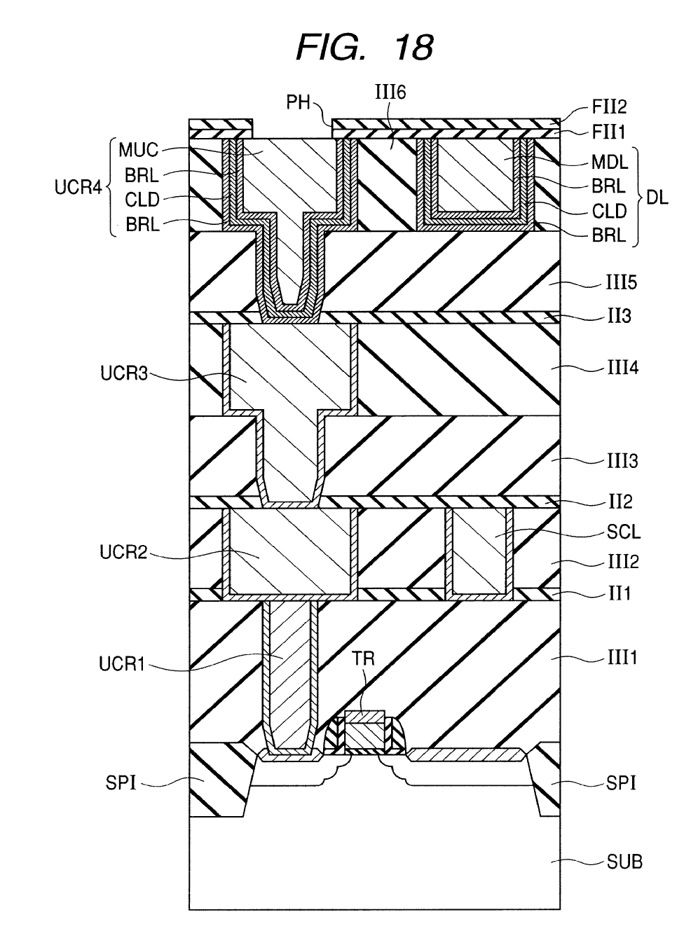

Then, as shown in FIG. 18, over the top surface of the insulation layer III6, the insulation film FII1 formed of a silicon nitride film (SiN) or the like is formed. Over the top surface of the insulation film FII1, the insulation film FII2 formed of a silicon oxide film (SiO₂) or the like is formed. Through the insulation films, a penetration hole PH is formed.

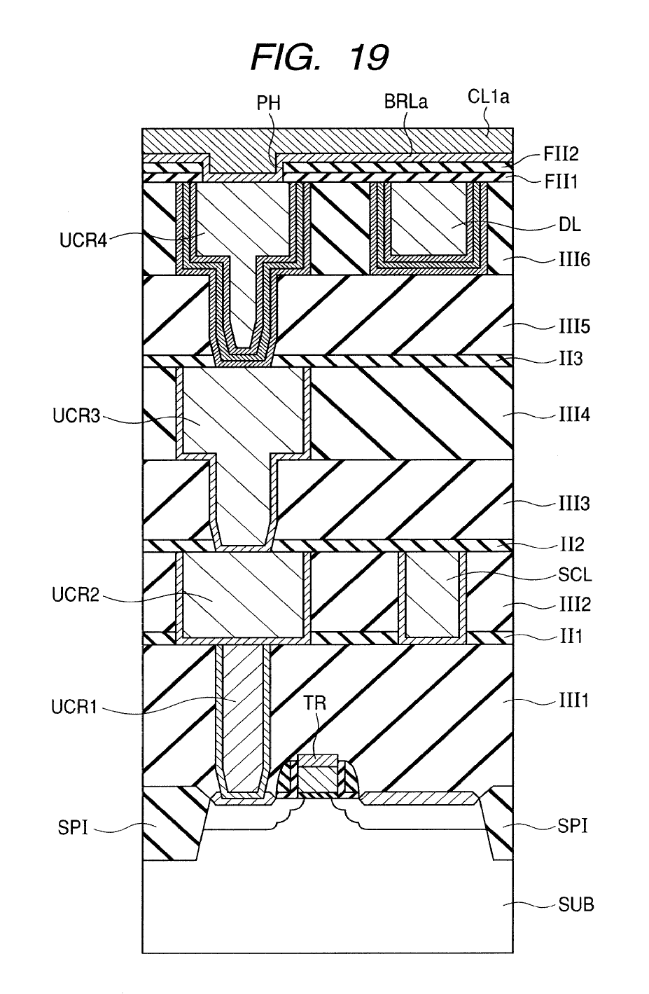

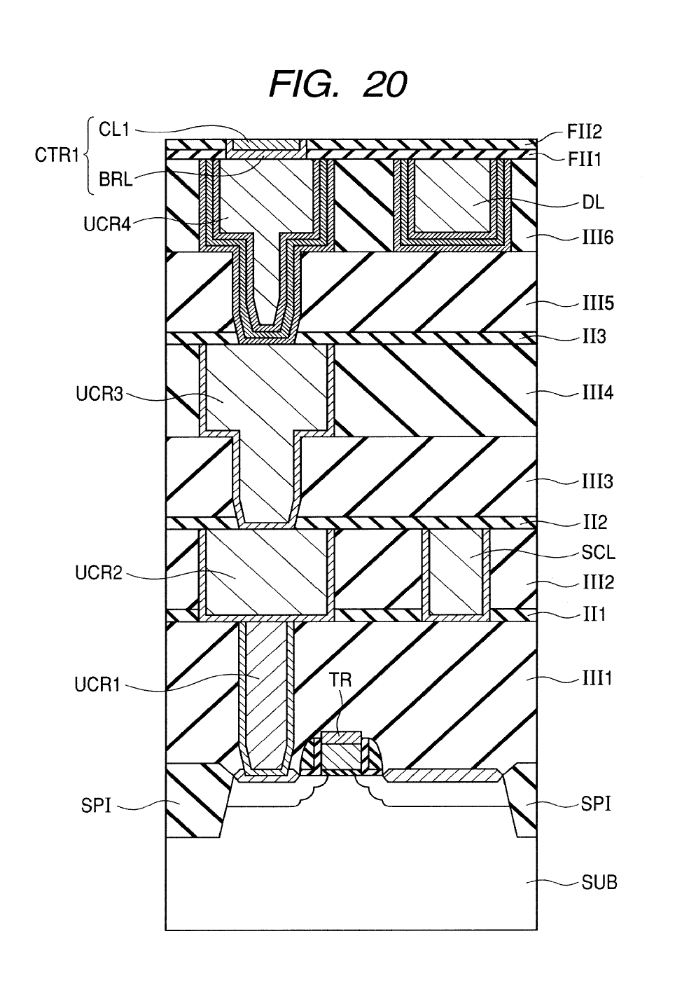

Then, as shown in FIG. 19, over the insulation films FII1 and FII2 and the inner circumferential surface of the penetration hole PH, a barrier layer BRLa is formed. Over the barrier layer BRLa, a conductive film CL1a is deposited.

Then, as shown in FIG. 20, by a CMP method, using the insulation film FII1 as a stopper film, portions of the barrier layer BRLa and the conductive film CL1a formed over the insulation film FII2 are removed.

As a result, the contact part CTR1 including the barrier layer BRL and the conductive layer CL1 is formed. On the other hand, the top surfaces of the insulation films FII1 and FII2 are planarized, resulting in formation of the flat insulation films FII1 and FII2.

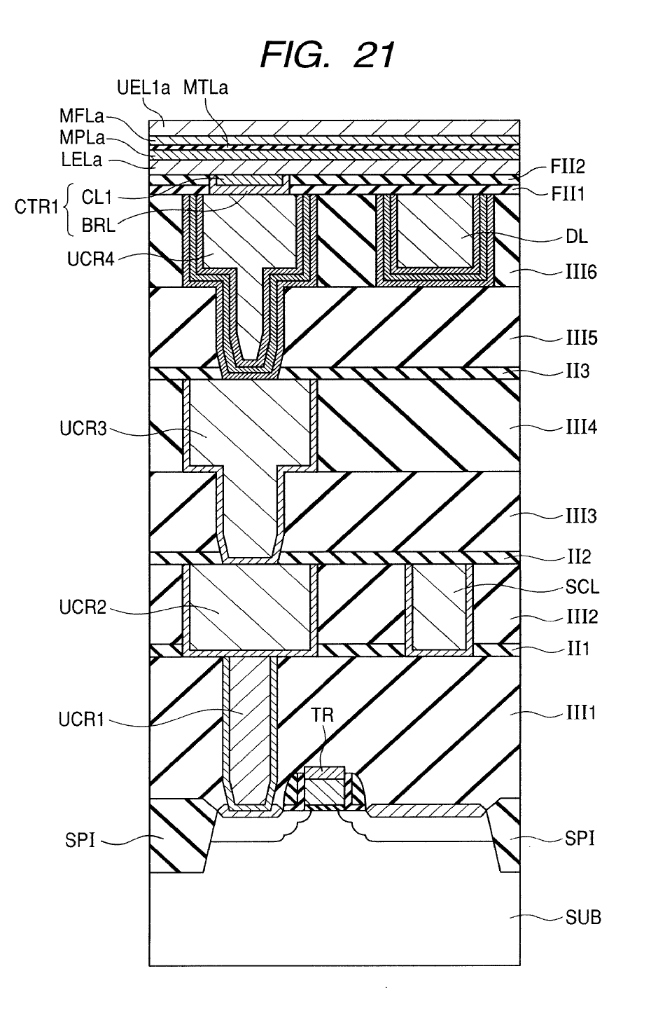

Then, as shown in FIG. 21, over the flat insulation film FII2 (contact part CTR1), a conductive film LELa is formed. Over the conductive film LELa, a conductive film MPLa, an insulation film MTLa, a conductive film MFLa, and a conductive film UEL1a are formed in this order. The conductive film. LELa is a layer to be the lower electrode LEL. The conductive film MPLa, the insulation film MTLa, the conductive film MFLa, and the conductive film UEL1a are layers to be the magnetization pinned layer MPL, the tunnel insulation film MTL, the magnetization free layer MFL, and the first upper electrode UEL1, respectively. Therefore, the materials forming the respective layers, and the thicknesses thereof are preferably set to be the materials and thicknesses of the layers to be formed such as the lower electrode LEL and the magnetization pinned layer MPL, respectively.

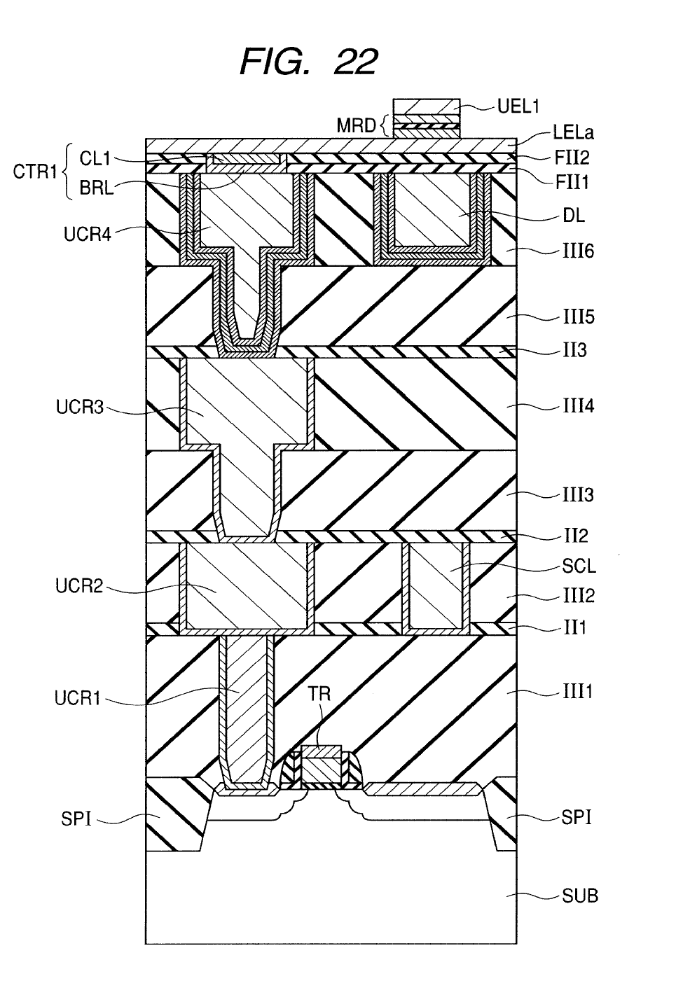

As shown in FIG. 22, the conductive film MPLa, the insulation film MTLa, the conductive film MFLa, and the conductive film UEL1a are patterned using a resist pattern not shown as a mask. As a result, the magnetoresistive element MRD and the first upper electrode UEL1 formed over the top surface of the magnetoresistive element MRD are formed.

Further, the magnetoresistive element MRD may be formed in the following manner. First, by using a resist pattern not shown as a mask, only the conductive film UEL1a is patterned to form the first upper electrode LEL1. Then, the resist pattern is removed. Then, by using the first upper electrode UEL1 as a mask, the conductive film MPLa, the insulation film MTLa, and the conductive film MFLa are patterned. This results in the formation of the magnetoresistive element MRD and the first upper electrode UEL1 formed over the top surface of the magnetoresistive element MRD. In this process, patterning is performed so that the first upper electrode UEL1 is substantially the same in dimensions in plan view as the magnetoresistive element MRD.

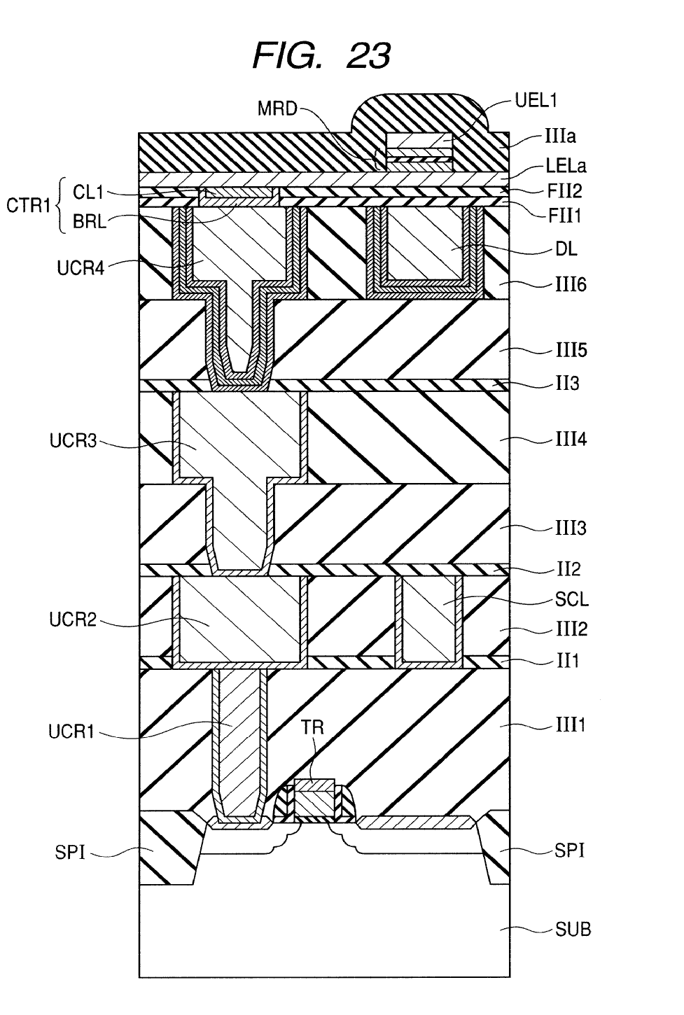

Then, as shown in FIG. 23, there is performed a step of forming an insulation layer IIIa including SiN or the like in such a manner as to cover the top of the main surface on the top side of the conductive film LELa, the side surface of the magnetoresistive element MRD, and the top surface and the side surface of the first upper electrode UEL1. The insulation layer IIIa is a layer to be the protective layer III.

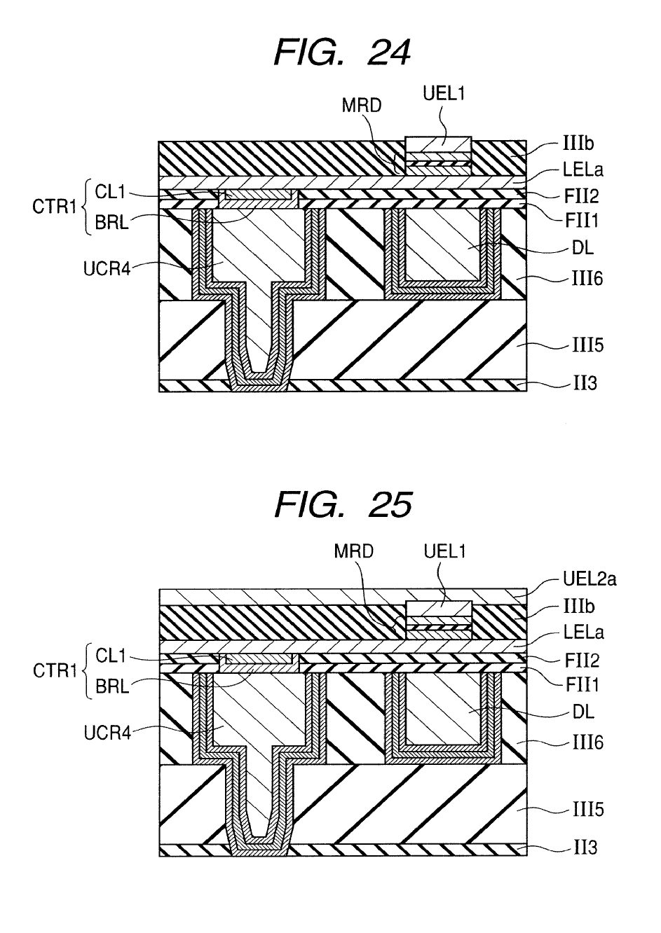

In FIG. 24 and subsequent figures, each cross-sectional view showing a form in each process, as seen from the same direction as for FIG. 3, shows only the insulation film II3 and the part overlying the insulation film II3. At the time when the insulation layer IIIa is formed as in FIG. 23, then, as shown in FIG. 24, a CMP treatment is performed on the region from the surface on the upper side to a prescribed depth of the insulation layer IIIa. Thus, polishing is performed so that at least the uppermost surface of the first upper electrode UEL1 is exposed. By the polishing, the insulation layer IIIa becomes the insulation layer IIIb.

Herein, as shown in FIG. 24, polishing is preferably performed so that the uppermost surface of the insulation layer IIIb lies between the uppermost surface and the lowermost surface of the first upper electrode UEL1. The first upper electrode UEL1 is formed of a metal material, and is scarcely polished with the CMP treatment. This can implement the form as shown in FIG. 24. Alternatively, polishing may be performed so that the insulation layer IIIb is in a shape inclined with respect to the thickness direction in the vicinity of the first upper electrode UEL1 (so as to be thickest at the site in contact with the first upper electrode UEL1, and to be reduced in thickness with an increase in distance from the first upper electrode UEL1).

Incidentally, at this step, in order to achieve high-precision control so that polishing of the insulation layer IIIb is terminated at the height at which the first upper electrode UEL1 is disposed, dummies of the magnetoresistive element MRD are preferably formed in a form satisfying a prescribed filling factor in such a manner as to surround the space region between adjacent cells and the memory cell region. Such a configuration results in formation of a large number of the magnetoresistive elements MRD. Therefore, it is possible to surely terminate polishing of the insulation layer IIIb at the height at which the first upper electrode UEL1 is disposed. Further, by preparing the dummies of the magnetoresistive element MRD, it is possible to improve the processability of the polished surface after the CMP treatment.

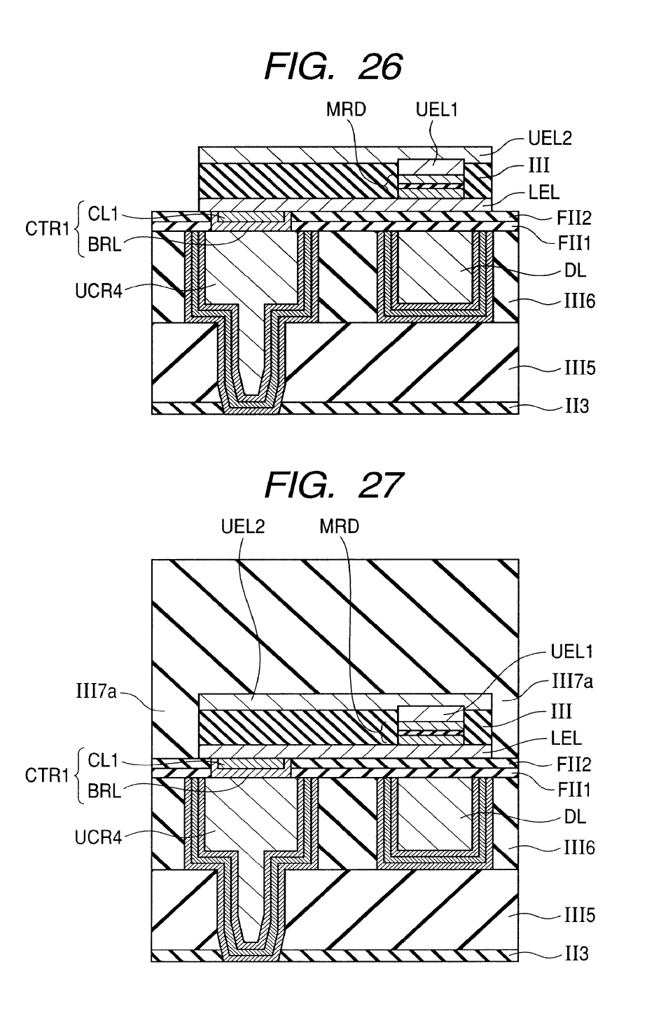

Then, as shown in FIG. 25, a conductive film UEL2a is formed in such a manner as to cover the top surfaces of the insulation layer IIIb and the first upper electrode UEL1. The conductive film UEL2a is a layer to be the second upper electrode UEL2. This is etched so as to have the dimensions shown in FIG. 26 by photolithography and etching, resulting in formation of the second upper electrode UEL2.

Thus, the second upper electrode UEL2 is, in plan view, larger than the first upper electrode UEL1. Further, as shown in FIG. 24, when a CMP treatment is performed in order to form the insulation layer IIIb, polishing is performed so that the uppermost surface of the insulation layer IIIb lies below the uppermost surface of the first upper electrode UEL1. Accordingly, as shown in FIG. 26, the second upper electrode UEL2 is formed in such a manner that a partial region of the first upper electrode UEL1 is embedded in the inside of the second upper electrode UEL2. Further, the conductive film LELa is patterned with the formed second upper electrode UEL2 as a hard mask (i.e., so as to be the same in dimensions in plan view as the second upper electrode UEL2), resulting in formation of the lower electrode LEL.

Then, as shown in FIG. 27, there is performed a step of forming an insulation film in such a manner as to cover the side surface of the protective layer III and the top surface of the second upper electrode UEL2. Specifically, an insulation layer III7a including a silicon oxide film or the like is formed in such a manner as to cover the side surfaces of the lower electrode LEL, and the protective layer III, and the side surface and the top surface of the second upper electrode UEL2.

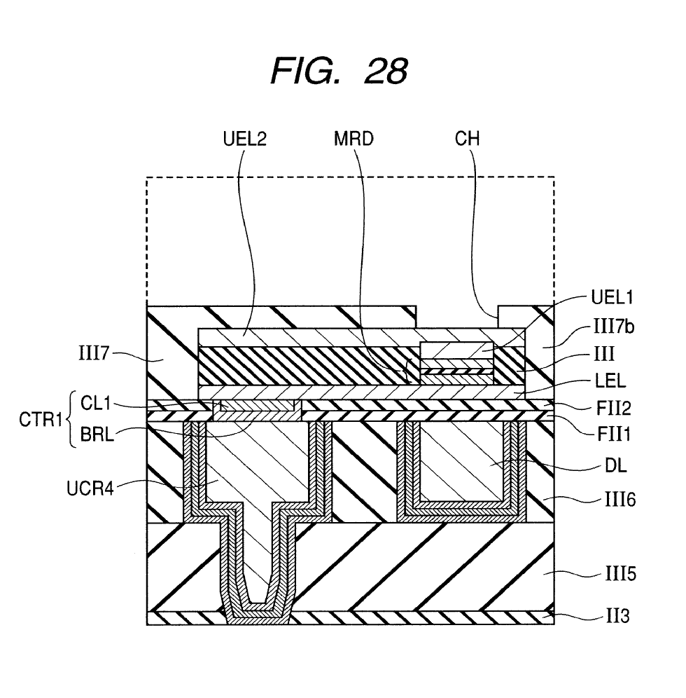

Then, as shown in FIG. 28, the insulation layer III7a is subjected to a CMP treatment and etching so that the insulation layer III7a remains to a height above the uppermost surface of the second upper electrode UEL2 by a given height. Thus, the insulation layer III7a is made into the insulation layer III7. Further, the contact hole CH is formed so that at least a part of the second upper electrode UEL2 is exposed. Herein, the contact hole CH is preferably formed so that the second upper electrode UEL2 is exposed in a region above the magnetoresistive element MRD, and facing the magnetoresistive element MRD.

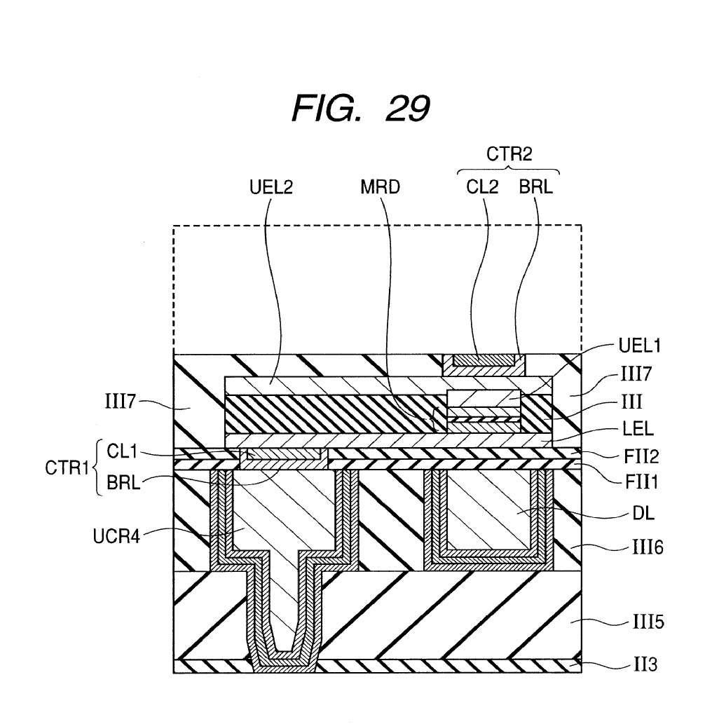

Then, as shown in FIG. 29, a barrier layer BRL is formed over inner surface of the contact hole CH. Then, a conductive layer CL2 such as copper is filled in the contact hole CH. As a result, the contact part CTR2 is formed.

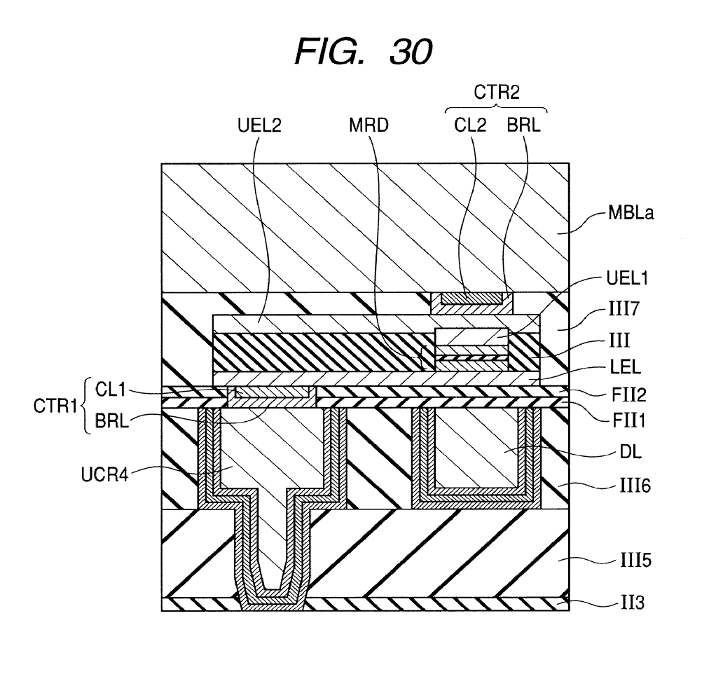

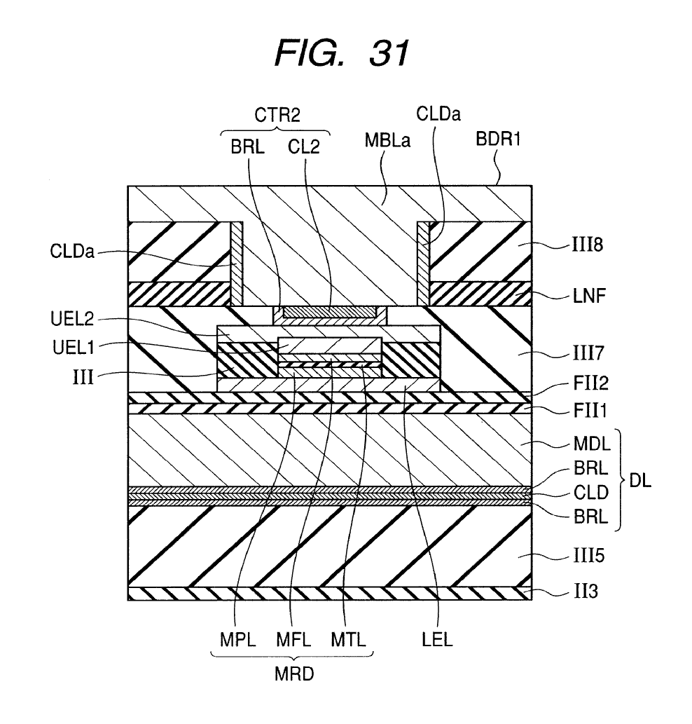

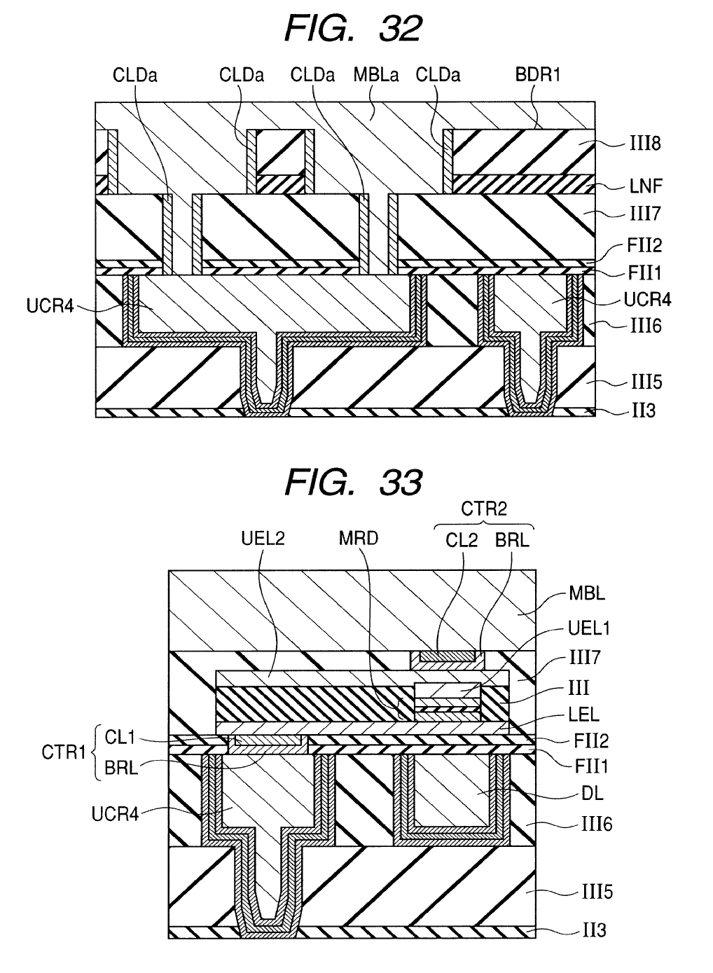

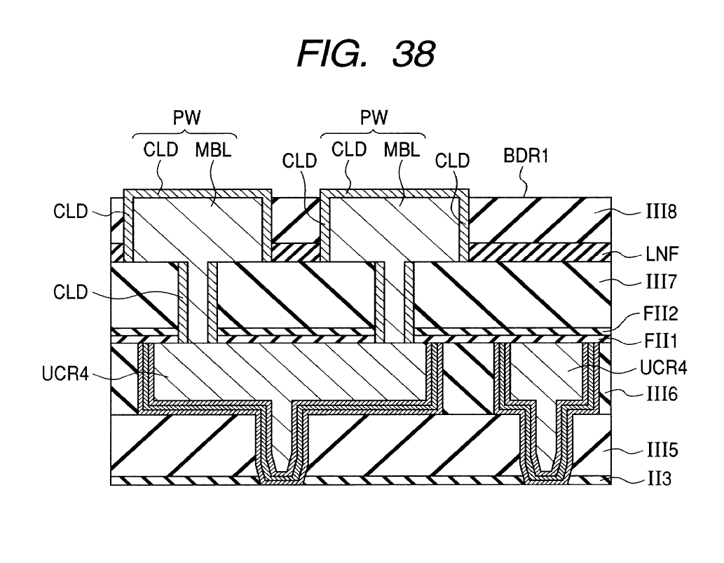

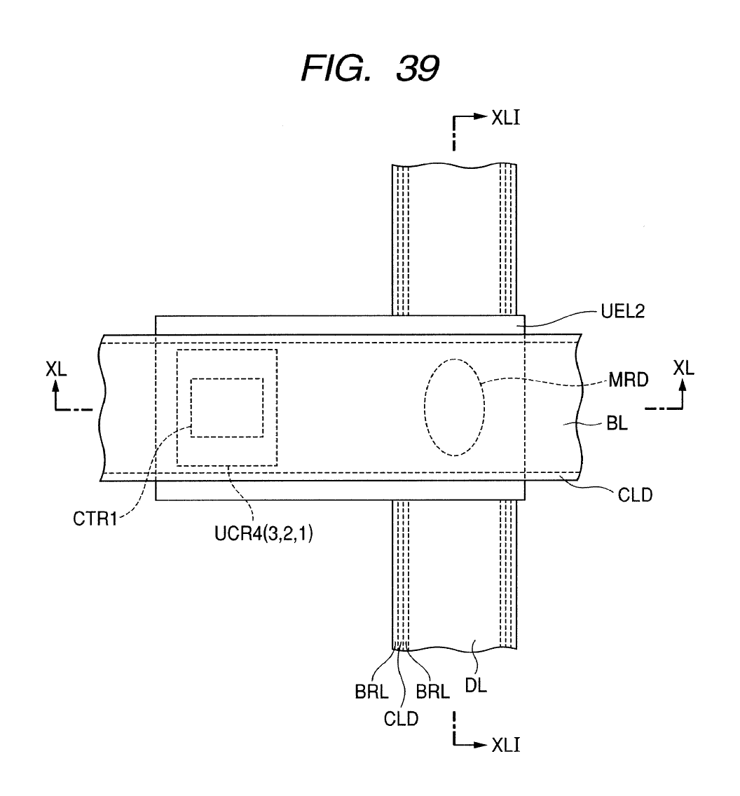

Subsequent FIGS. 30 to 32, 33 to 35, and 36 to 38 respectively show forms after performing the same step. FIGS. 30, 33, and 36 are views as seen from the same direction as for FIG. 3 (which will be hereinafter referred to as a “direction A”). FIGS. 31, 34, and 37 are views as seen from the direction crossing FIG. 3 (the same direction as for FIG. 4) (which will be hereinafter referred to as a “direction B”). Further, FIGS. 32, 35, and 38 are each a cross-sectional view showing a form of the peripheral circuit region as with FIG. 5.

Then, by reference to FIGS. 30 to 32, over the uppermost surface of the insulation layer III7, a liner film including, for example, SiN, and an insulation film including a silicon oxide film or the like are formed in this order. Then, particularly, the liner film and the insulation layer formed in regions facing the second upper electrodes UEL2, and regions facing regions sandwiched between a plurality of the second upper electrodes UEL2 are removed by etching, resulting in formation of a groove. Incidentally, the groove in the peripheral circuit region shown in FIG. 32 includes a groove penetrating through the insulation layer III8, and a groove with a narrower width than that of the groove in the insulation layer III8, penetrating through insulation layer III7, integrated with each other. The groove penetrating through the insulation layer III7 is preferably formed before the steps shown in FIGS. 30 to 32.

Thus, the liner film LNF and the insulation layer III8 shown in FIGS. 30 to 32 are formed. In the description up to this point, polishing and removal are performed in the thickness direction in the overall region of the insulation layer III7a. However, in FIG. 27, the insulation layer III7a is formed. Then, the grooves shown in FIGS. 30 to 32 are formed. For the region in which no groove is formed, the insulation layer III7 may be processed so as to have the same thickness as that of the insulation layer III7a (the height indicated with a dotted line in FIGS. 28 and 29). With this configuration, it is possible to implement a form similar to that of FIGS. 30 to 32 without forming the liner film LNF and the insulation layer III8.

Subsequently, the cladding layer is formed in such a manner as to cover the inner surfaces (the side surface and the bottom surface of the inside) of the groove, and the uppermost surface of the insulation layer III8. However, then, the cladding layer formed over the bottom surface of the groove, or the uppermost surface of the insulation layer III8 is removed by sputtering (sputtering etching). In other words, as shown in FIGS. 31 and 32, there is achieved a form in which only the portion of the cladding layer CLD over the side surface of the groove is left. Further, a conductive film MBLa including copper or the like is formed in such a manner as to cover the cladding layer CLD, and, the region in which the cladding layer CLD was formed such as the top of the uppermost surface of the insulation layer III8, and as to fill the previously formed groove. This form is shown in FIGS. 30 to 32.

Then, the region above the border part BDR1 of FIGS. 31 and 32 out of the conductive film MBLa is removed by photolithography and etching. This results in a bit line main body part MBL as shown in FIGS. 33 to 35.

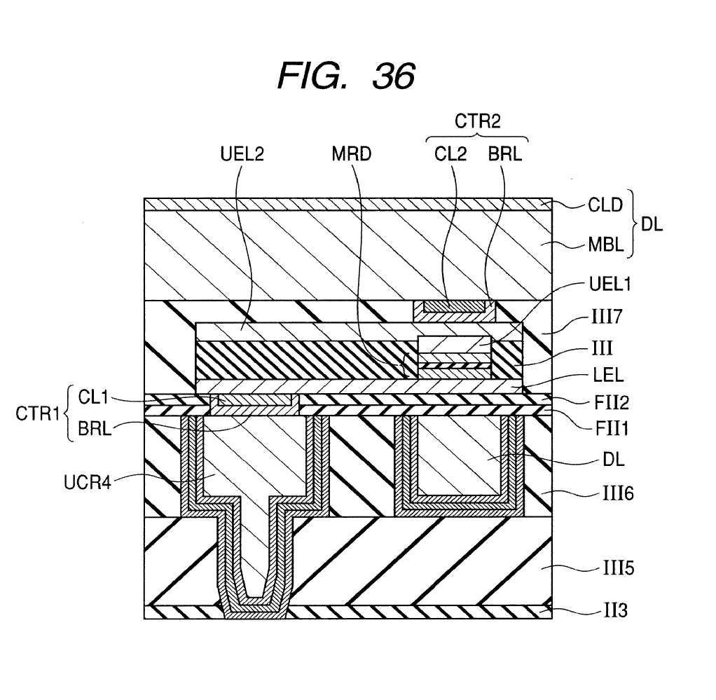

Then, as shown in FIGS. 36 to 38, there is formed the bit line BL or the wiring PW in which over the bit line main body part MBL, the cladding layer CLD is formed.

Incidentally, the main body part of the wiring PW in the peripheral circuit region is also a copper or the like-filled region formed simultaneously with the bit line main body part MBL, and hence is uniformly herein referred to as the bit line main body part MBL.

In the foregoing manner, the semiconductor device of the present embodiment shown in FIGS. 3 to 5 is formed. Herein, the operational effects of the present embodiment will be described. The operational effects of the semiconductor device of the present embodiment will be described.

As with the semiconductor device of the present embodiment, the upper electrode includes a lamination of two layers of the first upper electrode UEL1 and the second upper electrode UEL2, it is possible to more inhibit impurities from penetrating into the inside of the magnetoresistive element MRD from the top side of the upper electrode as compared with, for example, the case where the upper electrode includes only one layer. The impurities are substances which may impair the function of the magnetoresistive element MRD such as oxygen and moisture. The upper electrode has a lamination structure of two layers, which can inhibit penetration of impurities. This is for the following reason: the lamination structure enhances the effect of the upper electrodes present in plural number to block impurities which are about to go from the top side of the upper electrode toward the magnetoresistive element MRD.

Further, if the first upper electrode UEL1 is directly coupled with the bit line BL and the contact part CTR2, the stress applied from the bit line BL to the first upper electrode UEL1 increases. This may cause a defective condition such as peeling of the first upper electrode UEL1 from the magnetoresistive element MRD. However, the upper electrode includes two layers of the first upper electrode UEL1 and the second upper electrode UEL2. For this reason, the stress directly applied from the bit line BL to the first upper electrode UEL1 can be released.

Herein, the area in plan view of the second upper electrode UEL2 is set larger than that of the first upper electrode UEL1. This can further reduce the stress applied from the bit line BL to the second upper electrode UEL2. Therefore, the stress directly applied from the bit line BL to the first upper electrode UEL1 can be further released.

Further, the area in plan view of the second upper electrode UEL2 is made larger than that of the first upper electrode UEL1. This can increase the effect of blocking impurities penetrating from the top of the second upper electrode UEL2 toward the magnetoresistive element MRD.

Further, the area in plan view of the second upper electrode UEL2 is set larger than that of the first upper electrode UEL1. Therefore, the area in plan view of the contact part CTR2 can be set larger than the area in plan view of the first upper electrode UEL1. This can reduce the resistance value of the current in coupling between the second upper electrode UEL2 and the contact part CTR2. Therefore, the electrical resistance of the overall current path between the MOS transistors TR and the bit line BL can be reduced. As a result, it is possible to improve the conductivity of the current path.

Further, as particularly shown in FIGS. 3 and 4, a partial region of the first upper electrode UEL1 is embedded in the inside of the second upper electrode UEL2, and both are coupled with each other in such a manner as to be inserted one into another. As a result, as compared with, for example, the case where the main surfaces of the first upper electrode UEL1 and the second upper electrode UEL2 are coupled with each other in such a manner as to be in contact with each other as in FIG. 6, the mechanical contact area between the first upper electrode UEL1 and the second upper electrode UEL2 becomes larger. For this reason, in the case of FIG. 3 or 4, as compared with the case of FIG. 6, the resistance value of the current at the upper electrode can be further reduced. As a result, it is possible to improve the conductivity of the current path between the MOS transistors TR and the bit line BL.

Further, in this semiconductor device, as described above, the thickness of the cladding layer CLD at the side surface of the bit line BL is preferably larger than the thickness of the cladding layer CLD at the top surface of the bit line BL. Specifically, by reference to FIG. 4, the thickness W1 of the cladding layer CLD at the side of the bit line BL is preferably larger than the thickness W2 of the cladding layer CLD at the top of the bit line BL.

For example, the magnetic field due to the current passing through the bit line BL leaks toward a magnetoresistive element MRD adjacent to a desirable magnetoresistive element MRD. This phenomenon is more likely to occur from the side than from the top of the bit line main body part MBL. For this reason, by making W1 larger than W2, the magnetic shielding effect of the cladding layer CLD is enhanced. Accordingly, it is possible to inhibit the leakage of the magnetic field with more reliability. In other words, it is possible to inhibit the malfunction caused by the leakage of the magnetic field to the magnetoresistive element MRD adjacent to the intended magnetoresistive element MRD.

Further, as shown in FIG. 4, the cladding layers CLD covering the side surfaces of the bit line main body part MBL and the cladding layer CLD covering the top surface of the bit line main body part MBL are preferably disposed in such a manner as to be continuous to each other. This inhibits the magnetic force lines passing through the inside of the cladding layer CLD from leaking outside the cladding layer CLD, which can enhance the magnetic shielding effect of the magnetic force line around the bit line BL. In other words, the magnetic force lines can be allowed to act on the magnetoresistive element MRD in a higher density.

As shown in FIG. 3, the cladding layers CSD formed in the inner side surface of the digit line DL, the outer side surface of the bit line BL, and the like are formed in such a manner as to open toward the magnetoresistive elements MRD. In other words, over the surfaces of the bit line main body part MBL and the digit line main body part MDL opposite to the magnetoresistive element MRD, no cladding layer CLD is formed. With such a configuration, it is possible to enhance the efficiency for the current passing through the bit line BL or the digit line DL to write magnetic field signals to the magnetoresistive element MRD. In other words, the driving electrical power of the semiconductor device can be reduced.

Incidentally, if also in the peripheral circuit region shown in FIG. 5, the same magnetoresistive element MRD and second upper electrode UEL2 as those in the memory cell region of FIG. 3 or 4 are disposed, the second upper electrode UEL2 can be used as a local wiring.

Then, a description will be given to the operational effects of a method for manufacturing the semiconductor device in accordance with the present embodiment. With the manufacturing method, after formation of the protective layer III in a desired shape, there is formed the second upper electrode UEL2 larger in area in plan view than the first upper electrode UEL1. This can inhibit the following defective condition: at the stage of forming an insulation layer covering the side surfaces of the protective layer III, and the like later, and etching them, thereby to form the insulation layer III7 and the like, the protective layer III is simultaneously etched; and thus, a part of the magnetoresistive element MRD is exposed. This also applies to the supposed case where in the peripheral circuit region of FIG. 5, the same magnetoresistive element MRD and second upper electrode UEL2 as those in the memory cell region are formed.

A part of the protective layer III is etched, so that the magnetoresistive element MRD is exposed. This may cause a short circuit between the magnetoresistive element MRD and the conductive film MBLa formed thereabove. There is formed the second upper electrode UEL2 larger in dimensions in plan view than the magnetoresistive element MRD and the first upper electrode UEL1. For this reason, for example, when the insulation layer including a silicon oxide film formed over the second upper electrode UEL2 is subjected to a CMP treatment and etching, the CMP treatment and etching are stopped at the second upper electrode UEL2. As a result, it is possible to reduce the possibility that the protective layer III disposed at the part underlying the second upper electrode UEL2 is etched, or that the magnetoresistive element MRD covered with the protective layer III is exposed.

Further, in the present manufacturing method, a contact part CTR2 is formed between the uppermost surface of the second upper electrode UEL2 and the lowermost surface of the bit line BL. In other words, the second upper electrode UEL2 and the bit line BL are apart from each other. The contact part CTR2 disposed in a region sandwiched between the second upper electrode UEL2 and the bit line BL establishes an electrical coupling between the second upper electrode UEL2 and the bit line BL.

For example, when the groove for forming the bit line BL shown in FIGS. 30 to 32 is formed, the layer to be the insulation layer III8 is etched. However, there is a margin for the etching amount in the thickness direction by the thickness of the contact part CTR2. For this reason, it is possible to more surely inhibit the defective condition that the second upper electrode UEL2 and the underlying protective layer III are etched upon etching for forming the groove.

For example, when etching of the protective layer III may expose apart of the magnetoresistive element MRD, etching of the protective layer III covering the magnetoresistive element MRD may be inhibited by increasing the thickness of the first upper electrode UEL1, and providing the margin for the etching amount allowable for the protective layer III. However, with the present manufacturing method, the possibility of etching of the protective layer III is reduced. For this reason, the first upper electrode UEL1 can be more reduced in thickness. Reduction of the thickness of the first upper electrode UEL1 can release the stress of the first upper electrode UEL1 applied to the magnetoresistive element MRD. This can inhibit the defective condition such as peeling of the first upper electrode UEL1 from the magnetoresistive element MRD.

Further, as with the present manufacturing method, there is disposed the second upper electrode UEL2 larger in area in plan view than the first upper electrode UEL1. As a result, it is possible to easily control the position in plan view at which the contact hole CH is to be formed when the contact part CTR2 is formed. For example, it is difficult to form the contact hole CH over the first upper electrode UEL1 having a small area in plan view. However, when the contact hole CH is formed over the second upper electrode UEL2 larger in area in plan view than the first upper electrode UEL1, it is possible to expand the region capable of forming the contact hole CH therein.

### Embodiment 2

The present embodiment is different from Embodiment 1 in the manner of establishing a coupling between the second upper electrode UEL2 and the bit line BL, and the manufacturing method of the region. Below, the configuration of the present embodiment will be described.

By reference to FIGS. 39 to 41, a semiconductor device of Embodiment 2 does not include a contact part CTR2 coupling the second upper electrode UEL2 and the bit line BL. The second upper electrode UEL2 and the bit line BL (wiring) are directly coupled with each other. Incidentally, in respective drawings in Embodiment 2 and subsequent embodiments, when the configuration of the lower layers of the lamination structure of the semiconductor device, such as the semiconductor substrate SUB (see FIG. 3), and the insulation layer III1 is the same as that of Embodiment 1, it is not shown.

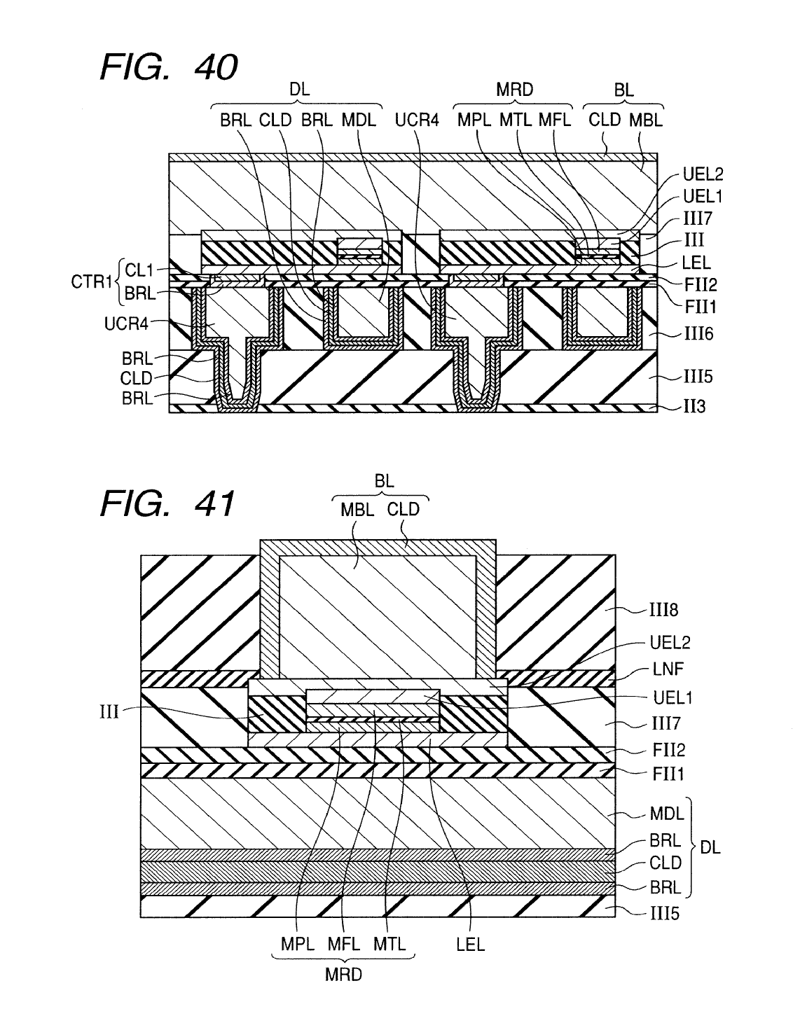

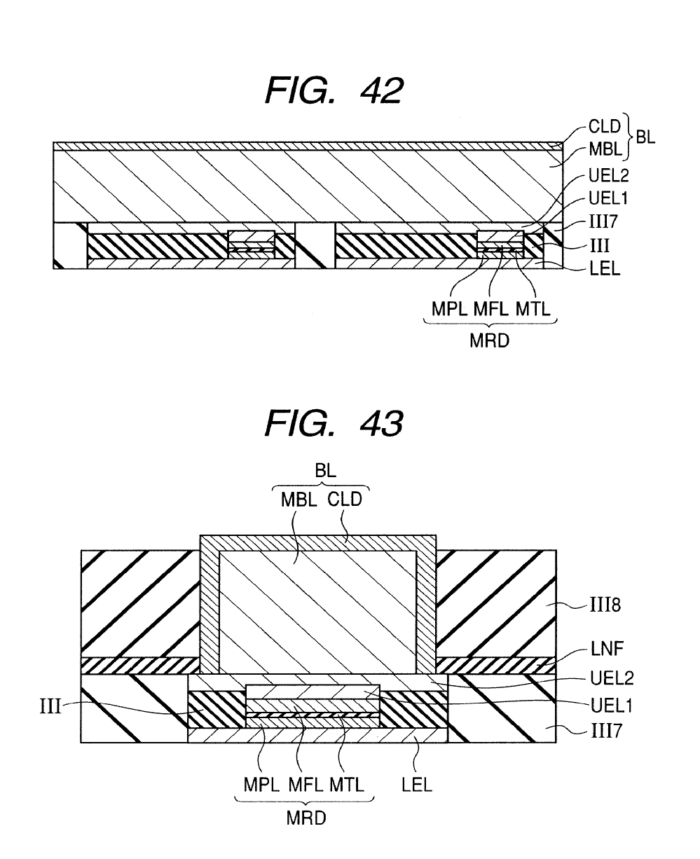

Further, in the semiconductor device of Embodiment 2, as shown in FIGS. 40 and 41, direct coupling is preferably established in such a manner that a partial region of the second upper electrode UEL2 is embedded in the inside of the bit line BL (bit line main body part MBL). In other words, the main surface of the second upper electrode UEL2 facing the bit line BL is preferably disposed in such a manner as to be inserted into the inside of the bit line BL. However, as shown in FIGS. 42 and 43, mechanical and electrical coupling may be established in such a manner that the second upper electrode UEL2 is not inserted into the inside of the bit line BL, and that the mutual main surfaces are in contact with each other.

Then, the method for manufacturing a semiconductor device of the present embodiment will be described. Herein, a description will be given to a method for manufacturing a semiconductor device in which a partial region of the second upper electrode UEL2 is disposed in such a manner as to be embedded in the inside of the bit line BL shown in FIGS. 40 and 41.

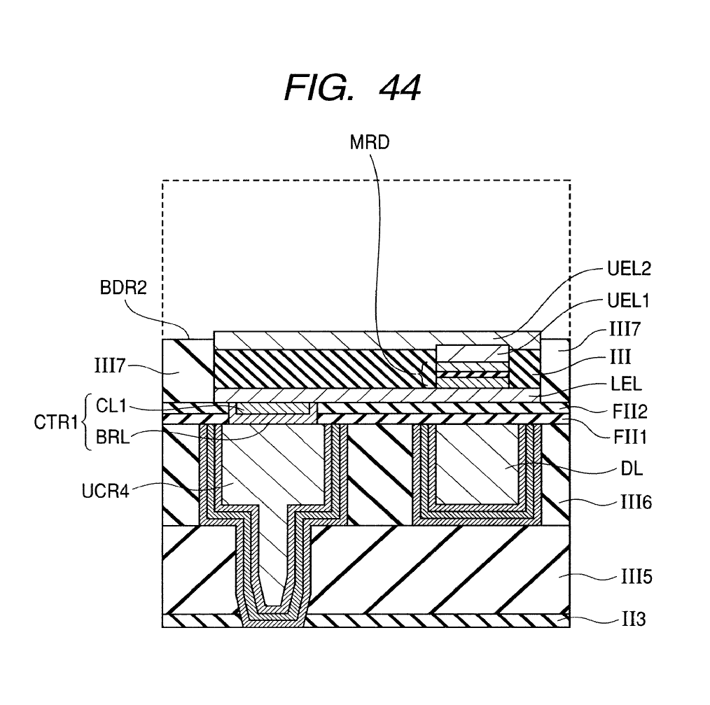

The method for manufacturing a semiconductor device of the present embodiment is the same as that of Embodiment 1 for FIGS. 8 to 27. Further, in FIGS. 44 to 49, the part underlying the insulation film. II3 (the semiconductor substrate SUB side) is not shown.

Upon formation of the insulation layer III7a as in FIG. 27, then, as shown in FIG. 44, the region from the surface on the top side to a given depth of the insulation layer III7a is subjected to a CMP treatment. Thus, polishing is performed so that at least the uppermost surface of the second upper electrode UEL2 is exposed. The polishing makes the insulation layer III7a into the insulation layer III7. However, as with Embodiment 1, only in the region in which the groove for forming the bit line BL is formed, the insulation layer III7a is polished and removed. In other regions, the insulation layer III7 may be kept up to a height indicated with a dotted line in FIG. 44.

Herein, as shown in FIG. 44, polishing is preferably performed so that the border part BDR2 which is the uppermost surface of the insulation layer III7 lies between the uppermost surface and the lowermost surface of the second upper electrode UEL2. The second upper electrode UEL2 is formed of a metal material, and is scarcely polished with a CMP treatment. This can implement the form as shown in FIG. 44.

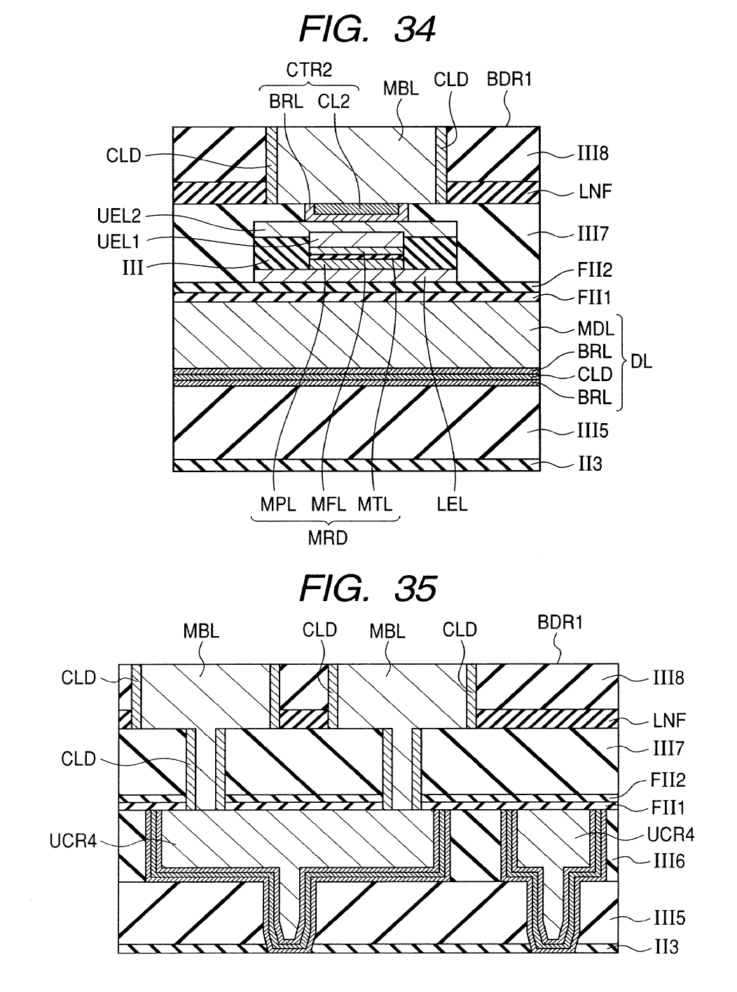

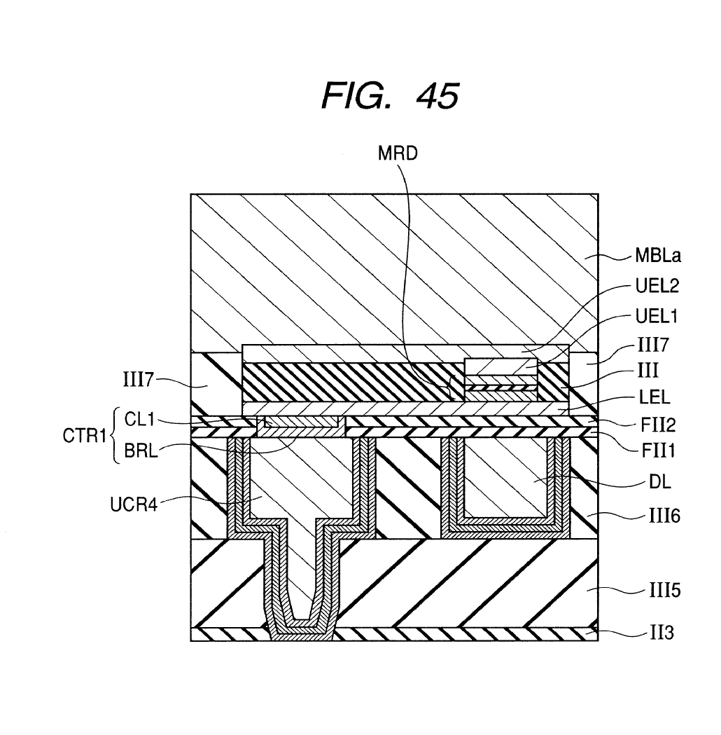

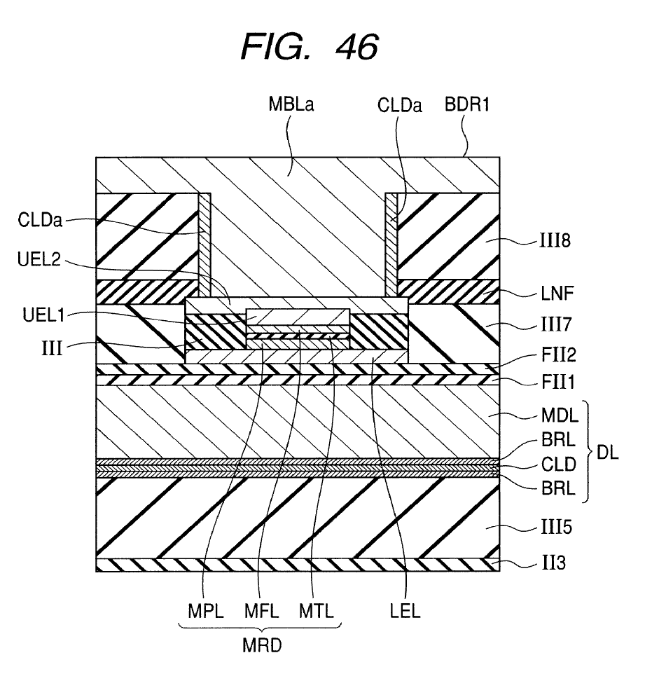

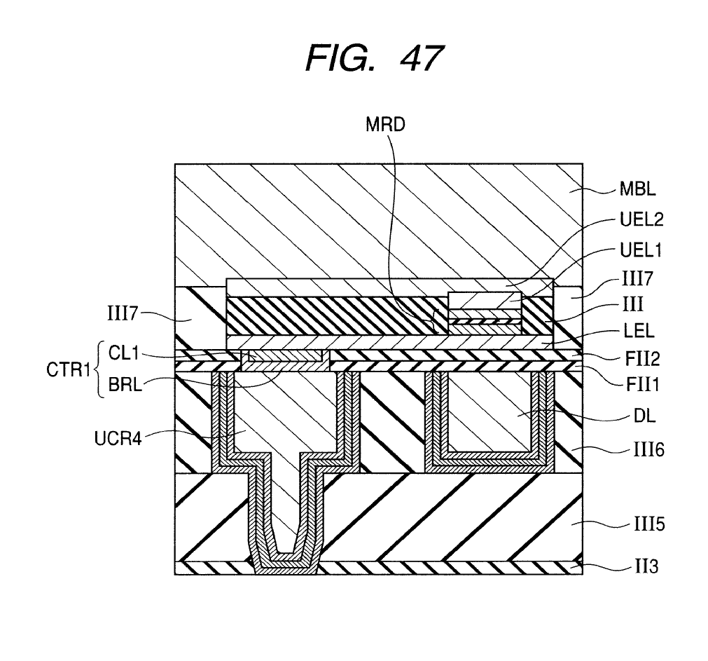

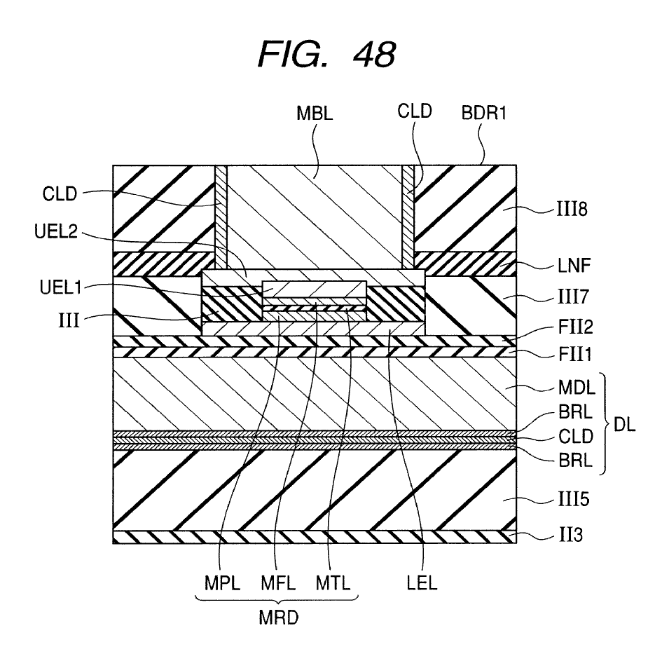

The subsequent FIGS. 45 and 46, and FIGS. 47 and 48 each show the form after performing the same step. FIGS. 45 and 47 are views as seen from the direction A. FIGS. 46 and 48 are views as seen from the direction B. Further, the step shown in FIGS. 45 to 46 is the same as the step shown in FIGS. 30 to 31. The step shown in FIGS. 47 to 48 is the same as the step shown in FIGS. 33 to 34.

Thus, over the second upper electrode UEL2, the bit line main body part MBL is formed in such a manner as to be directly coupled with the second upper electrode UEL2. Further, polishing is performed so that the border part BDR2 lies between the uppermost surface and the lowermost surface of the second upper electrode UEL2. Accordingly, the bit line main body part MBL is formed so that a partial region of the second upper electrode UEL2 is embedded in, and directly coupled with the inside of the bit line main body part MBL.

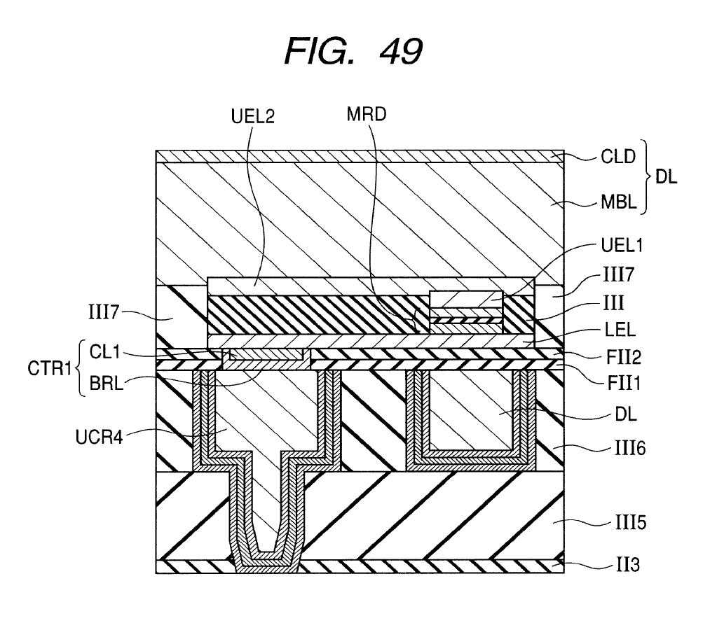

Further, the step shown in FIG. 49 is the same as the step shown in FIG. 36. Thus, there is formed the semiconductor device of the present embodiment shown in FIGS. 40 to 41.

Herein, a description will be given to the operational effects of the semiconductor device of the present invention. When the second upper electrode UEL2 and the bit line BL are directly coupled with each other as with the semiconductor device of the present embodiment, as compared with the case where both are coupled with each other via the contact part CTR2 as in, for example, Embodiment 1, the cross-sectional area of the current path connecting the bit line BL to the second upper electrode UEL2 is larger. This is for the following reason: the contact area between the second upper electrode UEL2 and the bit line BL of Embodiment 2 is larger than the contact area between the contact part CTR2 and the bit line BL or the second upper electrode UEL2 of Embodiment 1.

This can reduce the resistance value of the current at the second upper electrode UEL2. Therefore, the electrical resistance of the whole current paths between the MOS transistors TR and the bit line BL can be reduced. As a result, it is possible to improve the conductivity of the current path.

Further, particularly as shown in FIGS. 40 and 41, both are coupled with each other in such a manner that a partial region of the second upper electrode UEL2 is embedded and inserted in the inside of the bit line BL. This results in a larger in mechanical contact area between the second upper electrode UEL2 and the bit line BL as compared with, for example, the case where a coupling is established in such a manner that the main surfaces of the second upper electrode UEL2 and the bit line BL are in contact with each other as in FIGS. 42 and 43. For this reason, in the case of FIGS. 40 and 41, the resistance value of the current at the upper electrode can be still more reduced than in the case of FIGS. 42 and 43. As a result, it is possible to improve the conductivity of the current path between the MOS transistors TR and the bit line BL.

Incidentally, in the semiconductor device of Embodiment 2, there is no contact part CTR2, so that the bit line BL and the second upper electrode UEL2 are directly coupled with each other. For this reason, there is no margin for the etching amount in the thickness direction by the thickness of the contact part CTR2 present in the semiconductor device of Embodiment 1. However, in the semiconductor device of Embodiment 2, the same second upper electrode UEL2 as that of the semiconductor device of Embodiment 1 is also disposed. This produces an effect of inhibiting etching of the protective layer III and exposure of the magnetoresistive element MRD.

Embodiment 2 of the present invention is different from Embodiment 1 of the present invention only in the respective points described up to this point. Namely, all the configurations, conditions, procedures, effects, and the like not described above for Embodiment 2 of the present invention follow those of Embodiment 1 of the present invention.

### Embodiment 3

The present embodiment is different from Embodiment 1 in the form of the cladding layer covering the side surfaces and the top surface of the bit line BL, and the manufacturing method of the region. Below, the configuration of the present embodiment will be described.

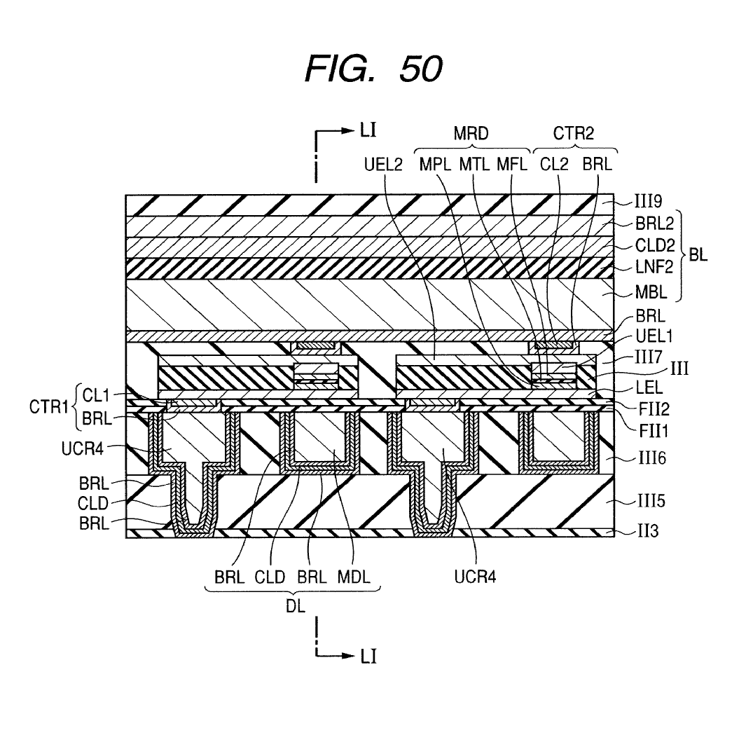

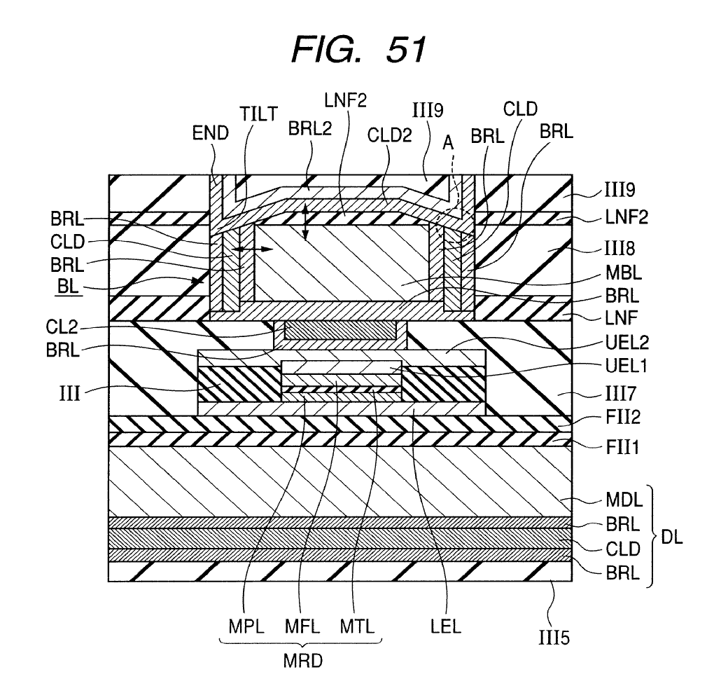

By reference to FIGS. 50 and 51, in the bit line BL of the present embodiment, the outside surfaces of the cladding layer CLD disposed in such a manner as to face the side surfaces of the bit line main body part MBL (the surfaces on the sides of the cladding layer CLD facing and opposite to the bit line main body part MBL) are covered with the barrier layers BRL. The outside surface of the cladding layer CLD2 disposed in such a manner as to face the top surface of the bit line main body part MBL is covered with a barrier layer BRL2.

Further, out of the inside surfaces of the cladding layer CLD (the surfaces of the cladding layer CLD facing the bit line main body part MBL), the side surfaces (surfaces present on the left and right sides of FIG. 51) and the bottom surface (the surface present on the bottom side of FIG. 51) are covered with the barrier layers BRL. The inside surface of the cladding layer CLD2 is covered with a liner film LNF2.

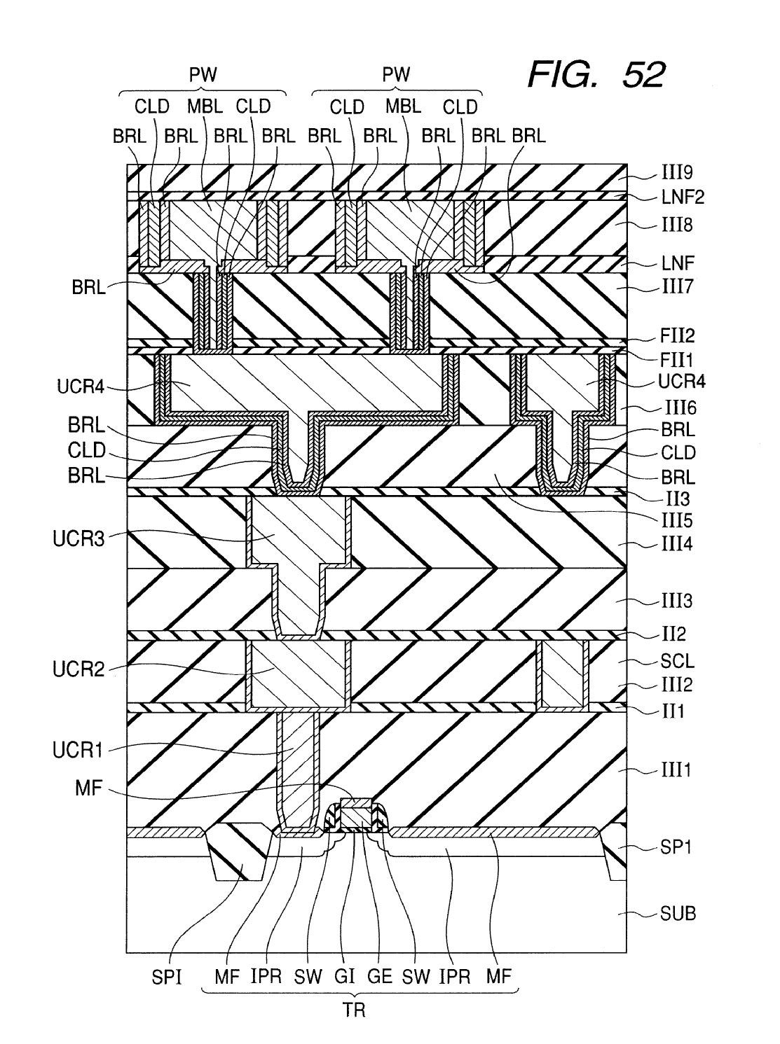

The insulation layer III9 is an insulation layer disposed for coupling the external loads such as electrode pads to the top of the insulation layer particularly in a partial region of the peripheral circuit region shown in FIG. 52. As shown in FIG. 52, over the side surface of the bit line main body part MBL of the wiring PW in the peripheral circuit region, as with the bit line main body part MBL in the memory cell region, the barrier layer BRL covering the cladding layer CLD is also formed. The bottom surface of the bit line main body part MBL (a region almost equal in height in the vertical direction to the liner film LNF) is covered with the barrier layer BRL.

The liner film LNF2 is disposed, as with the liner film LNF, for electrically separating the cladding layers CLD of the adjacent bit lines BL (wirings PW).

However, the liner film LNF2 over the bit line main body part MBL inhibits diffusion of atoms between the cladding layer CLD and the bit line main body part MBL as described later, and is different in role from the liner films LNF2 between a plurality of bit lines BL. However, as described later, these are formed simultaneously, and hence are referred to as liner films LNF2.

Further, at a corner part at which the cladding layers CLD at the side of the bit line main body part MBL and the cladding layer CLD2 at the top of the bit line main body part MBL cross each other and are coupled with each other (region surrounded by a circle dotted line in FIG. 51), the angle formed by the directions in which mutually coupled cladding layers CLD and cladding layer CLD2 extend in the cross-sectional view of FIG. 51 is an obtuse angle of more than 90° and less than 180°. In other words, at the cladding layer end TILT, the cladding layer CLD2 is in a tilted state with an angle with respect to the main surfaces in multilayer lamination in the semiconductor device.

Further, in the region surrounded by the circle dotted line A in FIG. 51, the cladding layer CLD and the cladding layer CLD2 are preferably continuous to each other.

As described up to this point, Embodiment 3 is different from Embodiment 1 in that the side surfaces and the top surface of the bit line main body part MBL, and the like are covered with a plurality of layers.

Incidentally, the barrier layer BRL2, the cladding layer CLD2, and the insulation layer III9 described up to this point are preferably formed of the same materials as those for the barrier layer BRL, the cladding layer CLD, and the insulation layer III1, respectively.

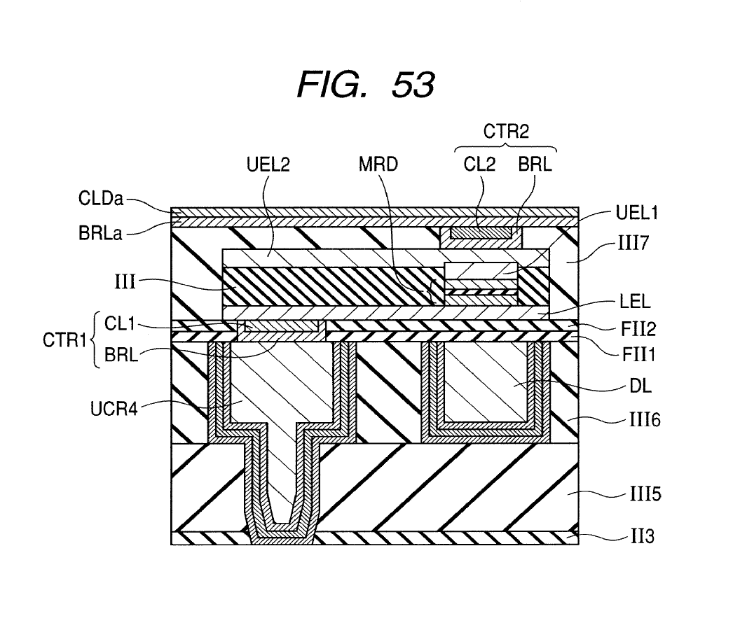

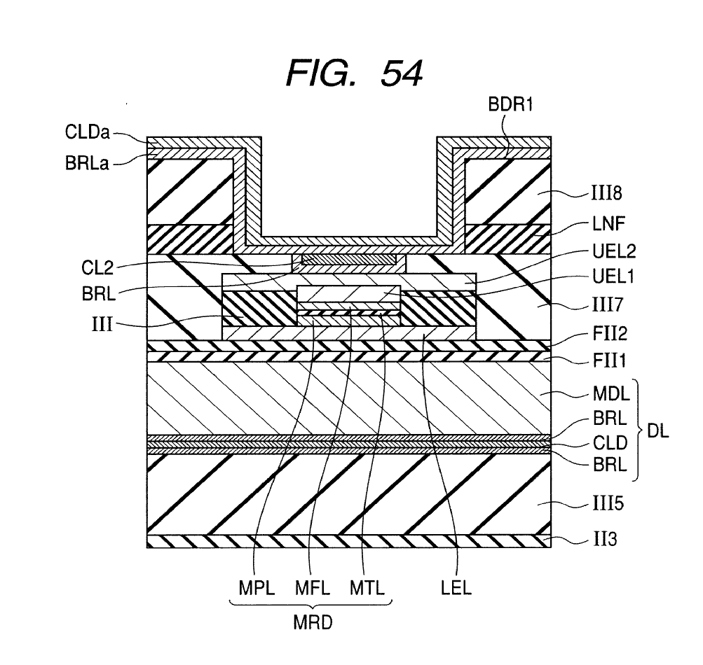

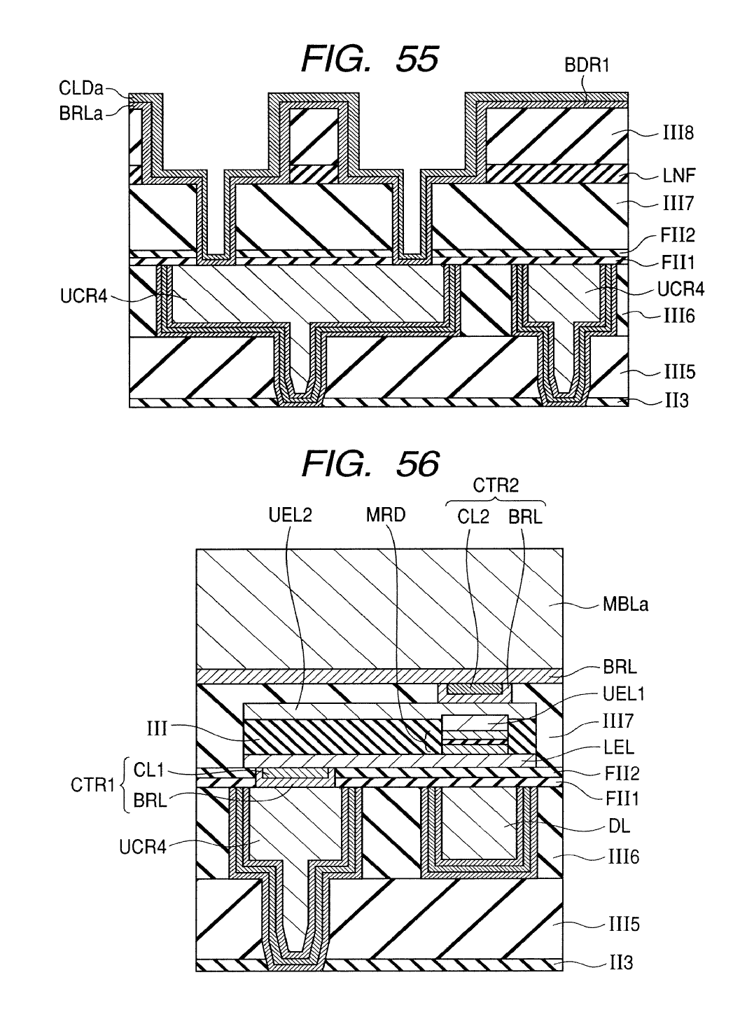

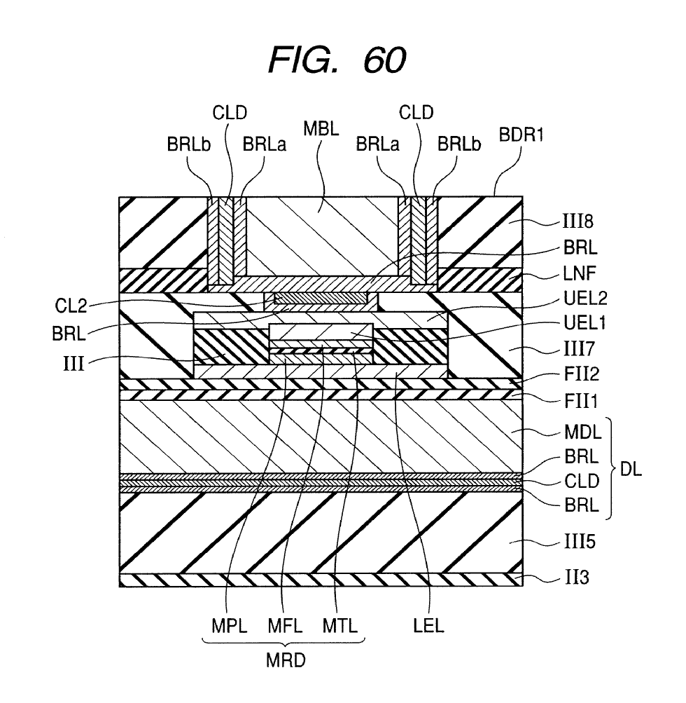

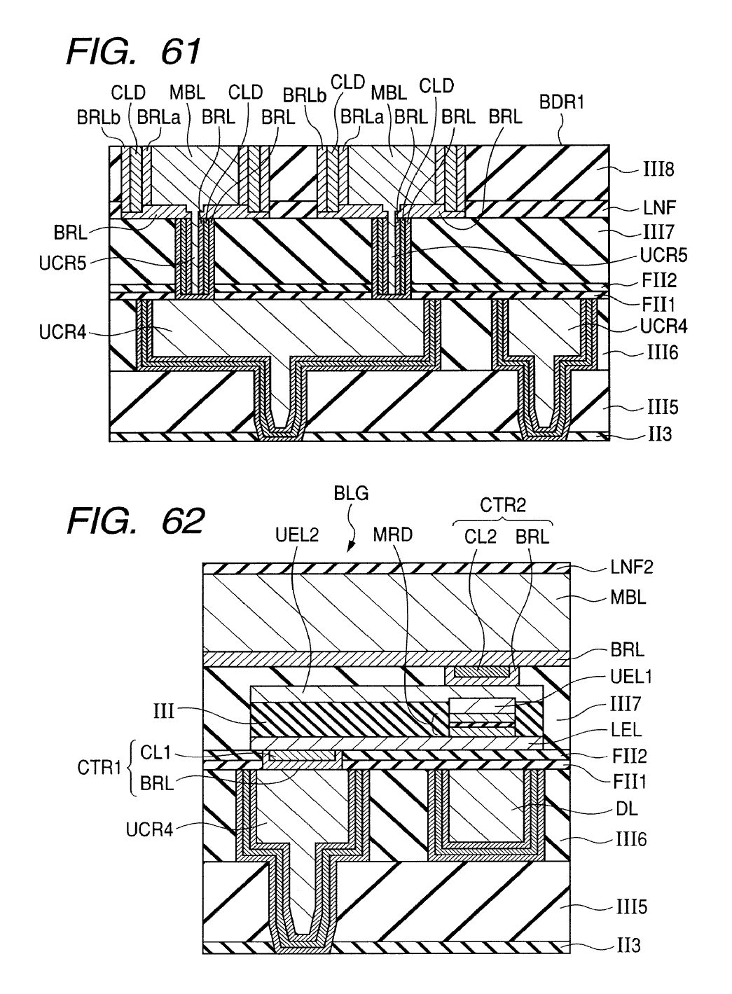

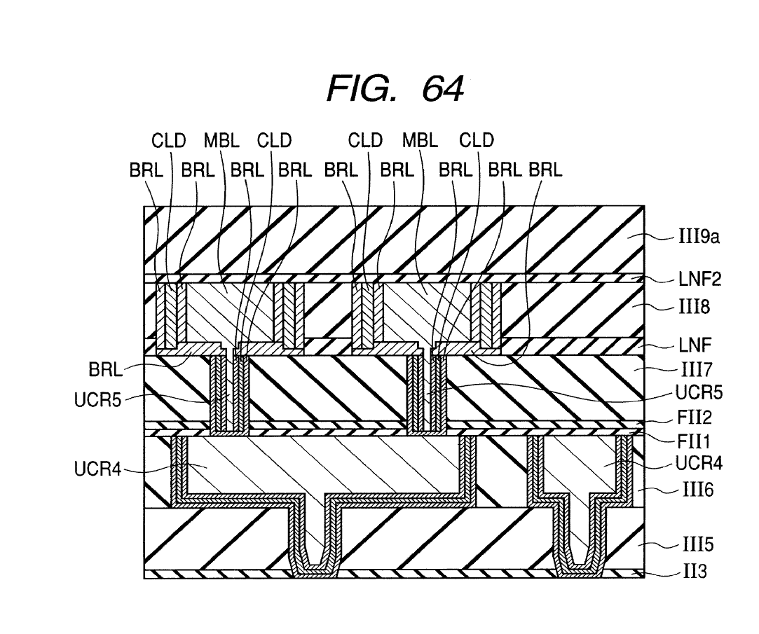

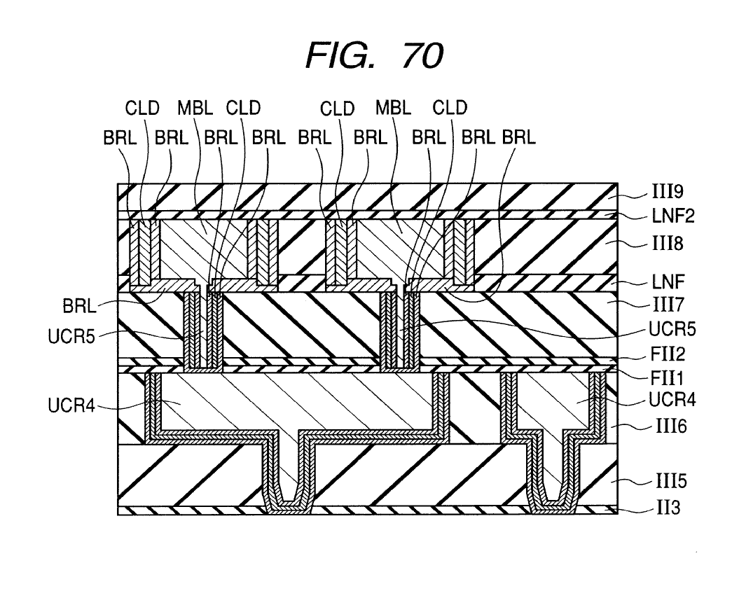

Then, a method for manufacturing a semiconductor device of the present embodiment will be described. The method for manufacturing a semiconductor device of the present embodiment is the same as that of Embodiment 1 for FIGS. 8 to 29. Further, in FIGS. 53 to 70, the part underlying the insulation film II3 (the semiconductor substrate SUB side) is not shown.

FIGS. 53 to 55, 56 to 58, 59 to 61, 62 to 64, 65 to 67, and 68 to 70 respectively show forms after performing the same step. FIGS. 53, 56, 59, 62, 65, and 68 are views as seen from the direction A. FIGS. 54, 57, 60, 63, 66, and, 69 are views as seen from the direction B. Further, FIGS. 32, 35, and 38 are each a cross-sectional view showing a form of the peripheral circuit region as with FIG. 5.

As in FIG. 29, the insulation layer III7 is formed, and a groove for forming the liner film LNF, the insulation layer III8, and the bit line BL shown in FIGS. 30 to 32 is formed. At this moment, the barrier layer BRLa and the cladding layer CLDa are formed in such a manner as to cover the inner surface of the groove, and the uppermost surface of the insulation layer III8. These are layers to be the barrier layer BRL and the cladding layer CLD, respectively, in FIG. 51. The conditions are shown in FIGS. 53 to 55.

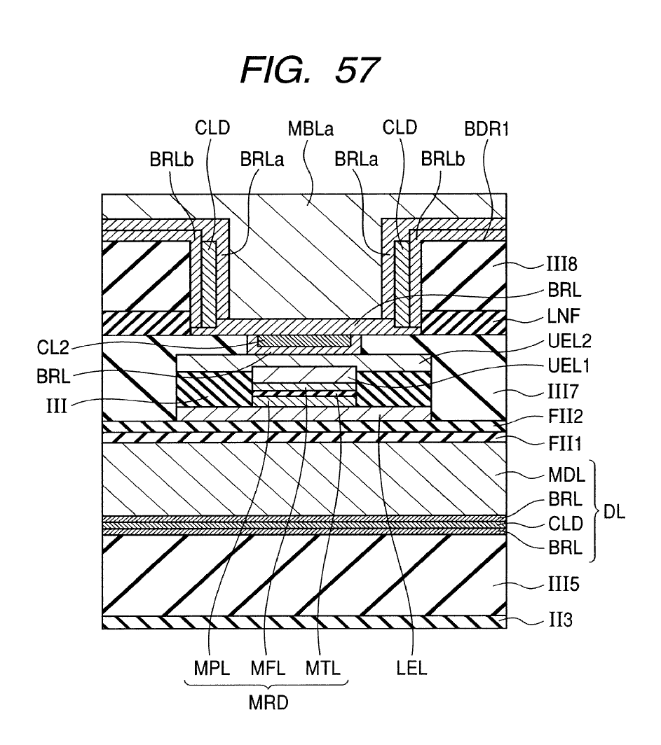

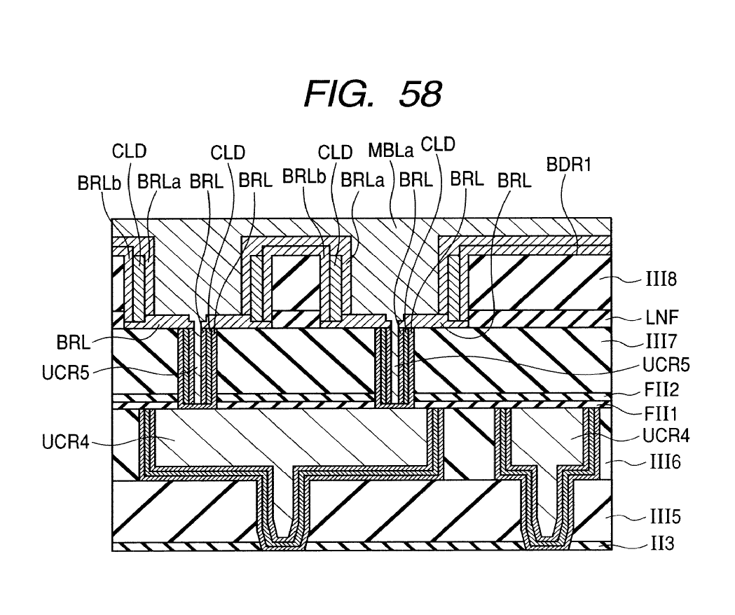

Then, by reference to FIGS. 56 to 58, there are removed portions of the cladding layer CLD at the bottom of the groove, namely, in a region facing and in direct contact with the contact part CTR2 in FIGS. 56 and 57 (with a height in the vertical direction almost the same as that of the liner film LNF), and in a region with a height in the vertical direction almost the same as that of the liner film LNF in the peripheral circuit region in FIG. 58. Furthermore, as with FIGS. 53 to 55, the barrier layer BRLa is formed again.

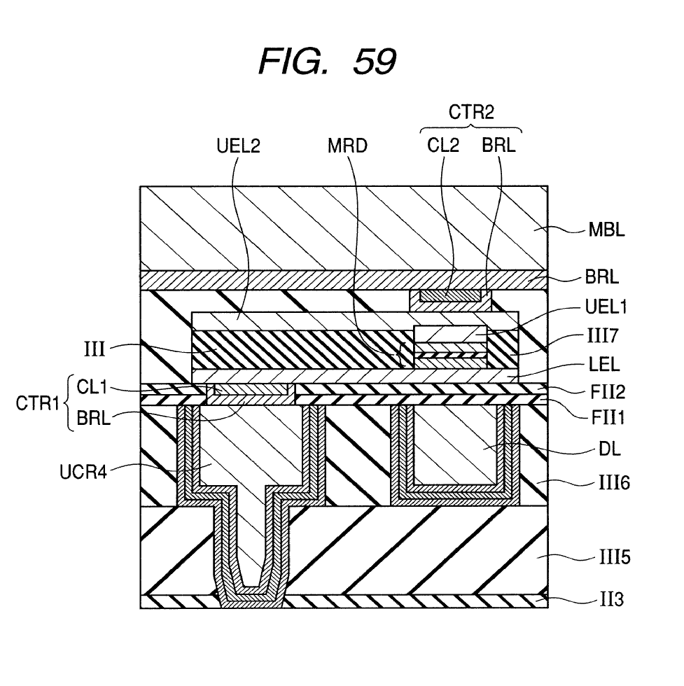

The subsequent steps shown in FIGS. 59 to 61 are the same as those shown in FIGS. 33 to 35. Then, as shown in FIGS. 62 to 64, over the entire surface of the bit line main body part MBL, a layer to be the liner film LNF2 and the insulation layer III9a (a layer to be the insulation layer III9) are formed. Then, particularly, these layers formed over the top of the bit line BL (bit line main body part MBL) in the memory cell region are subjected to photolithography and etching. Thus, the liner film and the insulation layer III9a formed over the top of the bit line main body part MBL in the memory cell region are removed. As a result, a bit-line groove BLG is formed.

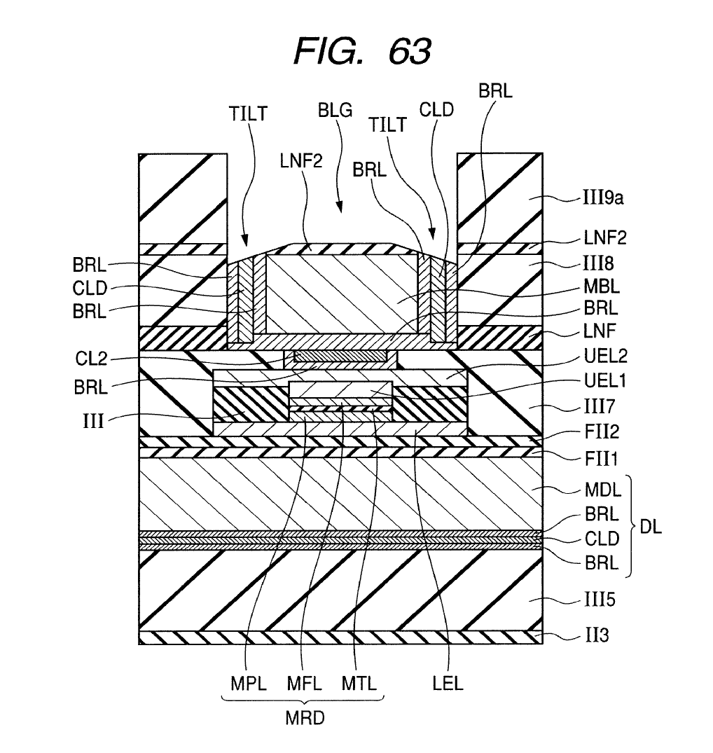

Then, particularly, portions of the liner film in the vicinity of the left and right ends in FIG. 63 of the bottom of the bit-line groove BLG are patterned and removed by sputtering or the like. With this configuration, particularly in a partial region of the bottom of the bit-line groove BLG, the liner film becomes thin, and is formed as the liner film LNF2. Further, there is formed a region to be a cladding layer end TILT having an angle with respect to the main surface of the lamination structure.

Thus, the region to be the cladding layer end TILT is formed. This can also expose a partial region of each upper end of the barrier layer BRL and the cladding layer CLD at the side of the bit line main body part MBL.

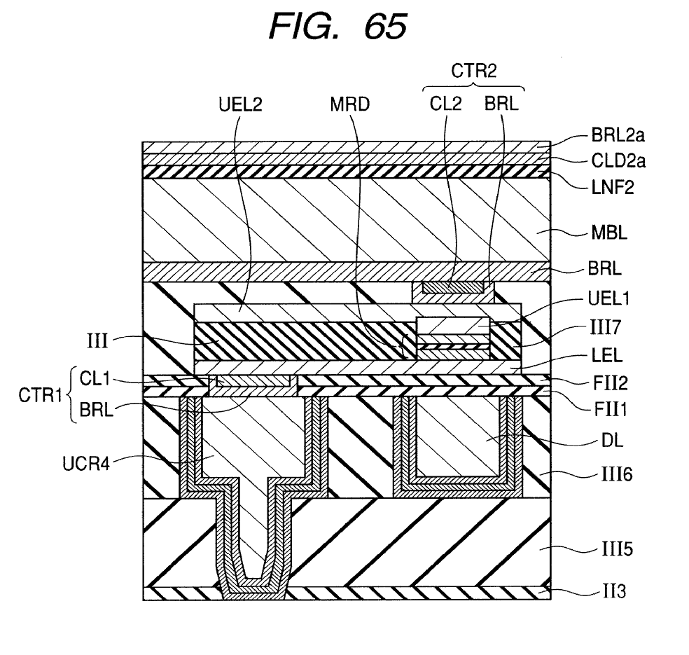

Then, in such a manner as to cover the inner surface of the bit-line groove BLG, the cladding layer CLD2a and the barrier layer BRL2a are formed in this order. The form is shown in FIGS. 65 to 67.

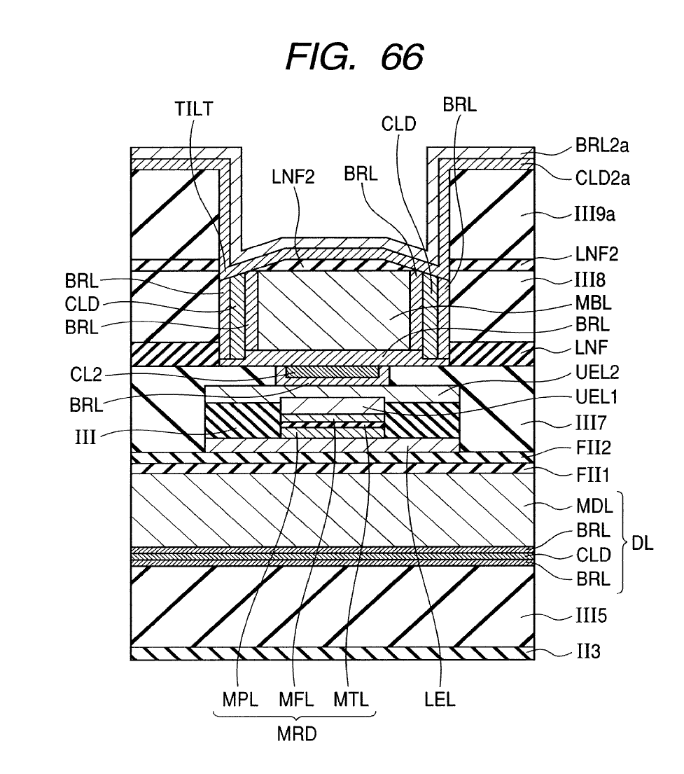

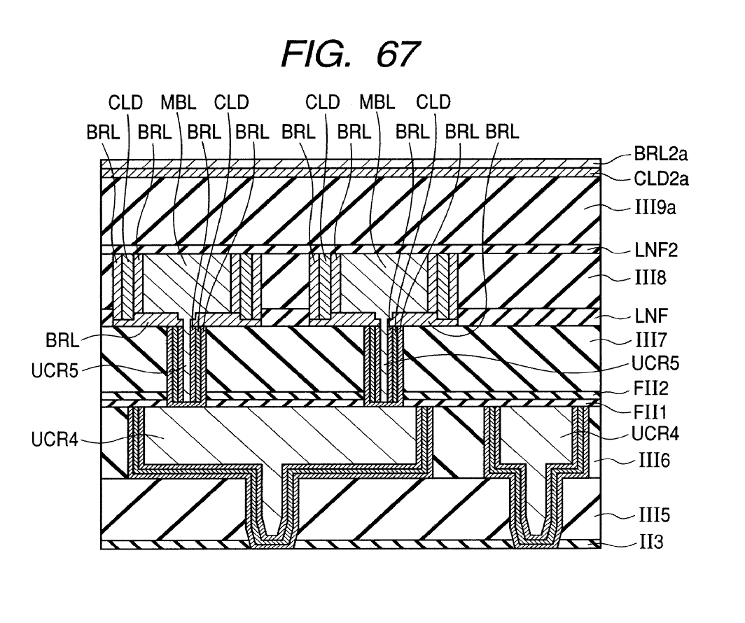

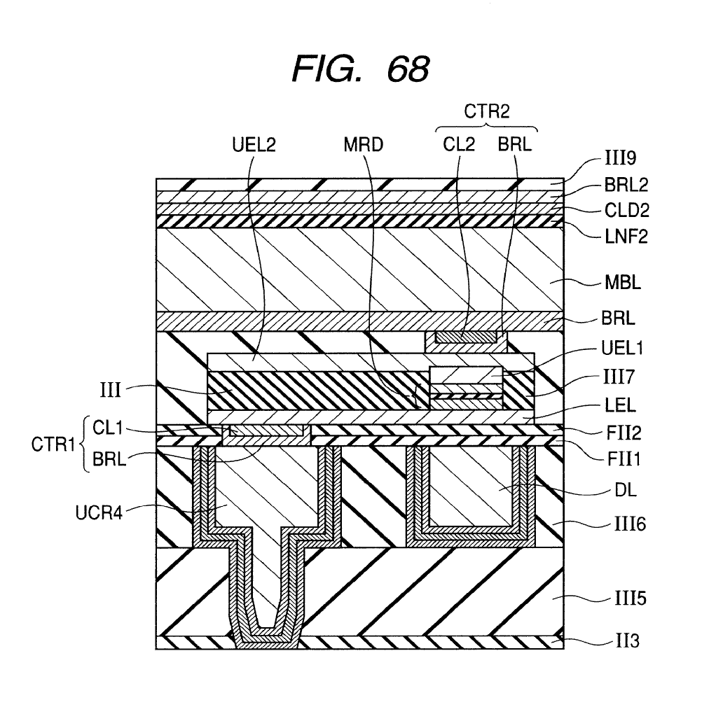

Finally, the relatively upper-side regions in FIGS. 66 and 67 of the cladding layer CLD2a and the barrier layer BRL2a are removed by, for example, CMP processing. As a result, the insulation layer III9 with the top surface planarilzed, and, the cladding layer CLD2 and the barrier layer BRL2 shown in FIGS. 68 to 70 are formed. Incidentally, in this step, the same treatment may be carried out by performing photolithography and etching in place of CMP processing.

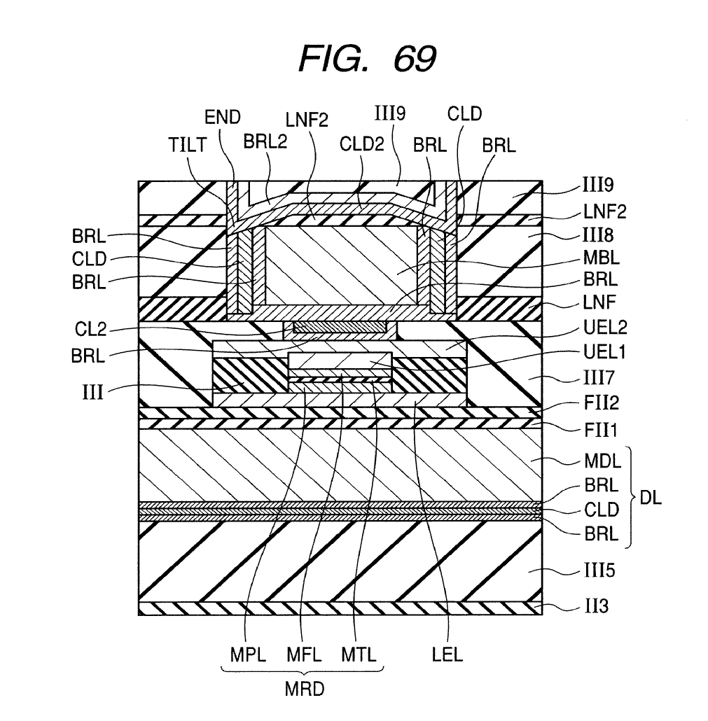

The treatment of planarizing the top surface shown in FIGS. 68 to 70 is performed. Accordingly, as shown in FIGS. 69 and 51, there is formed a protrusion end END at which the cladding layer and the barrier layer extend in such a manner as to upwardly protrude. However, the protrusion end END is, as shown in FIG. 66, a circumstantial region generated for forming the cladding layer CLD2a and the barrier layer BRL2a over the side surface of the bit-line groove BLG. For this reason, the protrusion end END can be minimized in dimensions by adjusting (increasing) the amount of removal in the removing step of the top surface part shown in FIGS. 68 to 70. The protrusion end END is a region not directly affecting the operation of the bit line BL. For this reason, for example, the cladding layer forming the protrusion end END may be in direct contact with the insulation layer III9 formed of a silicon oxide film or the like.

Thus, the semiconductor device of the present embodiment shown in FIGS. 50 to 52 is formed. Herein, a description will be given to the operational effects of the semiconductor device of the present embodiment.

For example, as in Embodiment 1, when the bit line main body part MBL and the cladding layer CLD are disposed in such a manner as to be in direct contact with each other (see FIG. 4), as indicated with an arrow in FIG. 51, atoms of the metal material such as copper forming the bit line main body part MBL and the material forming the cladding layer CLD may be diffused to each other. The cladding layer CLD, the barrier layer BRL covering the inner side of the cladding layer CLD2, and the liner film LNF2 have a role of inhibiting the mutual diffusion.

Incidentally, in the region in which the liner film. LNF2 on the top side of the bit line main body part MBL shown in FIG. 51, the barrier layer BRL (BRL2) may be disposed in place of the liner film LNF2.

Further, when the bit line main body part MBL is directly coupled with the cladding layer CLD, both may be peeled from each other. Therefore, by interposing the barrier layer BRL and the liner film LNF2 between both, it is possible to inhibit peeling of the cladding layer CLD from the bit line main body part MBL.

Further, as in Embodiment 1, when the cladding layer CLD and the insulation layers III8 and III9, and the like are disposed in such a manner as to be in direct contact with each other (see FIG. 4), the cladding layer CLD may be oxidized by the silicon oxide film or the like forming the insulation layer III8, thereby to be deteriorated in function. The barrier layers BRL and BRL2 covering the outside surfaces of the cladding layer CLD and the cladding layer CLD2, respectively, have a role of inhibiting the oxidation of the cladding layer CLD.

Then, for example, as in FIG. 4 of Embodiment 1, the angle formed between the directions of extension in cross section of the cladding layer CLD covering the side surface of the bit line main body part MBL and the cladding layer CLD covering the top surface of the bit line main body part MBL is assumed to be 90°. In this case, at the corner part of intersection of both the cladding layers CLD, there occurs a portion in which the direction of magnetic force lines passing through the inside of the cladding layer is changed by 90°.

When the angle formed between the directions of extension of respective cladding layers CLD thus crossing each other is 90° or less, upon passing a current through the bit line main body part MBL, and generating magnetic force lines passing through the inside of the cladding layer, the corner part becomes a region undergoing a sharp change in magnetization. Then, the corner part is rendered in a high-energy and unstable magnetization state.

At this step, the cladding layer CLD is about to transfer into a lower-energy and more stable state. Accordingly, the magnetization state of the vicinity of the corner part may be disturbed. Herein, the wording “the magnetization state is disturbed” means that the magnetic force lines which are essentially about to go in the direction of extension of the cladding layer CLD face other directions. When the magnetization state is thus disturbed, in order to make this closer to the direction of extension of the cladding layer CLD which is the ideal state, it becomes necessary to pass a larger current through the bit line main body part MBL.

However, as in FIG. 51, when at the corner part of intersection between the cladding layer CLD and the cladding layer CLD2, the angle formed between directions of extension of both exceeds 90°, the change in magnetization occurring at the corner part is not so sharp as that at the corner part in FIG. 4. This results in a low possibility that the corner part in FIG. 51 is rendered in a magnetization state as high in energy and unstable as the corner part in FIG. 4.

Therefore, with the configuration of FIG. 51, it is possible to reduce the possibility of occurrence of disturbance of the magnetization state in the vicinity of the corner part. Accordingly, it is possible to reduce the current to be passed through the bit line main body part MBL. Namely, it is possible to further reduce the power consumption of the semiconductor device.

Embodiment 3 of the present invention is different from Embodiment 1 of the present invention only in the respective points described up to this point. Namely, all the configurations, conditions, procedures, effects, and the like not described above for Embodiment 3 of the present invention follow those of Embodiment 1 of the present invention.

### Embodiment 4

In the present embodiment, as with Embodiment 2, the bit line BL and the second upper electrode UEL2 are directly coupled with each other. As with Embodiment 3, the cladding layers CLD covering the side surfaces and the top surface of the bit line main body part MBL are covered with the barrier layers BRL, or the like. In other words, the present embodiment has a configuration of combination of the coupling form of the bit line BL and the second upper electrode UEL2 in accordance with Embodiment 2, and the structure of the bit line BL in accordance with Embodiment 3.

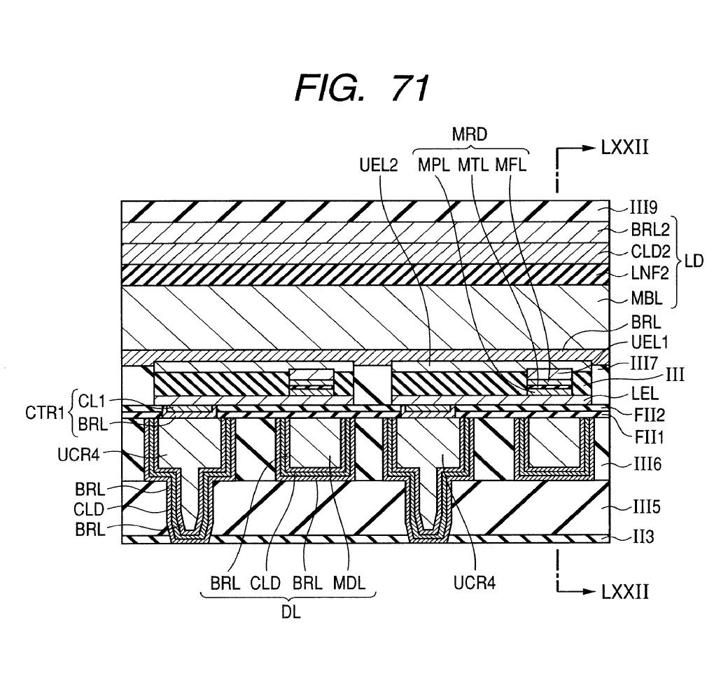

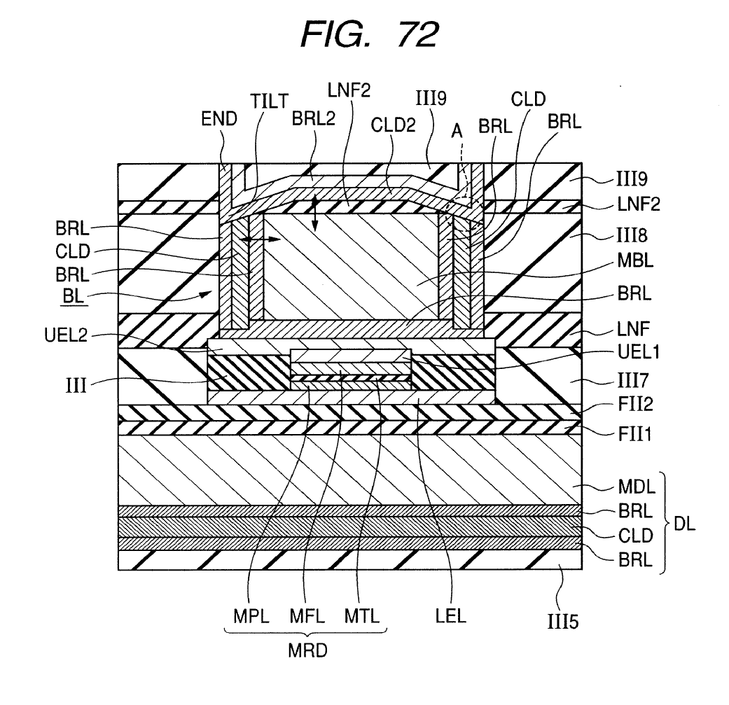

The specific form is shown in FIGS. 71 and 72. The semiconductor device having the form as in FIGS. 71 and 72 also produces the same effects as those of the semiconductor devices of respective embodiments described above.

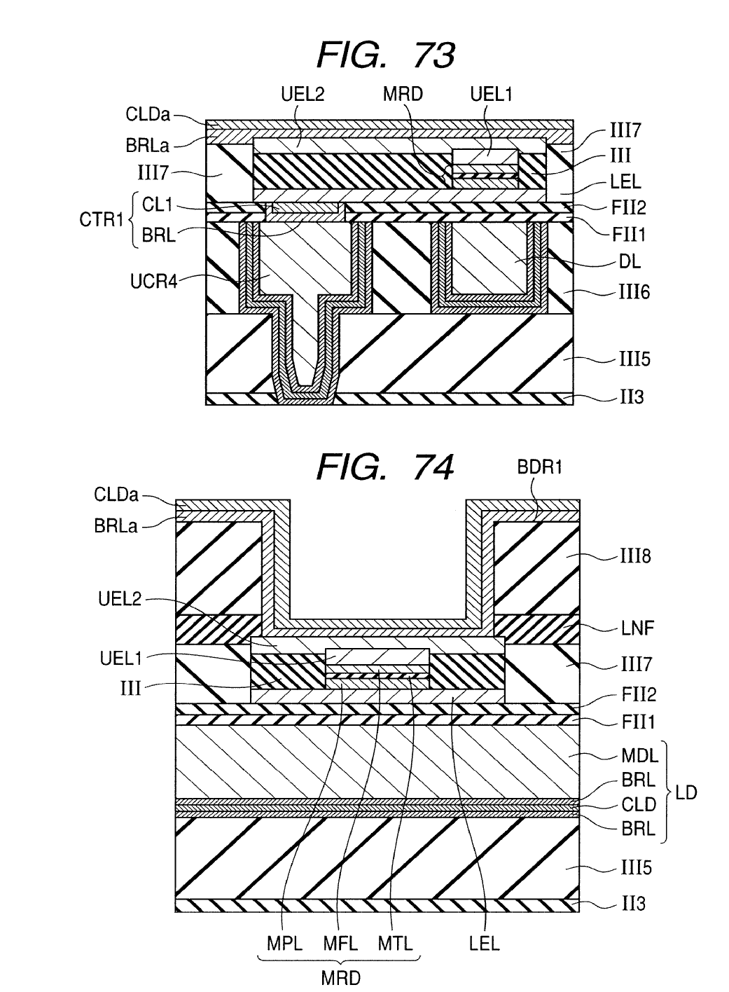

Then, a description will be given to the method for manufacturing a semiconductor device of the present embodiment. The method for manufacturing a semiconductor device of the present embodiment is the same as that of Embodiment 2 for figures before FIG. 44. Further, in FIGS. 73 to 76, the part underlying the insulation film II3 (the semiconductor substrate SUB side) is not shown.

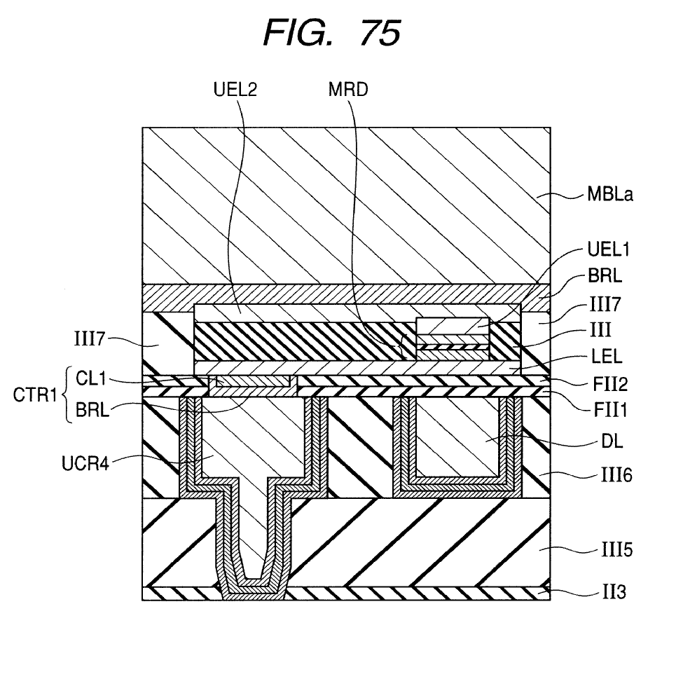

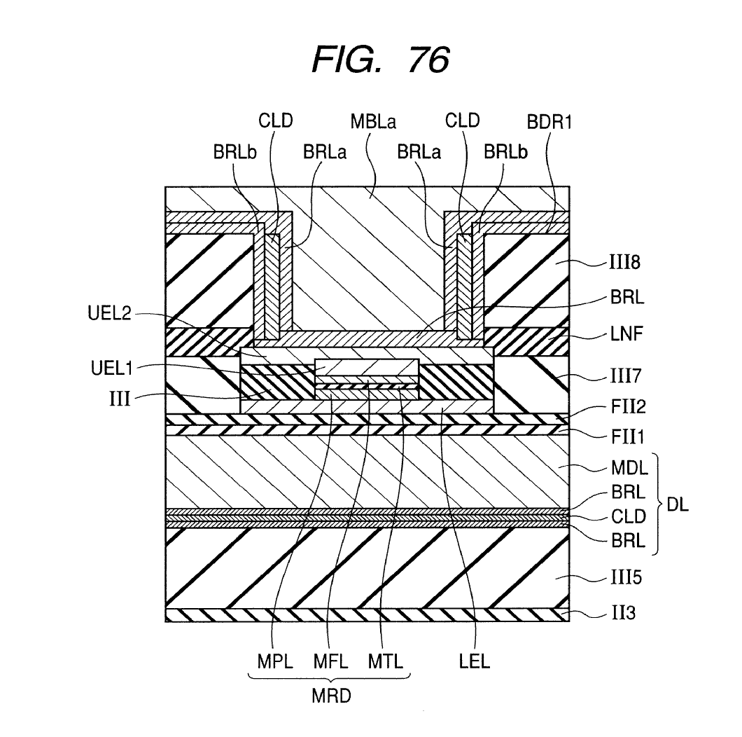

FIGS. 73 to 74, and 75 to 76 respectively show forms after performing the same step. FIGS. 73 and 75 are views as seen from the direction A. FIGS. 74 and 76 are views as seen from the direction B. Further, the steps shown in FIGS. 73 to 74 are the same as the steps shown in FIGS. 53 to 54. The steps shown in FIGS. 75 to 76 are the same as the steps shown in FIGS. 56 to 57.

Further, after the steps shown in FIGS. 75 to 76, the same treatments as those of FIGS. 59 to 70 of Embodiment 3 are performed. This results in the formation of the semiconductor device of the present embodiment shown in FIGS. 71 to 72.

Embodiment 4 of the present invention is different from Embodiments 1 to 3 of the present invention only in respective points described up to this point. Namely, all the configurations, conditions, procedures, effects, and the like not described above for Embodiment 4 of the present invention follow those of Embodiments 1 to 3 of the present invention.

### Embodiment 5

The present embodiment is different from Embodiment 1 in that the area in plan view of the magnetization pinned layer MPL of the magnetoresistive element MRD is larger than the area in plan view of the magnetization free layer MFL. Below, the configuration of the present embodiment will be described.

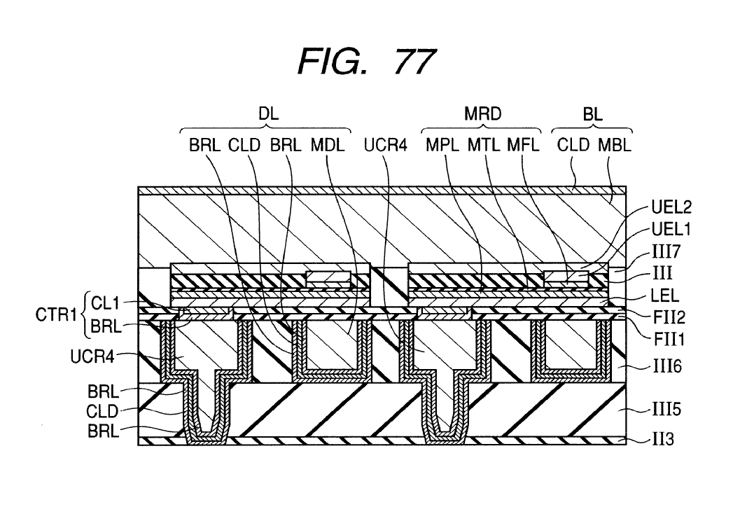

By reference to FIG. 77, in the semiconductor device of the present embodiment, the magnetization pinned layer MPL and the tunnel insulation film MTL of the magnetoresistive element MRD are substantially the same in area in plan view as the lower electrode LEL and the second upper electrode UEL2.

The tunnel insulation film MTL is preferably a thin film including, for example, AlOₓ or MgO. Further, the thickness thereof is preferably 0.5 nm or more and 2 nm or less.

Incidentally, in the semiconductor device of FIG. 77, the area in plan view of the magnetization pinned layer MPL of the semiconductor device of Embodiment 1 is larger than the area in plan view of the magnetization free layer MFL. However, the area in plan view of the magnetization pinned layer MPL of each semiconductor device of Embodiments 2 to 4 may be set larger than the area in plan view of the magnetization free layer MFL.

Then, a description will be given to the method for manufacturing a semiconductor device of the present embodiment. The method for manufacturing a semiconductor device of the present embodiment is basically the same as the method for manufacturing a semiconductor device of Embodiment 1, and hence is not shown. In the step corresponding to FIG. 22 of Embodiment 1, etching is performed so that the first upper electrode UEL1 and the magnetization free layer MFL are patterned, i.e., so that the insulation film MTLa is not patterned as an etching stopper.

Then, in the step corresponding to FIG. 26 of Embodiment 1, the insulation film MTLa is, as with the conductive film MPLa and the conductive film LELa, patterned using the second upper electrode UEL2 as a hard mask. As a result, the tunnel insulation film MTL, the magnetization pinned layer MPL, and the lower electrode LEL are formed. Other steps follow the method for manufacturing a semiconductor device of Embodiment 1.

Then, a description will be given to the operational effects of the semiconductor device of the present embodiment. In the semiconductor device of the present embodiment, the area in plan view of the magnetization pinned layer MPL of the magnetoresistive element MRD is larger than the area in plan view of the magnetization free layer MFL. This can be implemented in the following manner: in the step of FIG. 22 showing the manufacturing method of Embodiment 1, when the magnetoresistive element MRD is patterned by etching, the etching is stopped by the tunnel insulation film MTL in the magnetoresistive element MRD. This is for the following reason: the material forming the magnetization free layer MFL and the material forming the tunnel insulation film MTL of the magnetoresistive element MRD have an etching selectivity therebetween; and hence the layer to be the magnetization free layer MFL and the layer to be the tunnel insulation film MTL are less likely to be simultaneously etched.

The tunnel insulation film MTL is not etched. Accordingly, this can inhibit etching of the underlying layer to be the magnetization pinned layer MPL (conductive film MPLa), and layer to be the lower electrode LEL (conductive film LELa). For this reason, it is possible to inhibit the following from occurring: for example, the magnetization free layer MFL is affected by the leaked magnetic field from the magnetization pinned layer MPL, erroneously resulting in a change in electrical resistance.

Embodiment 5 of the present invention is different from Embodiment 1 of the present invention only in the respective points described up to this point. Namely, all the configurations, conditions, procedures, effects, and the like not described above for Embodiment 5 of the present invention follow those of Embodiment 1 of the present invention.

### Embodiment 6

The present embodiment is different from Embodiment 2 in form of the side surface portion of the protective layer III. Below, the configuration of the present embodiment will be described.

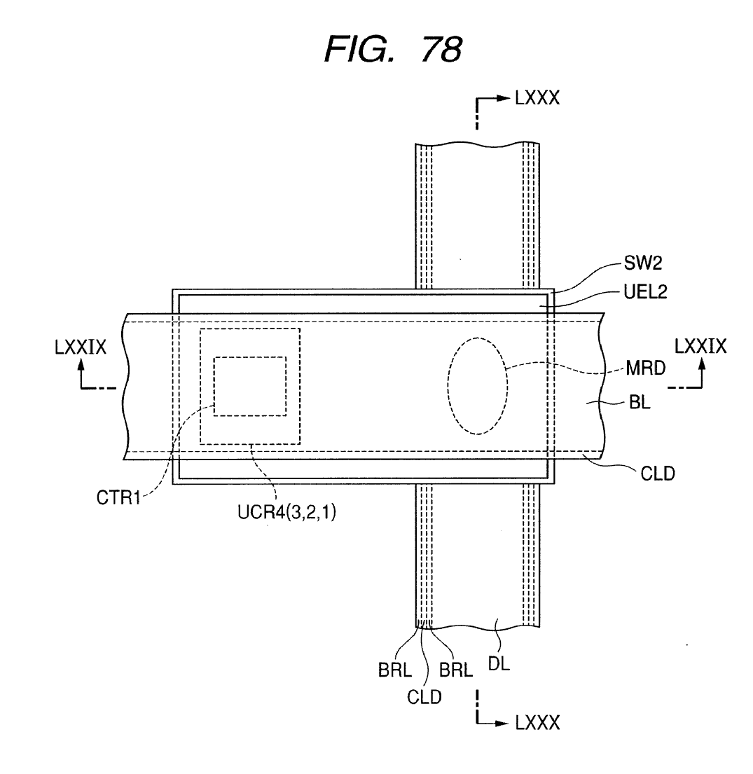

By reference to FIGS. 78 to 80, the semiconductor device of the present embodiment includes a sidewall SW2 (sidewall insulation film) formed in such a manner as to cover the side surface of the lamination structure of the second upper electrode UEL2, the protective layer III, and the lower electrode LEL. Incidentally, the side surface herein denotes the outer circumferential side surface extending in the direction of lamination of the second upper electrode UEL2, the protective layer III, and the lower electrode LEL.

The sidewall SW2 is preferably a thin film including SiN as with the protective layer III. However, the sidewall SW2 may be a thin film including SiO₂, AlOₓ, or SiON in place of SiN.

Further, the sidewall SW2 covers the side surfaces of the second upper electrode UEL2, the protective layer III, and the lower electrode LEL. For this reason, the thickness (along the vertical direction of FIGS. 78 to 80) thereof is preferably 5 nm or more and 100 nm or less.

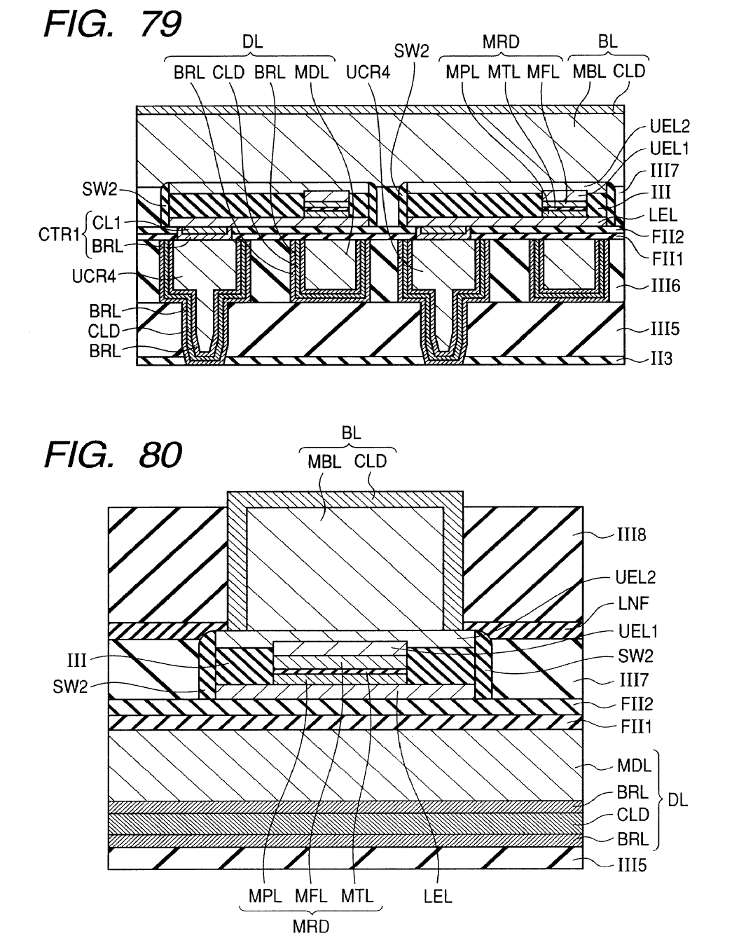

As shown in FIGS. 79 and 80, the sidewall SW2 often has a cross-sectional shape in which a part of the top (on the second upper electrode UEL2 side) has been removed by etching during formation. More specifically, as shown in FIGS. 79 and 80, in the sidewall SW2, the upper end is rounded, and the width in the left-right direction is narrower than those of other regions.

For this reason, the sidewall SW2 preferably covers at least the side surface of the lower electrode LEL.

Incidentally, the semiconductor device of FIGS. 78 to 80 is configured by adding the sidewall SW2 to the semiconductor device of Embodiment 2. However, it may be configured by adding the same sidewall SW2 as in FIGS. 78 to 80 to each semiconductor device of Embodiment 1 or Embodiments 3 to 5.

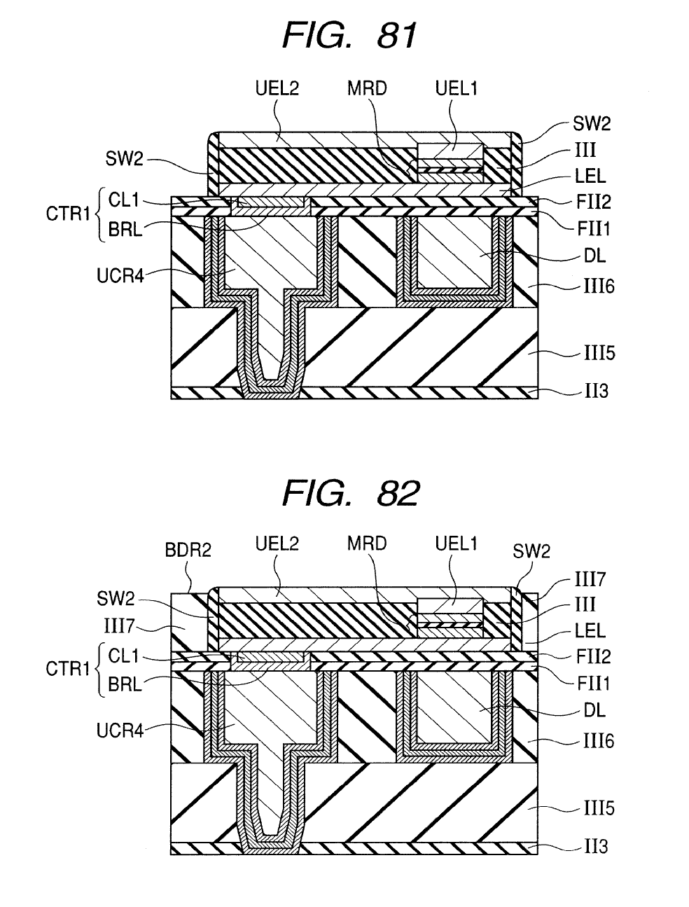

Then, a description will be given to the method for manufacturing the semiconductor device of the present embodiment. The method for manufacturing a semiconductor device of the present embodiment shown in FIGS. 78 to 80 is the same as that of Embodiment 1 for figures before FIG. 26. Further, in FIGS. 81 to 82, the part underlying the insulation film II3 (the semiconductor substrate SUB side) is not shown.

As shown in FIG. 26, upon formation of the lamination structure of the second upper electrode UEL2, the protective layer III, and the lower electrode LEL, a layer to be the sidewall SW2 is formed in such a manner as to cover the top of the second upper electrode UEL2 and the top of the flat insulation film FII2.

Thereafter, with a portion of the layer to be the sidewall SW2 left only by a given thickness in the direction along the main surface of each lamination structure from the side surface of the lamination structure of the second upper electrode UEL2, the protective layer III, and the lower electrode LEL, portions of the layer to be the sidewall SW2 in other regions and over the second upper electrode UEL2 are removed. Thus, the sidewall SW2 as shown in FIG. 81 is formed.

Then, for example, the same step as that in Embodiment 2 shown in FIGS. 27 and 44 is performed. As a result, as shown in FIG. 82, the insulation layer III7 is formed. From this onward, the same steps as those in Embodiment 2 shown in FIGS. 45 to 49 are performed. Thus, the semiconductor device of the present embodiment shown in FIGS. 78 to 80 is formed.

Then, the operational effects of the semiconductor device of the present embodiment will be described. When the sidewall SW2 is formed as in the semiconductor device of the present embodiment, in addition to the magnetoresistive element MRD with the side surface covered with the protective layer III, the side surface of the lower electrode LEL is also covered with the sidewall SW2 including SiN. This can inhibit the occurrence of the following defective condition: for example, at the time of etching of the insulation layer III7, apart of the side surface of the lower electrode LEL is exposed, which causes a short circuit between the bit line BL and the lower electrode LEL.

The insulation layer III7a shown in FIG. 27 is etched to a desirable thickness, thereby to form the insulation layer III7. At this step, the insulation layer III7 may be erroneously etched to a deeper site than the desirable thickness. This is for the following reason: the material such as SiO₂ forming the insulation layer III7 has a property of being more likely to be cut by etching or a CMP treatment than the metal material such as Ta forming the second upper electrode UEL2.

In other words, in the foregoing step, even when the second upper electrode UEL2, the protective layer III, or the like can be kept in a desirable shape without being excessively etched, for example, upon formation of the insulation layer III7 by etching of the insulation layer III7a covering the side surfaces of the second upper electrode UEL2, the protective layer III, and the lower electrode LEL, the insulation layer III7a may be excessively etched to expose the lower electrode LEL.

Thus, the sidewall SW2 is disposed in such a manner as to cover the side surface of the lower electrode LEL. As a result, even when the insulation layer III7a in the vicinity of the side surface of the lower electrode LEL is etched, the sidewall SW2 has a role of inhibiting exposure of the lower electrode LEL. The sidewall SW2 includes, as with the protective layer III, a material having a high selectivity in etching relative to the insulation layer III7a (insulation layer III7). For this reason, the sidewall SW2 is less likely to be etched at the time of etching of the insulation layer III7a.

Therefore, by disposing the sidewall SW2, it is possible to set the margin for etching amount in the thickness direction (vertical direction) when the insulation layer III7a is etched.

Embodiment 6 of the present invention is different from Embodiment 2 of the present invention only in respective points described up to this point. Namely, all the configurations, conditions, procedures, effects, and the like not described above for Embodiment 6 of the present invention follow those of Embodiment 2 of the present invention.

### Embodiment 7

The present embodiment is different from Embodiment 2 in the configuration and the operation principle of the semiconductor device. Below, the configuration of the present embodiment will be described.

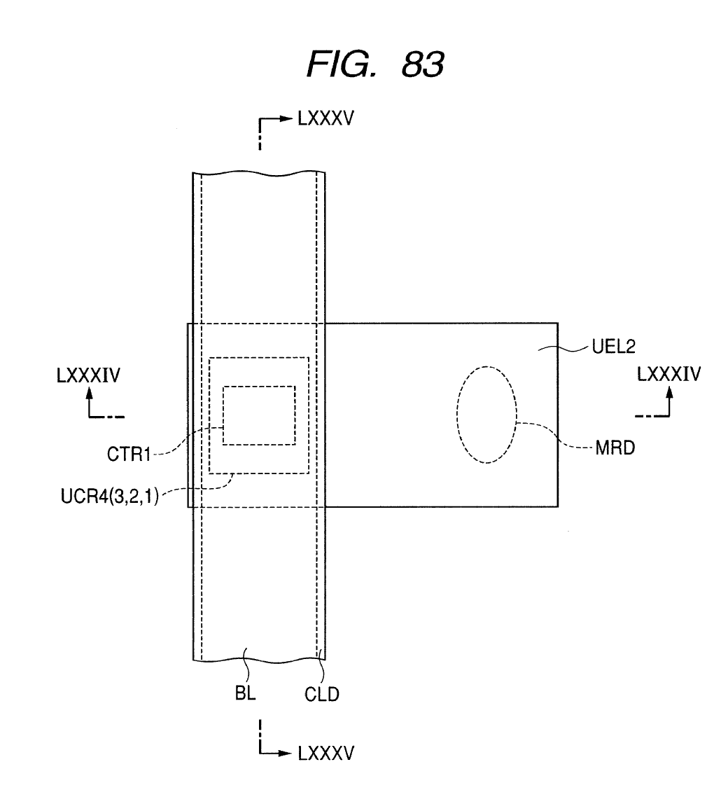

In the semiconductor device of the present embodiment, by reference to FIGS. 83 to 85, there is no digit line DL under the magnetoresistive element MRD. Further, the direction of extension of the bit line BL is, for example, the direction crossing the direction of extension of the bit line BL of the semiconductor device of Embodiment 1 or 2.

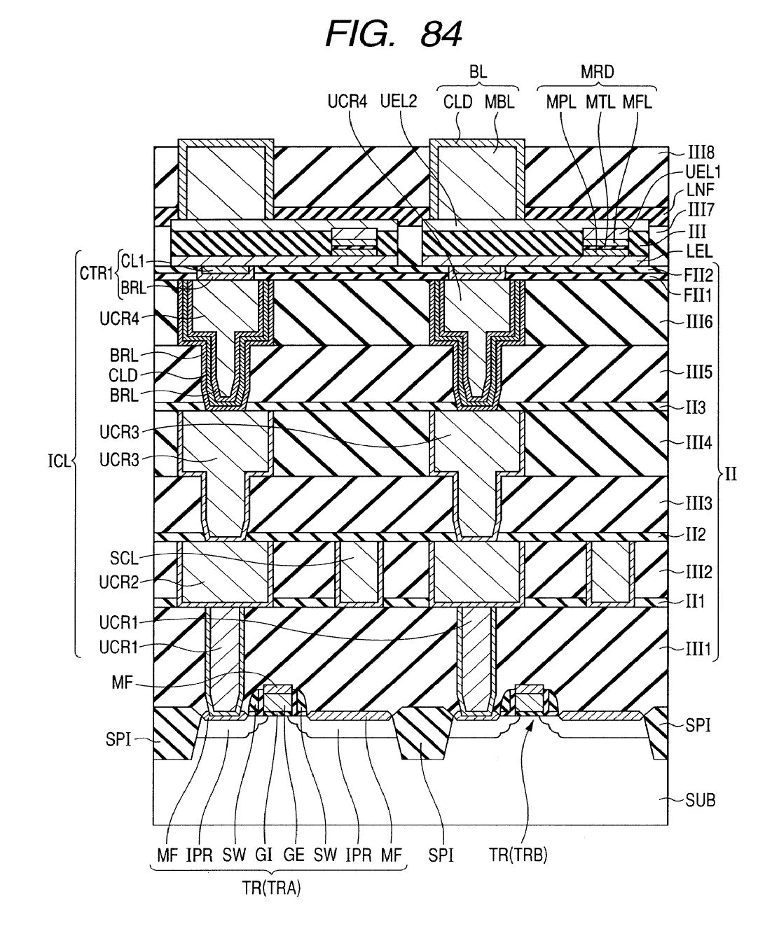

The bit line BL is disposed in a region separated from the top of the magnetoresistive element MRD in the direction along the main surface of the lamination structure forming the semiconductor device (the horizontal direction of FIG. 84). Specifically, over the extension of a straight line connecting the unit contact parts UCR1, UCR2, UCR3, and UCR4 (in the vertical direction of FIG. 84), the bit line BL is disposed.

In the semiconductor device of the present embodiment, as with the semiconductor device of Embodiment 2, there is also no contact part CTR2 coupling the second upper electrode UEL2 with the bit line BL, so that the second upper electrode UEL2 and the bit line BL (wiring) are directly coupled with each other.

Further, in the semiconductor device of the present embodiment, as with the semiconductor device of Embodiment 2, a direct coupling is also established in such a manner that a partial region of the second upper electrode UEL2 is embedded in the inside of the bit line BL (bit line main body part MBL).

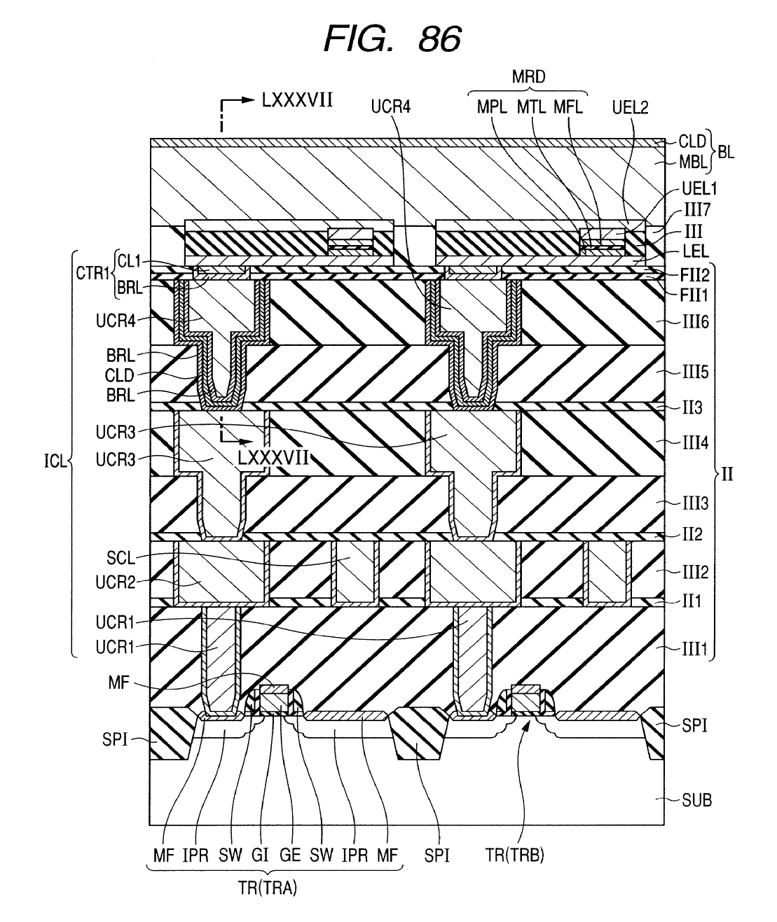

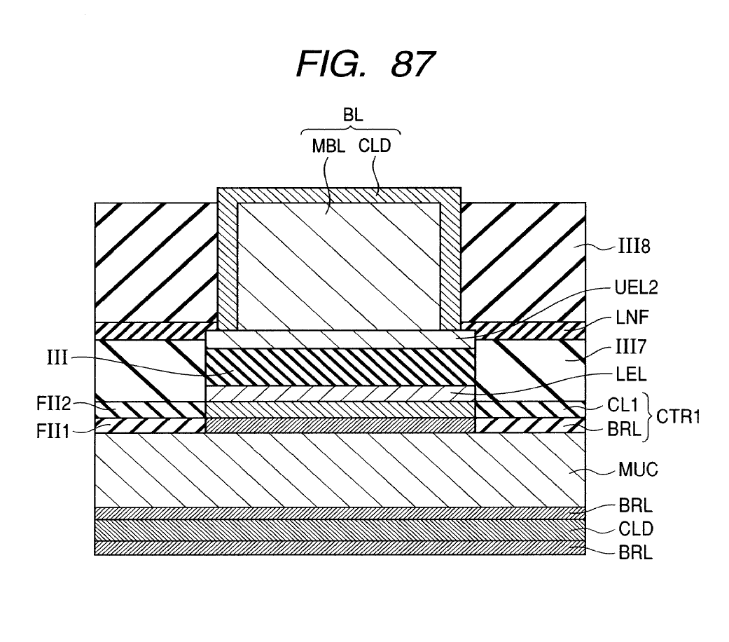

However, in the semiconductor device of the present embodiment, for example, as shown in FIGS. 86 and 87, the direction of extension of the bit line BL may be also the same as the direction of extension of the bit line BL of the semiconductor device of Embodiment 1 or 2. The semiconductor device shown in FIGS. 86 and 87 is different from the semiconductor device (shown in FIGS. 40 and 41) of Embodiment only in not having the digit line DL.

Incidentally, in the semiconductor device of FIGS. 83 to 87, the bit line BL and the coupling part between the bit line BL and the second upper electrode UEL2 have the same forms as those in Embodiment 2. However, in the semiconductor device of the present embodiment, for example, the same bit line BL as that in Embodiment 3 or 4 may be used. For example, as in Embodiment 1, the contact part CTR2 may be used to couple the bit line BL and the second upper electrode UEL2. Further, as with Embodiment 5, the area in plan view of the magnetization pinned layer MPL of the magnetoresistive element MRD may be larger than the area in plan view of the magnetization free layer MFL. Such a semiconductor device produces the same operational effects as those of the semiconductor devices of respective embodiments.

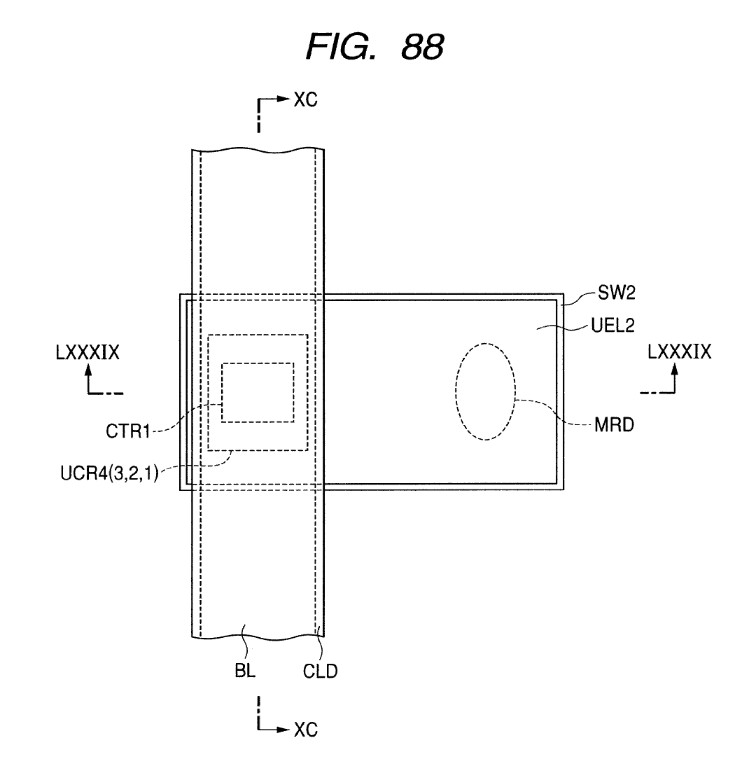

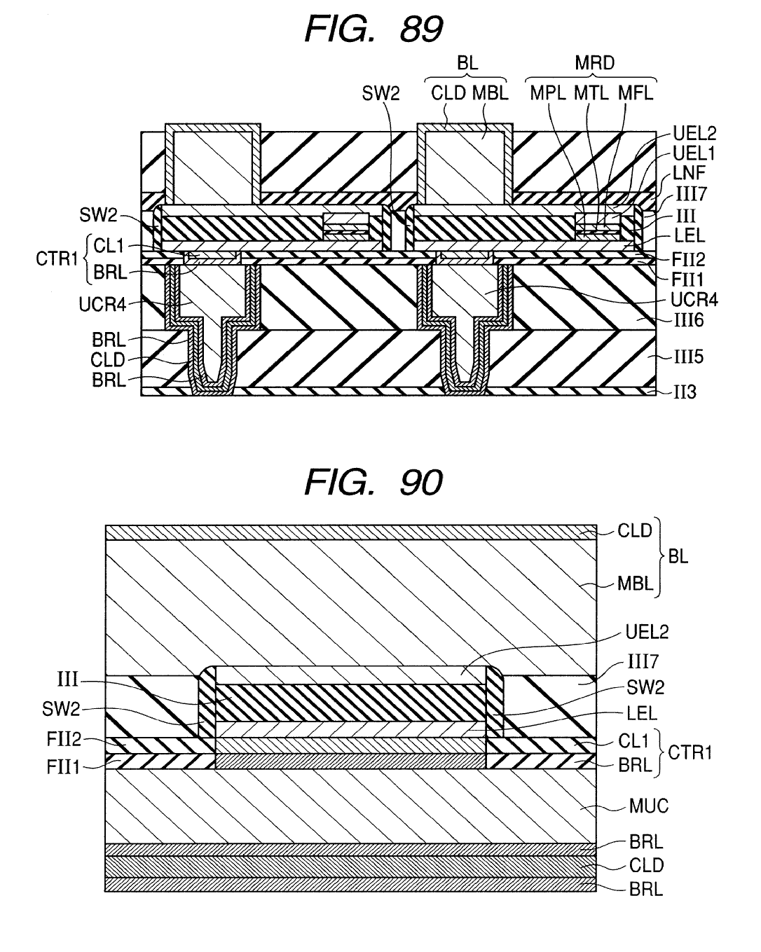

Alternatively, for example, in the semiconductor device of FIGS. 83 to 85, particularly on the lamination structure of the second upper electrode UEL2, the protective layer III, and the lower electrode LEL, the sidewall SW2 shown in Embodiment 6 may be provided. FIGS. 88 to 90 each show the form of the semiconductor device in that case. Such a semiconductor device produces the same operational effects as those of the semiconductor device of Embodiment 6.

Then, the operation principle of the semiconductor device having the foregoing configuration will be described. In each semiconductor device of Embodiments 1 to 6, there are disposed a plurality of so-called standard MRAMs in which the synthetic magnetic field formed by the currents flowing through the bit line BL and the digit line DL changes the direction of magnetization of the magnetization free layer MFL of the magnetoresistive element MRD.

In contrast, in the semiconductor device of Embodiment 7, there are disposed a plurality of so-called STT (Spin Transfer Torque)-MRAMs in which the current path from the bit line BL through the magnetoresistive element MRD, and a plurality of unit contact parts to the MOS transistors TR performs both of rewriting of data to the magnetoresistive element MRD, and reading of data from the magnetoresistive element MRD.

The principle of rewriting is as follows. First, a desirable MOS transistor TR is selected, and the switch is turned ON. Then, a current is passed through the current path.

At this step, for example, electrons are supplied from the MOS transistor TR side to the bit line BL side, thereby to pass a current. As a result, only the electrons having the same spin direction as the direction of magnetization of the magnetization pinned layer MPL are injected into the inside of the magnetization free layer MFL beyond the tunnel insulation film MTL. Then, the electrons having the spin direction opposite to the direction of magnetization of the magnetization pinned layer MPL are reflected by the magnetization pinned layer MPL. In other words, these electrons cannot reach the inside of the magnetization free layer MFL. As a result, the direction of magnetization of the magnetization free layer MFL becomes the same as the direction of magnetization of the magnetization pinned layer MPL.

In contrast, electrons are supplied from the bit line BL side to the MOS transistor TR side, thereby to pass a current. As a result, the electrons having the same spin direction as the direction of magnetization of the magnetization pinned layer MPL pass through the magnetization pinned layer MPL. Then, the electrons having the spin direction opposite to the direction of magnetization of the magnetization pinned layer MPL are reflected by the magnetization pinned layer MPL. In other words, these electrons move in the reverse direction to be injected into the inside of the magnetization free layer MFL. As a result, the direction of magnetization of the magnetization free layer MFL becomes opposite to the direction of magnetization of the magnetization pinned layer MPL.

Thus, as with the standard MRAM, the electrical resistance of the magnetoresistive element MRD changes. The difference in the resistance value is utilized as information corresponding to “0” or “1”.

Incidentally, the principle on which the STT-MRAM reads the information from the selected magnetoresistive element MRD is the same as with the standard MRAM.

Then, the method for manufacturing a semiconductor device of the present embodiment will be described. Herein, a description will be given to the method for manufacturing a semiconductor device shown in FIGS. 83 to 85.

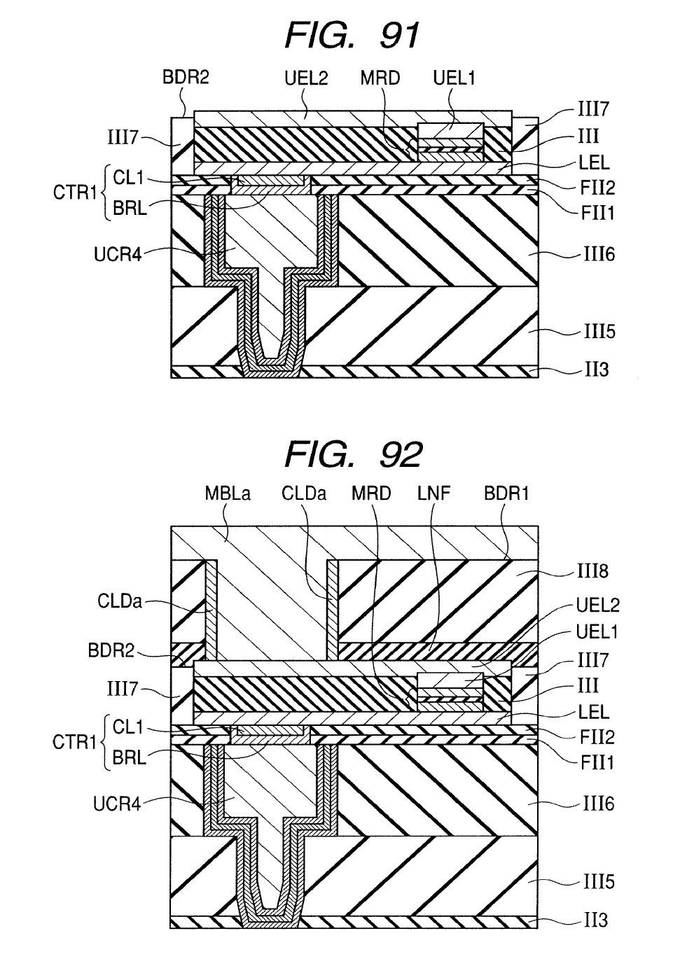

The method for manufacturing a semiconductor device of the present embodiment is the same as that of Embodiment 1 for FIGS. 8 to 27 described above, except that the digit line DL is not formed. Further, in FIGS. 91 to 95, the part underlying the insulation film II3 (the semiconductor substrate SUB side) is not shown.

Upon formation of the insulation layer III7a as in FIG. 27, then, as shown in FIG. 91, (as in FIG. 44), the region from the surface on the top side to a given depth of the insulation layer III7a is subjected to a CMP treatment. Thus, polishing is performed so that at least the uppermost surface of the second upper electrode UEL2 is exposed. The polishing makes the insulation layer III7a into the insulation layer III7. However, although not shown in FIG. 91, as with Embodiment 1, only in the region in which the groove for forming the bit line BL is formed, the insulation layer III7a is polished and removed. In other regions, the insulation layer III7 may be formed without polishing and removing the insulation layer III7a

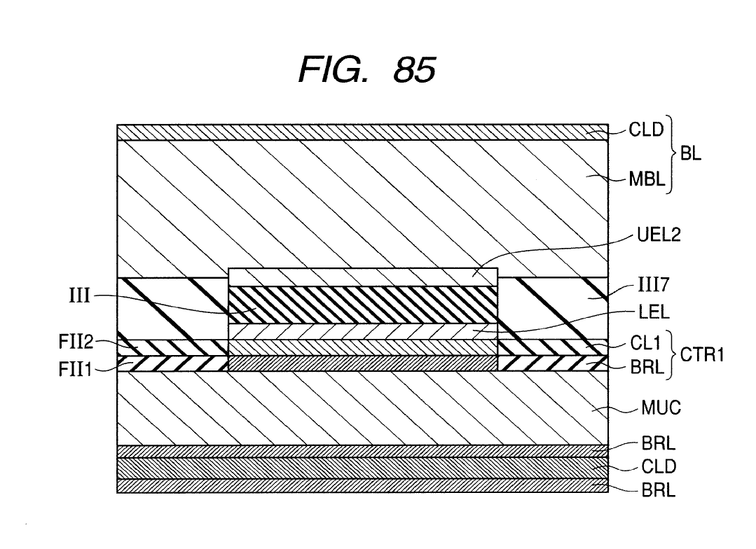

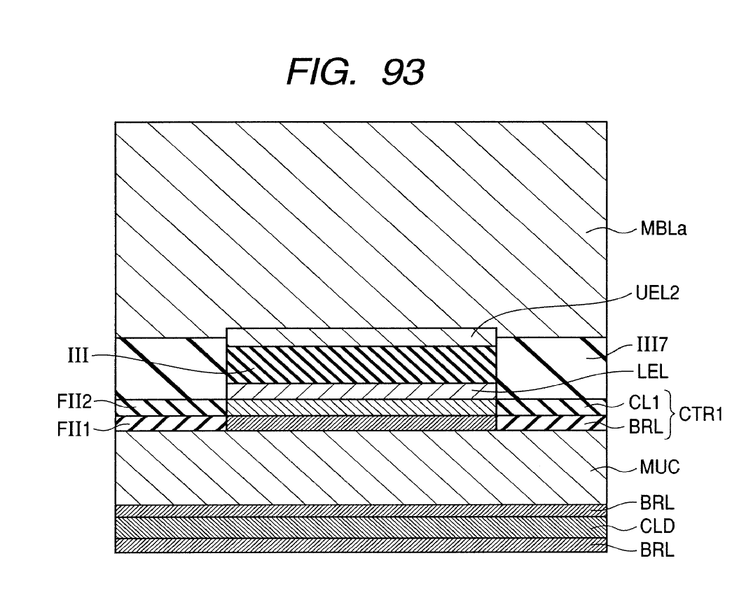

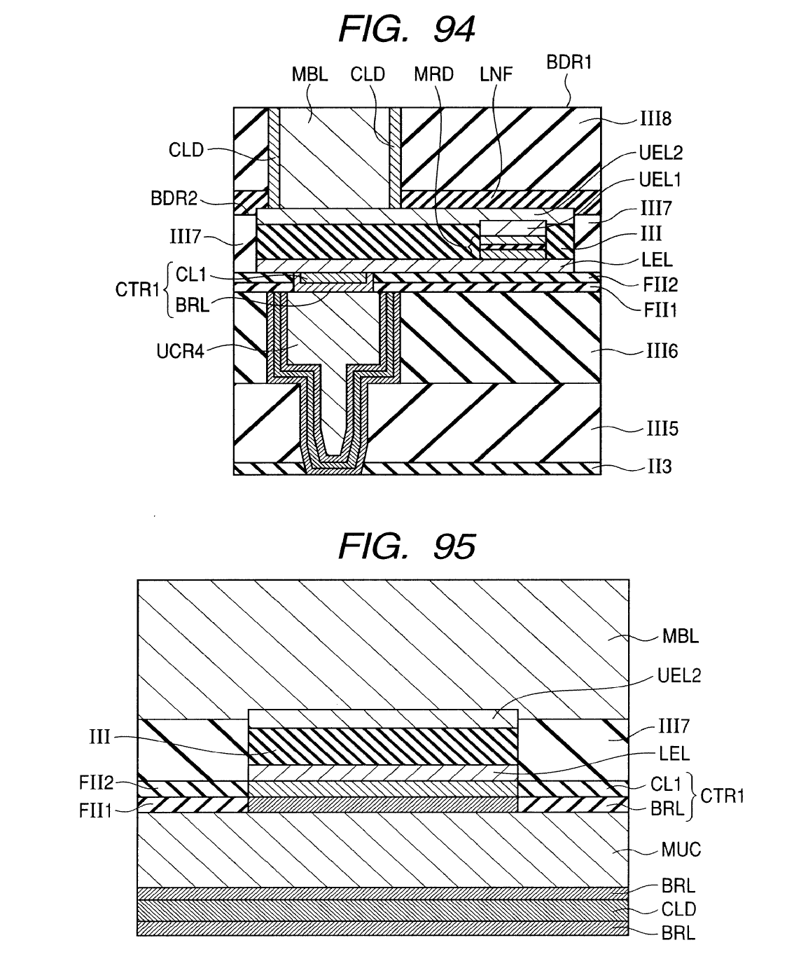

Subsequent FIGS. 92 and 93, and FIGS. 94 and 95, each show a form after performing the same step. FIGS. 92 and 94 are views as seen from the direction A. FIGS. 93 and 95 are views as seen from the direction B. However, FIGS. 93 and 95 each show a cross-sectional view at the same site as that in FIG. 85 and FIG. 87.

The steps shown in FIGS. 92 to 93 are the same as the steps shown in FIGS. 30 to 31. The steps shown in FIGS. 94 to 95 are the same as the steps shown in FIGS. 33 to 34. However, the direction of extension of the groove formed in FIGS. 92 to 93 crosses the direction of extension of the groove formed in FIGS. 30 to 31 (extends in the direction of about 90° with respect to the direction of extension of the groove formed in FIGS. 30 to 31).

As a result, the direction of extension of the bit line main body part MBL formed in FIGS. 94 to 95 crosses the direction of extension of the bit line main body part MBL formed in FIGS. 33 to 34 (extends in the direction of about 90° with respect to the direction of extension of the groove formed in FIGS. 33 to 34). In other words, the bit line main body part MBL herein formed crosses each bit line main body part MBL formed in Embodiments 1 to 6 at an angle of about 90° in the planar direction along the main surface of the second upper electrode UEL2.

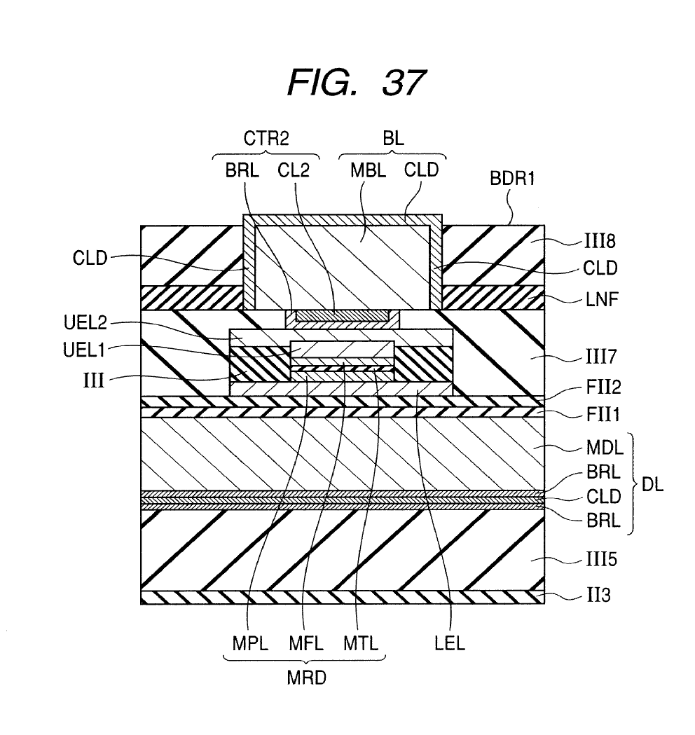

Then, as with FIGS. 36 to 37, the cladding layer CLD is formed, resulting in formation of the semiconductor device of the present embodiment shown in FIGS. 83 to 85.

Then, a description will be given to the operational effects of the semiconductor device of the present embodiment. In the semiconductor device of Embodiment 7, for example, as shown in FIG. 92, a groove extending along the main surface of the second upper electrode UEL2, for forming the bit line BL is formed in a region apart from the top of the magnetoresistive element MRD. Conversely, the magnetoresistive element MRD is not disposed immediately under the groove. This can inhibit the defective conditions such as etching and exposure damages of the magnetoresistive element MRD due to excessive etching in the thickness direction of the insulation layer III7a for forming the groove.

Embodiment 7 of the present invention is different from Embodiment 2 of the present invention only in respective points described up to this point. Namely, all the configurations, conditions, procedures, effects, and the like not described above for Embodiment 7 of the present invention follow those of Embodiment 2 of the present invention.

### Embodiment 8

The present embodiment is different from Embodiment 7 in configuration of the STT-MRAM. Below, the configuration of the present embodiment will be described.

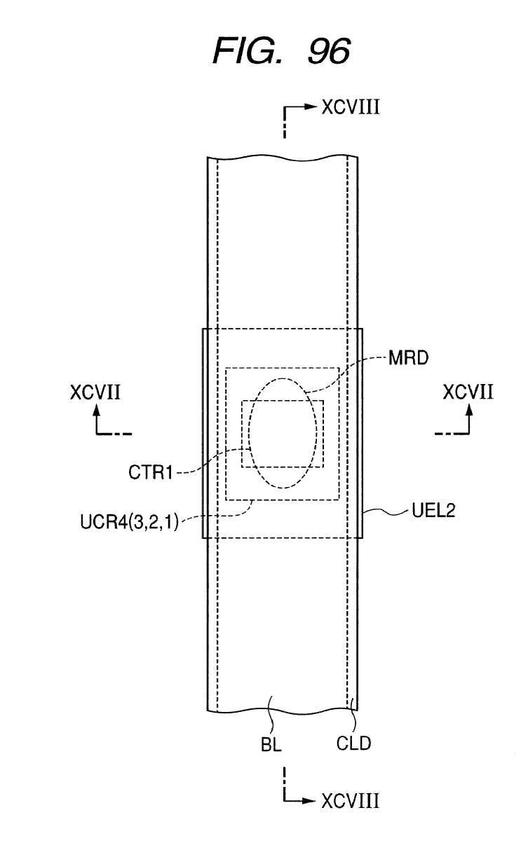

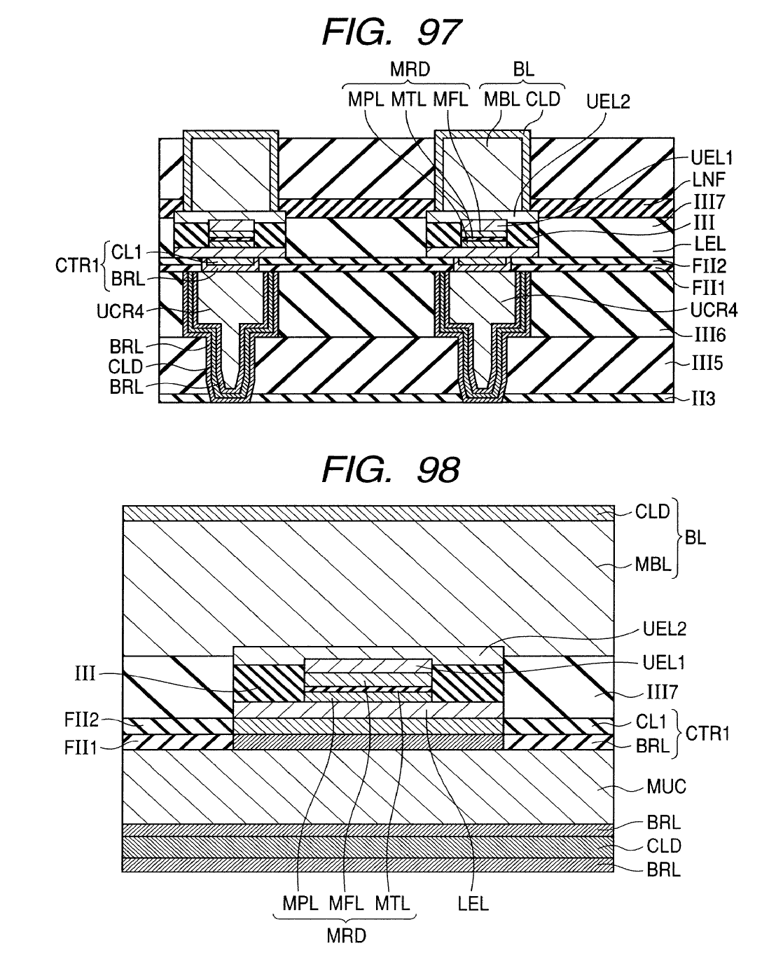

By reference to FIGS. 96 to 98, in the semiconductor device of Embodiment 8, the bit line BL is disposed immediately over the top of the magnetoresistive element MRD in the direction along the main surface of the lamination structure forming the semiconductor device (the horizontal direction of FIG. 84). In other words, the bit line BL, the magnetoresistive element MRD, and a plurality of unit contact parts are disposed, for example, along and on the straight line extending in the vertical direction of FIG. 97. In only the foregoing points, the semiconductor device of Embodiment 8 is different from the semiconductor device of Embodiment 7.

For this reason, the lower electrode LEL and the second upper electrode UEL2 of the semiconductor device of FIG. 97 are smaller in area in plan view than the lower electrode LEL and the second upper electrode UEL2 of the semiconductor device of FIG. 84. The STT-MRAM having such a configuration is smaller in occupancy area in plan view than the STT-MRAM having the configuration as that of Embodiment 7. Therefore, the semiconductor device of Embodiment 8 can be more improved in integration degree of the STT-MRAM than the semiconductor device of Embodiment 7. The semiconductor device of the present embodiment has the foregoing operational effects together with the operational effects of the semiconductor device of Embodiment 2.

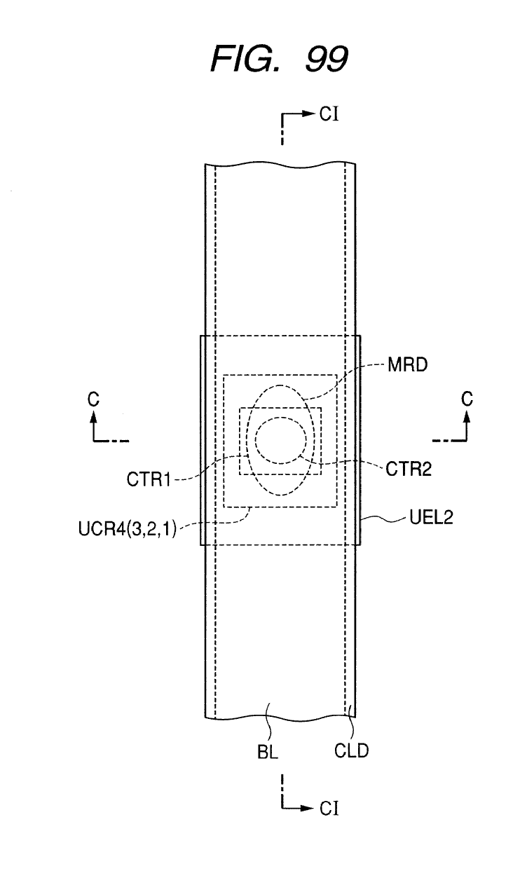

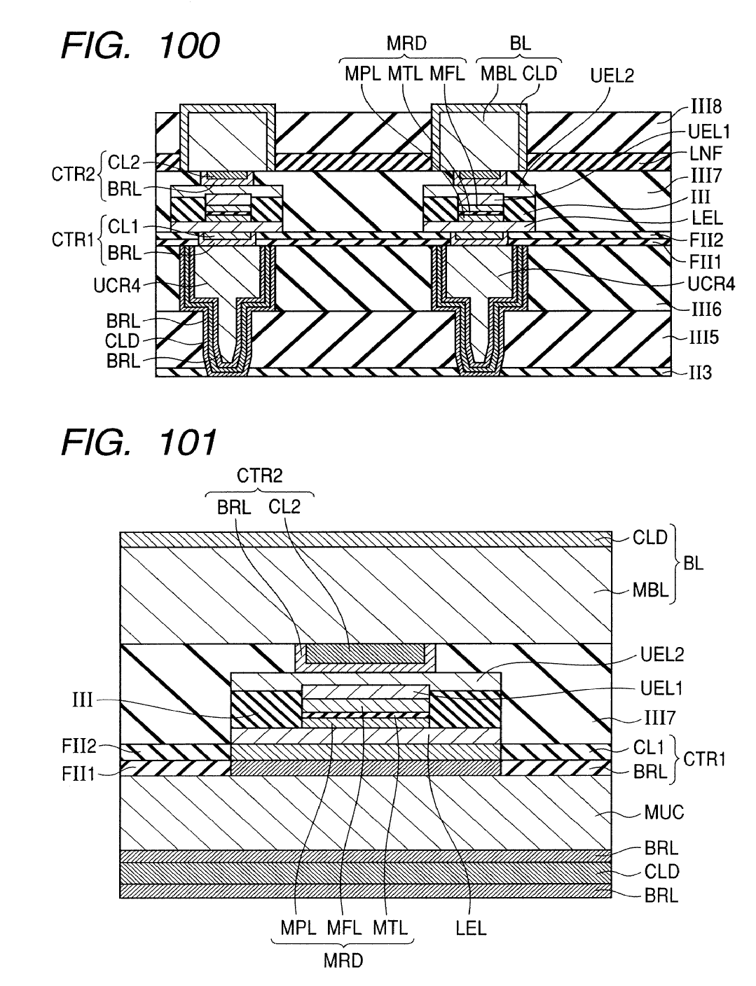

Incidentally, in the semiconductor device of FIGS. 96 to 98, the bit line BL, and the coupling part between the bit line BL and the second upper electrode UEL2 have the same forms as those of Embodiment 2. However, in the semiconductor device of the present embodiment, for example, as in Embodiment 1, using the contact part CTR2, the bit line BL and the second upper electrode UEL2 may be coupled to each other. FIGS. 99 to 101 each show the form of the semiconductor device in that case. Such a semiconductor device produces the same operational effects as those of the semiconductor device of Embodiment 1.

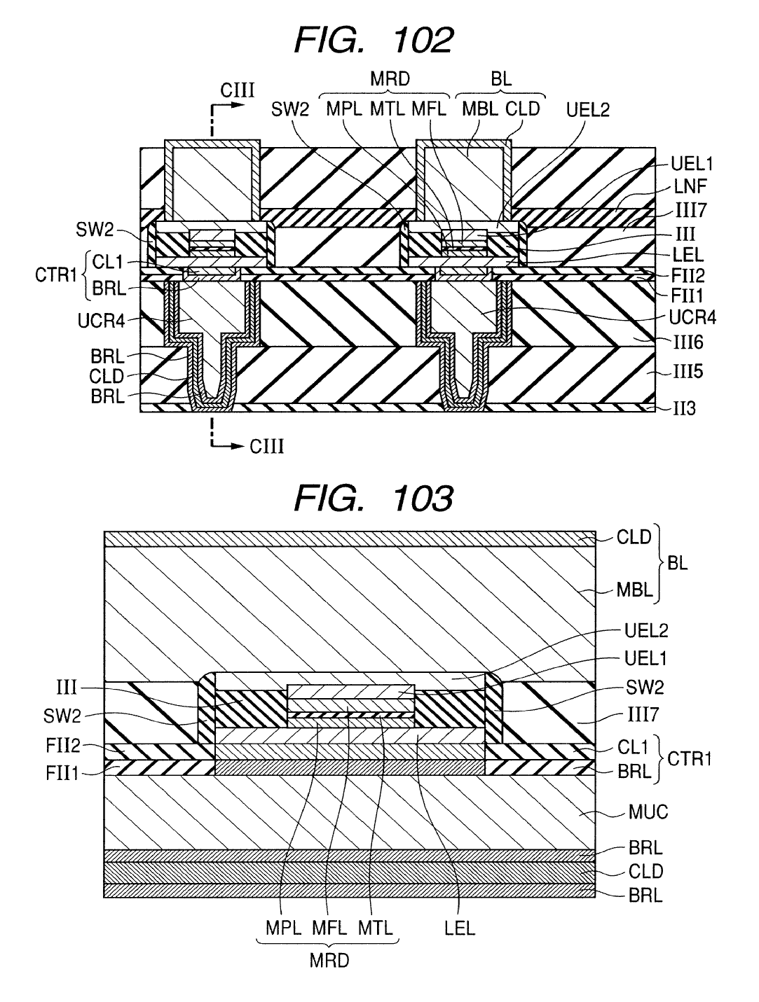

Further, for example, particularly, on the lamination structure of the second upper electrode UEL2, the protective layer III, and the lower electrode LEL of the semiconductor device of FIGS. 96 to 98, the sidewall SW2 shown in Embodiment 6 may be provided. FIGS. 102 and 103 each show a form of the semiconductor device in that case. Such a semiconductor device produces the same operational effects as those of the semiconductor device of Embodiment 6.

Further, in the semiconductor device of the present embodiment, the direction of extension of the bit line BL may also be the same as the direction of extension of the bit line BL of the semiconductor device of Embodiment 1 or 2. Further, as with Embodiment 5, the magnetization pinned layer MPL of the magnetoresistive element MRD may be larger in area in plan view than the magnetization free layer MFL.

The method for manufacturing a semiconductor device of the present embodiment is the same process as the method for manufacturing a semiconductor device of Embodiment 7, and hence is not shown. However, patterning is performed so that the position (position in plan view) at which the lower electrode LEL, the second upper electrode UEL2, or the like is formed or dimensions thereof, and the position (position in plan view) at which the magnetoresistive element MRD is formed are different from those in Embodiment 7.

Embodiment 8 of the present invention is different from Embodiment 7 of the present invention only in respective points described up to this point. Namely, all the configurations, conditions, procedures, effects, and the like not described above for Embodiment 8 of the present invention follow those of Embodiment 7 of the present invention.

It should be considered that the embodiments herein disclosed are illustrative and are not restrictive in all respects. The scope of the present invention is not defined by the foregoing description but is defined by the appended claims. All changes within the meaning and range of equivalency of the claims are intended to be embraced therein.

The present invention is in particular advantageously applicable to a semiconductor device including a magnetoresistive element and a manufacturing method thereof.

1-6. (canceled)

7. A method for manufacturing a semiconductor device, comprising the steps of:
preparing a semiconductor substrate having a main surface;
forming a magnetoresistive element located over the main surface of the semiconductor substrate, and having a first upper electrode substantially the same in dimensions in plan view as the magnetoresistive element over the magnetoresistive element;
forming a protective layer so as to cover the side surface of the magnetoresistive element;
forming a second upper electrode larger in dimensions in plan view than the first upper electrode over the first upper electrode; and
forming a wiring located over the second upper electrode.

8. The method for manufacturing a semiconductor device according to claim 7,
wherein in the step of forming the second upper electrode, the second upper electrode is formed such that a partial region of the first upper electrode is embedded in the inside of the second upper electrode.

9. The method for manufacturing a semiconductor device according to claim 7, further comprising the steps of:
after the step of forming the second upper electrode, forming an insulation film so as to cover the side surface of the protective layer and the top surface of the second upper electrode; and
removing the insulation film formed over the second upper electrode so as to expose the second upper electrode,
wherein in the step of forming the wiring the wiring is formed over the second upper electrode so as to be directly coupled with the second upper electrode.

10. The method for manufacturing a semiconductor device according to claim 9,
wherein in the step of forming the wiring, the wiring is formed such that a partial region of the second upper electrode is embedded in the inside of the wiring for establishing a direct coupling therebetween.

11. The method for manufacturing a semiconductor device according to claim 7, further comprising the steps of:
after the step of forming the second upper electrode, forming an insulation film so as to cover the side surface of the protective layer and the top surface of the second upper electrode;
removing the insulation film formed over the second upper electrode so as to expose at least a part of the second upper electrode; and
in the removing step, forming a contact part so as to fill the region from which the insulation film has been removed,
wherein in the step of forming the wiring, the wiring is formed such that the second upper electrode and the wiring are electrically coupled with each other by the contact part.

12. The method for manufacturing a semiconductor device according to claim 7, further comprising the steps of:
forming a lower electrode disposed so as to sandwich the magnetoresistive element with the first upper electrode; and
forming a sidewall insulation film so as to cover the side surface of the lower electrode.
